(19) United States
(12) Patent Application Publication
(10) Pub. No.: US 2026/0067590 A1
(43) Pub. Date: Mar. 5, 2026

(54) PIXEL CIRCUIT AND IMAGE SENSOR INCLUDING THE SAME

(71) Applicant: SAMSUNG ELECTRONICS CO., LTD., Suwon-si (KR)

(72) Inventors: DONGSUK YOO, Suwon-si (KR); Youngchan Kim, Suwon-si (KR); Youngsun Oh, Suwon-si (KR)

(73) Assignee: SAMSUNG ELECTRONICS CO., LTD., Suwon-si (KR)

(21) Appl. No.: 19/201,483

(22) Filed: May 7, 2025

(30) Foreign Application Priority Data
Aug. 27, 2024 (KR) 10-2024-0115417

(51) Int. Cl. H04N 25/51; H04N 25/616; H04N 25/67; H04N 25/771; H10F 39/00; H10F 39/18

(52) U.S. Cl. CPC H04N 25/51; H04N 25/616; H04N 25/67; H04N 25/771; H10F 39/182; H10F 39/8027; H10F 39/8053; H10F 39/8063; H10F 39/807

(57) ABSTRACT

An image sensor may include a pixel and a row driver configured to control the pixel. The pixel may include a first photoelectric element, at least one second photoelectric element, and at least one third photoelectric element that are connected to a first node, a second node, and a third node, respectively. The pixel may further include a driving transistor configured to generate a pixel signal based on a voltage of the first node applied to a gate of the driving transistor, a gain control transistor connected between the first node and the second node, a first switch transistor connected between the second node and the third node, and a capacitor connected between the third node and a power source.

### CROSS-REFERENCE TO RELATED APPLICATION

This application claims priority to and the benefit of Korean Patent Application No. 10-2024-0115417 filed in the Korean Intellectual Property Office on Aug. 27, 2024, the entire contents of which is incorporated herein by reference.

### BACKGROUND

### 1. Field

The present disclosure relates to a pixel circuit and an image sensor including the pixel circuit.

### 2. Description of Related Art

Image sensors are devices for capturing two-dimensional or three-dimensional images of objects. Image sensors generate images of objects, using photoelectric conversion elements that react according to the intensity of light reflected from the objects. With the recent development of complementary metal-oxide semiconductor (CMOS) technology, CMOS image sensors using CMOS are being widely used.

Recently, as image sensors are mounted on various devices, there is a growing demand for image sensors with improved characteristics of high dynamic range (HDR) and signal to noise ratio (SNR) in both low and high-light conditions.

### SUMMARY

Embodiments of the present disclosure provide an image sensor having a high dynamic range.

An image sensor may include a pixel and a row driver connected to the pixel and configured to control the pixel. The pixel may include a first photoelectric element, at least one second photoelectric element, and at least one third photoelectric element that are connected to a first node, a second node, and a third node, respectively; a driving transistor configured to generate a pixel signal based on a voltage of the first node applied to a gate of the driving transistor; a gain control transistor connected between the first node and the second node; a first switch transistor connected between the second node and the third node; and a capacitor connected between the third node and a power source.

A pixel circuit may include: a first group including a first photoelectric element configured to generate a photoelectric charge, a driving transistor configured to generate a pixel signal based on a voltage of a first node connected to the first photoelectric element, a gain control transistor connected between the first node and a second node, and a first switch transistor connected between the second node and a third node; a second group including at least one second photoelectric element connected to the second node; a third group including at least one third photoelectric element connected to the third node and a capacitor between the third node and a power source; and a separation pattern disposed between the first group, the second group, and the third group, wherein the first group is disposed in a central region of the pixel circuit, and wherein the second group and the third group are disposed in a plurality of peripheral areas of the pixel circuit.

An image sensor may include a pixel and a row driver connected to the pixel and configured to control the pixel. The pixel may include: a first photoelectric element, at least one second photoelectric element, and at least one third photoelectric element that are connected to a first node, a second node, and a third node, respectively; a driving transistor configured to generate a pixel signal based on a voltage of the first node applied to a gate of the driving transistor; a gain control transistor connected between the first node and the second node; a first switch transistor connected between the second node and the third node; and a capacitor connected between the third node and a power source. The first switch transistor may be disposed in a central region of the pixel, and the at least one second photoelectric element and the at least one third photoelectric element may be disposed in a plurality of peripheral areas of the pixel.

### BRIEF DESCRIPTION OF DRAWINGS

FIG. 1 is a drawing showing an image sensor according to one or more embodiments.

FIG. 2 is a circuit diagram of a pixel according to one or more embodiments.

FIG. 3 is a top plan view schematically showing the pixel according to FIG. 2.

FIG. 4 is a schematic cross-sectional view with respect to the pixel according to FIG. 3.

FIG. 5 is a timing diagram showing an operation of an image sensor according to one or more embodiments.

FIG. 6 is a circuit diagram of a pixel according to one or more embodiments.

FIG. 7 is a top plan view schematically showing the pixel according to FIG. 6.

FIG. 8 is a top plan view showing an example of the pixel according to FIG. 6.

FIG. 9 is a top plan view schematically showing the pixel according to FIG. 6.

FIG. 10 is a top plan view schematically showing the pixel according to FIG. 6.

FIG. 11 is a timing diagram showing an operation of an image sensor according to one or more embodiments.

FIG. 12 is a timing diagram showing an operation of an image sensor according to one or more embodiments.

FIG. 13 is a circuit diagram of a pixel according to one or more embodiments.

FIG. 14 is a top plan view schematically showing the pixel according to FIG. 13.

FIG. 15 is a timing diagram showing an operation of an image sensor according to one or more embodiments.

FIG. 16 is a circuit diagram of a pixel according to one or more embodiments.

FIG. 17 is a top plan view schematically showing the pixel according to FIG. 16.

FIG. 18 is a timing diagram showing an operation of an image sensor according to one or more embodiments.

FIG. 19 is a circuit diagram of a pixel according to one or more embodiments.

FIG. 20 is a top plan view schematically showing the pixel according to FIG. 19.

FIG. 21 is a top plan view schematically showing the pixel according to FIG. 19.

FIG. 22 is a top plan view schematically showing the pixel according to FIG. 19.

FIG. 23 is a top plan view schematically showing the pixel according to FIG. 19.

FIG. 24 is a timing diagram showing an operation of an image sensor according to one or more embodiments.

FIG. 25 is a circuit diagram of a pixel according to one or more embodiments.

FIG. 26 is a top plan view schematically showing the pixel according to FIG. 25.

FIG. 27 is a timing diagram showing an operation of an image sensor according to one or more embodiments.

FIG. 28 is a circuit diagram of a pixel according to one or more embodiments.

FIG. 29 is a top plan view schematically showing the pixel according to FIG. 28.

FIG. 30 is a timing diagram showing an operation of an image sensor according to one or more embodiments.

FIG. 31 is a circuit diagram of a pixel according to one or more embodiments.

FIG. 32 is a top plan view schematically showing the pixel according to FIG. 31.

FIG. 33 is a timing diagram showing an operation of an image sensor according to one or more embodiments.

FIG. 34 is a circuit diagram of a pixel according to one or more embodiments.

FIG. 35 is a top plan view schematically showing the pixel according to FIG. 34.

FIG. 36 is a timing diagram showing an operation of an image sensor according to one or more embodiments.

FIG. 37 to FIG. 47 are top plan views schematically showing a pixel according to one or more embodiments.

FIG. 48 is a graph showing a signal-to-noise ratio (SNR) according to one or more embodiments.

FIG. 49 is a block diagram showing a vehicle according to one or more embodiments.

### DETAILED DESCRIPTION OF EMBODIMENTS

In the following detailed description, only certain embodiments of the present disclosure have been shown and described, simply by way of illustration. As those skilled in the art would realize, the described embodiments may be modified in various different ways, all without departing from the spirit or scope of the present disclosure.

Accordingly, the drawings and description are to be regarded as illustrative in nature and not restrictive. Like reference numerals designate like elements throughout the specification. In the flowchart described with reference to the drawings, the operation order may be changed, several operations may be merged, certain operations may be divided, and particular operations may not be performed.

In addition, expressions written in the singular may be construed in the singular or plural unless an explicit expression such as “one” or “single” is used. Terms including ordinal numbers such as first, second, and the like will be used only to describe various components, and are not to be interpreted as limiting these components. These terms may be used for the purpose of distinguishing one component from other components.

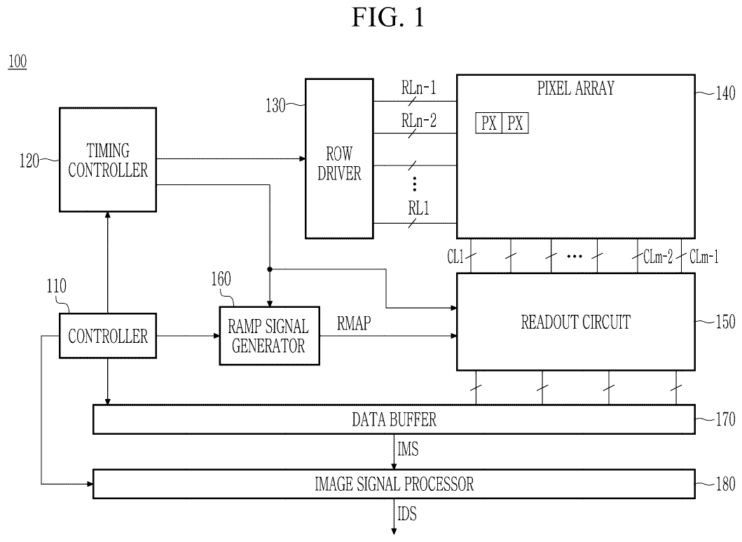

FIG. 1 is a drawing showing an image sensor according to one or more embodiments.

As shown in FIG. 1, an image sensor 100 may include a controller 110, a timing generator 120, a row driver 130, a pixel array 140, a readout circuit 150, a ramp signal generator 160, a data buffer 170, and an image signal processor 180. FIG. 1 illustrates that the image sensor 100 includes the image signal processor 180, but the present disclosure is not limited thereto, and the image signal processor 180 may be located outside the image sensor 100.

The image sensor 100 may be mounted in an electronic device having an image or light sensing function. For example, the image sensor 100 may be mounted in electronic devices such as cameras, smart phones, wearable devices, IoT (Internet of Things) devices, home appliances, tablet PCs (personal computers), personal digital assistants (PDAs), portable multimedia players (PMPs) navigation devices, drones, advanced drivers assistance systems (ADASs), etc. Also, the image sensor 100 may be mounted in electronic devices which are incorporated as components in vehicles, furniture, manufacturing equipment, doors, various measuring devices, etc.

The controller 110 may generally control each of components 120, 130, 140, 150, 160, 170, and 180 included in the image sensor 100. The controller 110 may control operation timing of each of the components 120, 130, 140, 150, 160, 170, and 180 by using control signals.

In one or more embodiments, the controller 110 may control the ramp signal generator 160 to adjust a reference signal RAMP generated by the ramp signal generator 160. In one or more embodiments, the controller 110 may control a timing controller 120 to adjust floating diffusion (FD) capacitance of a pixel circuit within the pixel array 140 through the row driver 130. In one or more embodiments, the controller 110 may control the timing controller 120 to adjust operation timing of a elements within the pixel array 140 through the row driver 130.

The timing controller 120 may generate a signal which is a reference for the operation timings of the components of the image sensor 100. The timing controller 120 may control the timings of the row driver 130, the readout circuit 150, and the ramp signal generator 160. The timing controller 120 may provide a control signal to control the timings of the row driver 130, the readout circuit 150, and the ramp signal generator 160.

The timing controller 120 may control timing of elements within a pixel PX in a reset period, an integration period, and a readout period. The reset period may be a period in which the charges accumulated in floating diffusion nodes within the pixel PX are reset. The integration period may be a period in which the photoelectric element is exposed to light to generate photo charges. The readout period may be a period in which the photo charges generated in the photoelectric element are transferred to the readout circuit 150.

In one or more embodiments, the controller 110 may control the timing controller 120 to divide and readout the photoelectric charges generated by the photoelectric element during the integration period to a plurality of nodes.

The pixel array 140 may include the plurality of pixels PX, and a plurality of row lines RL and a plurality of column lines CL that are coupled to the plurality of pixels PX, respectively. In one or more embodiments, each pixel PX may include at least one photoelectric element (also referred to as optical sensing device). The photoelectric elements may detect incident light, and convert the incident light into electrical signals based on the amount of light, i.e., a plurality of analog pixel signals. The levels of analog pixel signals which are output from the photoelectric elements may increase as the amounts of charge which are output from the photoelectric elements increase. In other words, the levels of analog pixel signals which are output from the photoelectric elements may increase as the amount of light entering the pixel array 140 increases.

In one or more embodiments, the pixel PX may include a split photoelectric element structure including at least two photoelectric elements. For example, the pixel PX may include a first photoelectric element having a large light-receiving area and a second photoelectric element having a smaller light-receiving area than that of the first photoelectric element. Hereinafter, the first photoelectric element may be referred to as a large photodiode (LPD), and the second photoelectric element may be referred to as a small photodiode (SPD). The small photodiode and the large photodiode may be independently exposed.

Because a light-receiving area of the large photodiode (LPD) is wider, it may generate more charges than the small photodiode (SPD) under the same light-receiving condition. That is, the large photodiode (LPD) may have a higher sensitivity than the small photodiode (SPD). Accordingly, in the case of a low-light environment, an image signal may be generated based on the charges generated by the large photodiode (LPD). In the case of high-light environment, an image signal may be generated based on the charges generated by the small photodiode (SPD).

Meanwhile, the small photodiode (SPD) may operate in high-light ranges by extending exposure times. A high-capacity capacitor may be connected to the small photodiode (SPD). The high-capacity capacitor connected to the small photodiode (SPD) may store the charges generated and overflowing from the small photodiode (SPD) during the long exposure time. For example, the high-capacity capacitor may include a lateral overflow integration capacitor (LOFIC).

In one or more embodiments, the pixel PX may include one first photoelectric element and a plurality of second photoelectric elements. For example, the plurality of second photoelectric elements may be disposed to achieve axial symmetry about any axis of symmetry. In one or more embodiments, the first photoelectric element may be disposed in a central region of the pixel PX, and the plurality of second photoelectric elements may be disposed in a plurality of peripheral areas surrounding the central region of the pixel PX. For example, the central region may include a center of the pixel PX, and the plurality of peripheral areas may include a peripheral region of the pixel PX such as an edge, a vertex, a corner, or the like.

In one or more embodiments, a capacitor may be connected to at least one second photoelectric element among the plurality of second photoelectric elements. For example, the pixel PX may include one capacitor connected to one first photoelectric element, four second photoelectric elements, and two second photoelectric elements. The sensitivity ratio between the first photoelectric element, the second photoelectric element, and the capacitor may be controlled by adjusting the number of the second photoelectric elements connected to the capacitor is connected, among the plurality of second photoelectric elements. This adaptability allows for better control over the pixel sensitivity and improve precision in detecting light. The circuit structure of the pixel according to the embodiments of the present disclosure may enable a wider dynamic range to be achieved as the sensitivity ratio increases, without the need for adding additional capacitors, which would otherwise increase complexity and size.

In one or more embodiments, the controller 110 may operate in a first mode during a first section among the readout period, and may control the timing controller 120 to operate in a second mode during a second section among the readout period.

Based on the control of the controller 110, the pixel PX may sequentially operate according to a plurality of modes. In one or more embodiments, the pixel PX may operate in the first mode based on the large photodiode (LPD). The first mode may include a first operation and a second operation distinguished according to a conversion gain. The conversion gain may be a rate at which the charge generated by a photoelectric element, for example, the first photoelectric element is converted into the electric signal (e.g., a pixel voltage). The conversion gain may be varied according to the capacitance (hereinafter, briefly referred to as capacitance of floating diffusion node) of the parasitic capacitor connected to the floating diffusion node. For example, when the capacitance of the floating diffusion node increases, the conversion gain may decrease, and when the capacitance decreases, the conversion gain may increase. In one or more embodiments, the first operation may be a high conversion gain operation based on the large photodiode (LPD), and the second operation may be a low conversion gain operation based on the large photodiode (LPD).

In one or more embodiments, the pixel PX may operate in the second mode based on the small photodiode (SPD). The second mode may include a third operation and a fourth operation distinguished based on whether signals due to the overflowed charge of the small photodiode (SPD) stored in the capacitor is read, and the capacitor is connected to the small photodiode (SPD). In one or more embodiments, the third operation may be an operation to readout the charges generated by the small photodiode (SPD), and the fourth operation may be an operation to readout the charges stored in the capacitor.

The pixel signals of the first operation and the second operation according to the first mode and the third operation and the fourth operation according to the second mode may correspond to different light conditions. The pixel signals according to the first operation, the second operation, the third operation, and the fourth operation may be generated within one frame section.

One image data IDS may be generated based on an image output signal IMS generated based on the plurality of pixel signals output from the plurality of pixels PX of the pixel array 140. The synthesized image may have a high dynamic range.

The plurality of row lines RL (RL1 to RLn−1) may extend in a first direction, and may be connected to the plurality of pixels disposed along the first direction. For example, the plurality of row lines RL may transfer the control signal output from the row driver 130 to elements included in the pixel, for example, transistors. Signal lines other than the row lines RL may be arranged in the first direction. The plurality of column lines CL (CL1 to CLm−1) may extend in a second direction crossing the first direction, and may be connected to the plurality of pixels PX disposed along the second direction. The column line CL may transfer the pixel signal output from the plurality of pixels PX to the readout circuit 150. In response to a control signal of the timing controller 120, the row driver 130 may generate the control signal for driving the pixel array 140, and may provide the control signal to the plurality of pixels PX of the pixel array 140 through the plurality of row lines RL. In one or more embodiments, the row driver 130 may control the pixels PX in row line units, such that the pixels detect incident light. Each row line unit may include at least one row line RL.

In response to a control signal from the timing controller 120, the readout circuit 150 may convert the pixel signal (or electric signal) from the pixels PX connected to a row line RL selected from among the plurality of pixels PX into a pixel value representing the amount of light. The readout circuit 150 may include a correlated double sampling circuit, and an analog-digital converter (ADC) circuit, or the like.

The correlated double sampling (CDS) circuit may include a plurality of comparators, and each comparator may compare the pixel signal received from the pixel array 140 through the plurality of column lines CL with the reference signal RAMP from a lamp generator 160. Specifically, the CDS circuit may compare the received pixel signal with the reference signal RAMP, and output the comparison result to an analog digital conversion circuit.

The plurality of pixel signals output from the plurality of pixels PX may have deviations due to the unique characteristics of each pixel (e.g., fixed pattern noise (FPN), or the like) and/or deviations due to differences in characteristics of pixel circuits for outputting pixel signals from the pixel PX (e.g., transistors for outputting charges stored in photoelectric conversion device within a pixel). Obtaining a reset component (e.g., reset voltage) and a sensing component (e.g., sensing voltage) with respect to the pixel signal and extract their difference (e.g., a difference between the reset voltage and the sensing voltage) as a valid signal component, in order to compensate for the deviation between the plurality of pixel signals output through the plurality of column lines CL, is referred to as a correlated double sampling. The correlated double sampling circuit may output a comparison result in which the correlated double sampling technique is applied with respect to the received pixel signal.

The analog digital conversion circuit may convert the comparison result of the correlated double sampling circuit to digital data, and thereby may generate and output pixel values corresponding to a plurality of pixels, on a row-by-row basis. The analog digital conversion circuit may include a plurality of counters. The counter may be implemented as an up-counter and a calculation circuit, or up/down counters, or a bit-wise inversion counter, in which the count value sequentially increases based on a counting clock signal. The plurality of counters may be connected to the output of each of the plurality of comparators. Each of the plurality of counters may count the comparison result output from a corresponding comparator, and may output a digital data (e.g., pixel value) according to the counting result.

The ramp signal generator 160 may generate a reference signal RAMP and transmit it to the readout circuit 150. The ramp signal generator 160 may include current sources, resistors, and capacitors. The ramp signal generator 160 may adjust ramp voltage which is voltage to be applied to a ramp resistor by adjusting the current magnitude of a variable current source or the resistance value of a variable resistor. In this way, the ramp signal generator 160 may generate a plurality of ramp signals which falls or rises at slopes determined depending on the current magnitudes of variable current sources or the resistance values of variable resistors.

The data buffer 170 may store the pixel values of the plurality of pixels PX coupled to the selected column line CL, received from the readout circuit 150. The data buffer 170 may output the pixel value stored in response to an enable signal from the controller 110 to the image signal processor 180 as the image output signal IMS.

The image signal processor 180 may perform image signal processing on image output signals IMS received from the data buffer 170. For example, the image signal processor 180 may receive a plurality of image output signals IMS from the data buffer 170, and synthesize the received image output signal IMS to generate an image IDS.

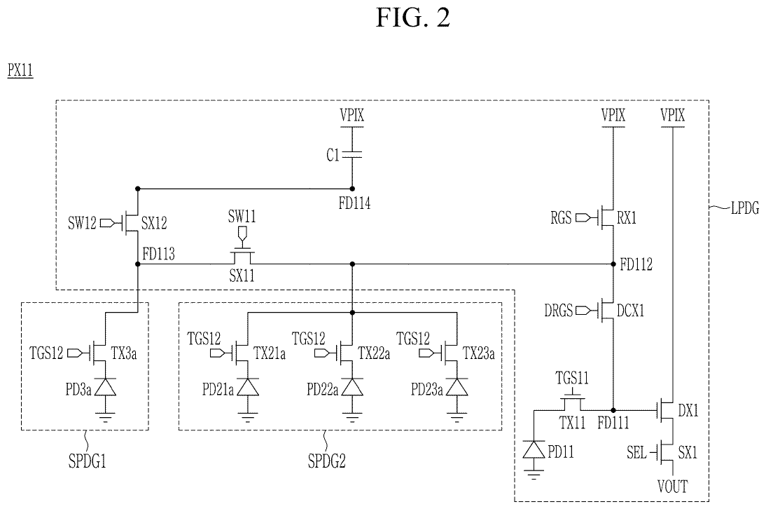

FIG. 2 is a circuit diagram of a pixel according to one or more embodiments. Specifically, FIG. 2 is a circuit diagram of the pixel PX of FIG. 1.

Referring to FIG. 2, a pixel PX11 may include a first small photodiode group SPDG1 including a third photodiode PD3a, a second small photodiode group SPDG2 including a plurality of second photodiodes PD21a, PD22a, and PD23a, and a large photodiode group LPDG including a first photoelectric element PD11.

The plurality of second photodiodes PD21a, PD22a, and PD23a and the third photodiode PD3a may be small photodiodes, and the first photoelectric element PD11 may be a large photodiode.

The large photodiode group LPDG may include a plurality of transistors, for example, a first transmission transistor TX11, a reset transistor RX1, a driving transistor DX1, a selection transistor SX1, a gain control transistor DCX1, a first switch transistor SX11, a second switch transistor SX12, and a first capacitor C1. Control signals TGS11, RGS, SEL, DRGS, SW11, and SW12 may be applied to the large photodiode group LPDG. In one or more embodiments, the control signals may be generated by the row driver 130 (see FIG. 1) based on the control of the timing controller 120.

The first transmission transistor TX11 may be connected between the first photoelectric element PD11 and a first floating diffusion node FD111. The first transmission transistor TX11 may be controlled by a first transmission control signal TGS11. When the first transmission transistor TX11 is turned on, the charge generated by the first photoelectric element PD11 may be transferred to the first floating diffusion node FD111.

The reset transistor RX1 may be connected between a second floating diffusion node FD112 and the power source voltage line supplying a power source voltage VPIX. The reset transistor RX1 may be controlled by a reset control signal RGS. When the reset transistor RX1 is turned on, the power source voltage VPIX may be applied to the second floating diffusion node FD112, and thereby the second floating diffusion node FD112 may be reset. When the switch transistor SX11 is turned on while the reset transistor RX1 is turned on, a third floating diffusion node FD113 and the second floating diffusion node FD112 may be reset to the power source voltage VPIX. When the switch transistor SX11 and the switch transistor SX12 are turned on while the reset transistor RX1 is turned on, the second floating diffusion node FD112, the third floating diffusion node FD113, and a fourth floating diffusion node FD114 may be reset to the power source voltage VPIX. When the gain control transistor DCX1 is turned on while the reset transistor RX1 is turned on, the first floating diffusion node FD111 and the second floating diffusion node FD112 may be reset to the power source voltage VPIX.

A gate of the driving transistor DX1 may be connected to the first floating diffusion node FD111. A first end of the driving transistor DX1 may be connected to the power source voltage VPIX, and a second end thereof may be connected to a first end of the selection transistor SX1. The driving transistor DX1 may operate as a source-follower amplifier with respect to a voltage of the first floating diffusion node FD111. In response to the voltage of the first floating diffusion node FD111, the driving transistor DX1 may output a pixel voltage VOUT to the column line CL (see FIG. 1) through the selection transistor SX1.

The selection transistor SX1 may be connected to the first end of the driving transistor DX1 and the column line CL, and may be controlled by a selection control signal SEL. When the selection transistor SX1 is turned on, the pixel voltage VOUT output from the driving transistor DX1 may be output to the readout circuit 150 (see FIG. 1) through the column line CL connected to the selection transistor SX1. For example, when the selection transistor SX1 is turned on in the readout operation, a pixel signal including a reset signal corresponding to a reset operation or an image signal corresponding to a charge accumulation operation may be output through the column line CL.

The gain control transistor DCX1 may be connected between the first floating diffusion node FD111 and the second floating diffusion node FD112. The gain control transistor DCX1 may be controlled by a gain control signal DRGS. When the gain control transistor DCX1 is turned on, the first floating diffusion node FD111 and the second floating diffusion node FD112 are connected to each other such that the capacitance may increase, and a conversion gain, which is a ratio of charges converted to voltage may decrease. That is, when a conversion gain transistor DCX1 is turned on, pixel PX11 may operate in a low conversion gain (LCG) mode to the first photoelectric element PD11. To the contrary, when the conversion gain transistor DCX1 is turned off, the first photoelectric element PD11 may operate in a high conversion gain (HCG) mode. The HCG mode may be activated in relatively low-light conditions, so that the pixel PX11 becomes more sensitive to light and generates a larger electrical signal per photo (i.e., high gain), compared to the LCG mode.

The first switch transistor SX11 may be connected between the second floating diffusion node FD112 and the third floating diffusion node FD113. The first switch transistor SX11 may be controlled by a first switch control signal SW11. When the first switch transistor SX11 is turned on, the first floating diffusion node FD111 and the third floating diffusion node FD113 may be connected.

The second switch transistor SX12 may be connected between the third floating diffusion node FD113 and the fourth floating diffusion node FD114. The second switch transistor SX12 may be controlled by a second switch control signal SW12. When the second switch transistor SX12 is turned on, the third floating diffusion node FD113 and the fourth floating diffusion node FD114 are connected, so that the first capacitor C1 is connected to the third floating diffusion node FD113, thereby increasing the capacitance.

The first capacitor C1 may be connected between the fourth floating diffusion node FD114 and the power source voltage line supplying the power source voltage VPIX. When the second switch transistor SX12 is turned on while the first switch transistor SX11 is turned on, the second floating diffusion node FD112, the third floating diffusion node FD113, and the fourth floating diffusion node FD114 may be connected to each other, thereby increasing a capacitance of the second floating diffusion node FD112. That is, the first capacitor C1 may be used to adjust the capacitance of the second floating diffusion node FD112. In one or more embodiments, the photoelectric charge generated from the third photodiode PD3a during the integration period may overflow, and the overflowed charge may be accumulated in the first capacitor C1 by passing through the third floating diffusion node FD113 and the fourth floating diffusion node FD114.

The first capacitor C1 may include a lateral overflow integration capacitor (LOFIC). When the first capacitor C1 includes LOFIC, overflowed charges among charges transferred from the first photoelectric element PD11, the second photodiodes PD21a, PD22a, and PD23a, and the third photodiode PD3a to the first floating diffusion node FD111 may be stored. That is, a large amount of charge that overflows may be accumulated into the first capacitor C1 without being discarded.

The first small photodiode group SPDG1 may include a third transmission transistor TX3a. A control signal TGS12 may be applied to the first small photodiode group SPDG1.

The third transmission transistor TX3a may be connected between the third photodiode PD3a and the third floating diffusion node FD113. The third transmission transistor TX3a may be controlled by a second transmission control signal TGS12. When the third transmission transistor TX3a is turned on, the charge generated by the third photodiode PD3a may be transferred to the third floating diffusion node FD113.

The second small photodiode group SPDG2 may include a plurality of transistors, for example, second transmission transistors TX21a, TX22a, and TX23a. The control signal TGS12 may be applied to the second small photodiode group SPDG2.

A plurality of second transmission transistors TX21a, TX22a, and TX23a may be connected between the plurality of second photodiodes PD21a, PD22a, and PD23a corresponding thereto and the second floating diffusion node FD112. Each of the plurality of second transmission transistors TX21a, TX22a, and TX23a may be controlled by the second transmission control signal TGS12. When the plurality of second transmission transistors TX21a, TX22a, and TX23a are turned on, the charge generated by the plurality of second photodiodes PD21a, PD22a, and PD23a may be transferred to the second floating diffusion node FD112.

The photoelectric charges generated by the large photodiode group LPDG, the first small photodiode group SPDG1, and the second small photodiode group SPDG2 may be transmitted to and accumulated in at least one among the first floating diffusion node FD111, the second floating diffusion node FD112, the third floating diffusion node FD113, the first capacitor C1. In each of the first floating diffusion node FD111, the second floating diffusion node FD112, and the third floating diffusion node FD113, a parasitic capacitor may be formed, or an actual capacitor element may be connected.

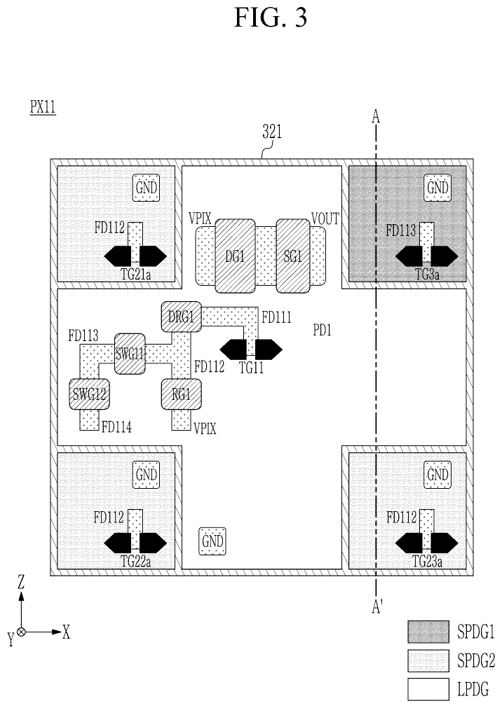

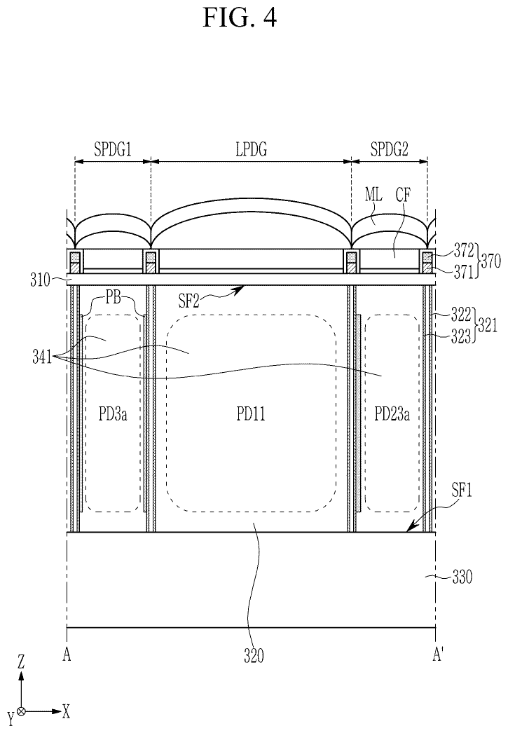

FIG. 3 is a top plan view schematically showing the pixel according to FIG. 2. FIG. 4 is a schematic cross-sectional view with respect to the pixel according to FIG. 3. Specifically, FIG. 4 is an exemplary cross-sectional view taken along line A-A′ of FIG. 3.

Referring to FIG. 3, the pixel PX11 may include the first small photodiode group SPDG1, the second small photodiode group SPDG2, the large photodiode group LPDG. Hereinafter, the first small photodiode group SPDG1, the second small photodiode group SPDG2, the large photodiode group LPDG may indicate regions where photoelectric elements and transistors included in each of the first small photodiode group SPDG1, the second small photodiode group SPDG2, the large photodiode group LPDG are disposed.

As shown in FIG. 3 and FIG. 4, a separation pattern 321 may be disposed on an outer surface of the pixel PX11, and between the first small photodiode group SPDG1, the second small photodiode group SPDG2, and the large photodiode group LPDG within the pixel PX11.

The separation pattern 321 may be positioned along the peripheries (or boundaries) of the first small photodiode group SPDG1, the second small photodiode group SPDG2, and the large photodiode group LPDG within the pixel PX11 to divide regions (hereinafter, referred to as pixel regions) of the first small photodiode group SPDG1, the second small photodiode group SPDG2, and the large photodiode group LPDG, on a two-dimensional plane.

A first switch gate SWG11, a second switch gate SWG12, a reset gate RG1, a gain control gate DRG1, a driving gate DG1, a selection gate SG1, a first transfer gate TG11 may be formed within the large photodiode group LPDG. The first switch gate SWG11 may be a gate of the first switch transistor SX11. The second switch gate SWG12 may be a gate of the second switch transistor SX12. The reset gate RG1 may be a gate of the reset transistor RX1. The gain control gate DRG1 may be a gate of the gain control transistor DCX1. The driving gate DG1 may be a gate of the driving transistor DX1. The selection gate SG1 may be a gate of the selection transistor SX1. The first transfer gate TG11 may be a gate of the first transmission transistor TX11.

In addition, the first floating diffusion node FD111, the second floating diffusion node FD112, the third floating diffusion node FD113, the fourth floating diffusion node FD114 may be formed within the large photodiode group LPDG. A ground region GND and a power source voltage region VPIX, a pixel voltage region VOUT may be formed within the large photodiode group LPDG.

In one or more embodiments, the second switch gate SWG12 may be formed in the first small photodiode group SPDG1 rather than the large photodiode group LPDG. Meanwhile, the present disclosure is not limited thereto, and the plurality of transistors within the pixel may be formed in various arrangements.

A third transfer gate TG3a may be formed within the first small photodiode group SPDG1. The third transfer gate TG3a may be a gate of the third transmission transistor TX3a. The third floating diffusion node FD113 may be formed within the first small photodiode group SPDG1. In addition, the ground region GND may be formed within the first small photodiode group SPDG1.

A plurality of second transfer gates TG21a, TG22a, and TG23a may be formed within the second small photodiode group SPDG2. Each of the plurality of second transfer gates TG21a, TG22a, and TG23a may be gates of plurality of second transmission transistors TX21a, TX22a, and TX23a, respectively. The second floating diffusion node FD112 may be formed within the second small photodiode group SPDG2. In addition, the ground region GND may be formed within the second small photodiode group SPDG2.

The large photodiode group LPDG may be formed in the central region of the pixel PX11, and the first small photodiode group SPDG1 and the second small photodiode group SPDG2 may be disposed symmetrically to each other in a peripheral area (e.g., edge) of the pixel PX11. The first small photodiode group SPDG1 and the second small photodiode group SPDG2 may have a rectangular shape. As shown in FIG. 3, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

Meanwhile, a plurality of microlens may be disposed in an upper portion of the pixel PX11 in various manners.

Referring to FIG. 4, the pixel PX11 may include a microlens ML, a color filter layer CF, a surface insulation layer 310, a semiconductor substrate 320, the separation pattern 321, and an insulation layer 330.

The microlens ML may have a convex shape, and may have a predetermined radius of curvature. The microlens ML may be arranged to correspond to each pixel region. For example, the microlens ML may include a first microlens corresponding to a region of the first photoelectric element PD11, a second microlens corresponding to a region of the second photodiode PD23a, and a third microlens corresponding to a region of the third photodiode PD3a.

The color filter layer CF may be disposed in a lower portion of the microlens ML. The color filter layer CF may be disposed on the surface insulation layer 310. A color filter CF may be arranged to correspond to each unit pixel. Each color filter CF may be arranged two-dimensionally from a planar perspective. The color filter layer CF may pass reflection light incident through the microlens ML, and allow only light of a required wavelength to be incident on a photoelectric conversion region 341. The color filter layer CF may be referred to as the color filter array. In some embodiments, in order to obtain only a color image, an infrared image, or a depth image, the color filter layer CF may be omitted.

The surface insulation layer 310 may be stacked on a second surface SF2 of the semiconductor substrate 320.

A color filter grid 370 may be disposed in a mesh shape between the color filters CF. The color filter grid 370 may define a region where the color filter CF is disposed. In one or more embodiments, at least a portion of the color filter grid 370 may overlap with the separation pattern 321 in a third direction Z.

The color filter grid 370 may be formed on the surface insulation layer 310. The color filter grid 370 may include, for example, a metal pattern 371 and a low refractive index pattern 372. The metal pattern 371 and the low refractive index pattern 372 may be sequentially stacked on the surface insulation layer 310.

The semiconductor substrate 320 may be, for example, a bulk silicon or silicon-on-insulator (SOI). The semiconductor substrate 320 may be a silicon substrate, and may include other materials, for example, silicon germanium, indium antimonide, lead tellurium compound, indium arsenic, indium phosphide, gallium arsenide or gallium antimonide. Alternatively, the semiconductor substrate 320 may include a base substrate on which an epitaxial layer is formed. In some embodiments, the semiconductor substrate 320 may have a first conductivity type. For example, the first conductivity type may be a P-type.

The semiconductor substrate 320 may include a first surface SF1 and the second surface SF2 opposed to each other. The first surface SF1 may be referred to as a front side of the semiconductor substrate 320, and the second surface SF2 may be referred to as a back side of the semiconductor substrate 320. In some embodiments, light may be incident on the second surface SF2 of the semiconductor substrate 320, which may be a light-receiving surface exposing the photoelectric conversion region 341.

The semiconductor substrate 320 may include the photoelectric conversion region 341, and the photoelectric conversion region 341 may have a second conductivity type. For example, the second conductivity type may be an N-type. By PN junction of the photoelectric conversion region 341 of N-type and the substrate 320 of P-type, the photodiodes PD11, PD23a, and PD3a may be formed.

The semiconductor substrate 320 may include a P-type barrier PB. The P-type barrier PB may be disposed to be spaced apart from the photoelectric conversion region 341 by a preset interval. For example, each P-type barrier PB may be formed to be spaced apart from each photoelectric conversion region 341 in the first direction X and the second direction Y. In addition, the P-type barrier PB may extend in the third direction Z along the photoelectric conversion region 341. That is, the P-type barrier PB may be vertically formed within the semiconductor substrate 320. The P-type barrier PB may be doped with P-type impurities.

The separation pattern 321 may be disposed on an exterior side of the semiconductor substrate 320 or between a plurality of photodiodes PD11, PD23a, and PD3a. The separation pattern 321 may define the plurality of photodiodes PD11, PD23a, and PD3a. The plurality of photodiodes PD11, PD23a, and PD3a may be arranged two-dimensionally from a planar perspective. For example, the separation pattern 321 may be formed in a lattice shape in planar perspective, to separate the plurality of photodiodes PD11, PD23a, and PD3a from each other.

In one or more embodiments, the separation pattern 321 may be formed by filling an insulating material into a deep trench formed by patterning the semiconductor substrate 320. The separation pattern 321 may be an insulation material formed of, for example, oxide, nitride, oxynitride or a combination thereof. In one or more embodiments, the separation pattern 321 may include a conducting material layer and a cover insulation layer surrounding the conducting material layer. For example, the conducting material layer may include an oxide such as polysilicon, metal, or metal nitride or silicon dioxide (SiO₂), and the cover insulation layer may include oxide, nitride, oxynitride or a combination thereof.

In one or more embodiments, the separation pattern 321 may include an insulation spacer layer 322 and a conductive filling pattern 323. The insulation spacer layer 322 may be conformally extended along a side surface of a trench within the semiconductor substrate 320. The conductive filling pattern 323 may be formed on the insulation spacer layer 322, and fill a portion of the trench of the semiconductor substrate 320.

In one or more embodiments, the separation pattern 321 may be a frontside deep trench isolation (FDTI).

Meanwhile, as an example, although FIG. 4 illustrates a frontside deep trench isolation (FDTI) pattern, in which the separation pattern 321 extends to penetrate the semiconductor substrate 320 from the first surface SF1 of the semiconductor substrate 320 to the second surface SF2, the present disclosure is not limited thereto, and the separation pattern 321 may be a backside deep trench isolation (BDTI).

The insulation layer 330 may include a plurality of transistors. In one or more embodiments, the plurality of transistors may be implemented as a vertical transfer gate (VTG).

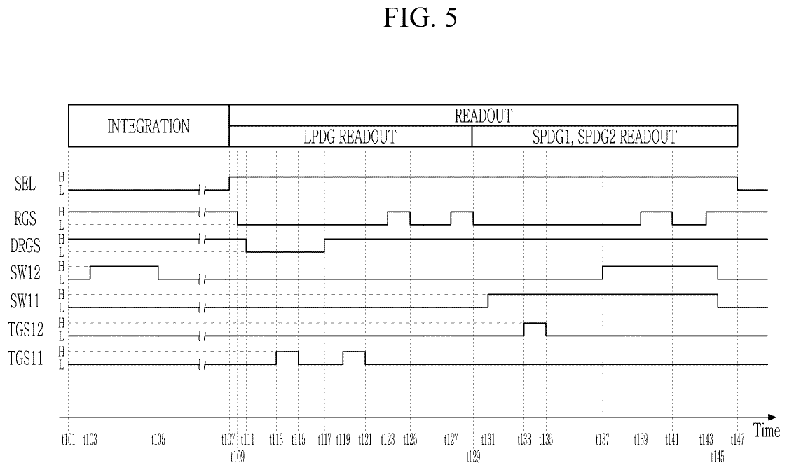

FIG. 5 is a timing diagram showing an operation of the image sensor according to one or more embodiments.

In more detail, FIG. 5 may show one scan period for driving the pixel PX11 according to FIG. 2. One scan period may sequentially include an integration period INTEGRATION and a readout period READOUT.

The integration period INTEGRATION (i.e., t101 to t107) may be a period where the first photoelectric element PD11, the plurality of second photodiodes PD21a, PD22a, and PD23a, and the third photodiode PD3a are exposed to light and thereby generate charges.

At t101, the selection control signal SEL, the first switch control signal SW11, the second switch control signal SW12, the first transmission control signal TGS11, the second transmission control signal TGS12 may be a low level L, and the reset control signal RGS and the gain control signal DRGS may be a high level H.

At t103, the second switch control signal SW12 may transition from the low level L to the high level H. While the second switch control signal SW12 maintains the high level H, the third floating diffusion node FD113 and the fourth floating diffusion node FD114 may be connected. Accordingly, the overflowed photoelectric charge among the photoelectric charge generated from the third photodiode PD3a may be accumulated in the first capacitor C1.

At t105, the second switch control signal SW12 may transition from the high level H to the low level L.

The readout period READOUT (i.e., t107 to t147) may be a period where a pixel signal VOUT generated by the pixel PX11 is transferred to the readout circuit 150 (see FIG. 1). The readout period READOUT may include a large photodiode group readout period LPDG READOUT (i.e., t107 to t129), first and second small photodiode group readout periods SPDG1 and SPDG2 READOUT (i.e., t129 to t147).

At t107, the selection control signal SEL may transition from the low level L to the high level H. As the selection control signal SEL maintains the high level H, the pixel PX11 may read the pixel signal VOUT.

At t109, the reset control signal RGS may transition from the high level H to the low level L.

At t111, the gain control signal DRGS may transition from the high level H to the low level L.

As the gain control signal DRGS maintains the low level L, the pixel PX11 may output a signal corresponding to the accumulated charge to the first floating diffusion node FD111 as the pixel signal VOUT. That is, the pixel PX11 may operate in the high conversion gain (HCG) mode.

Between t111 and t113, when the image sensor 100 operates in the high conversion gain (HCG) mode with respect to the first photoelectric element PD11, the pixel PX11 may output a signal (i.e., reset signal) corresponding to the charge of the first floating diffusion node FD111 as the pixel signal VOUT.

At t113, the first transmission control signal TGS11 may transition from the low level L to the high level H. Thereafter, at t115, the first transmission control signal TGS11 may transition from the high level H to the low level L. The first transmission transistor TX11 may be turned on by the first transmission control signal TGS11 of the high level H, and the photoelectric charge generated by the first photoelectric element PD11 may be transferred to the first floating diffusion node FD111.

Between t115 and t117, when the image sensor 100 operates in the high conversion gain (HCG) mode with respect to the first photoelectric element PD11, the pixel PX11 may output a signal (i.e., image signal) corresponding to the charge of the first floating diffusion node FD111 as the pixel signal VOUT.

At t117, the gain control signal DRGS may transition from the low level L to the high level H.

As the gain control signal DRGS maintains the high level H, the pixel PX11 may output a signal corresponding to the accumulated charge to the first floating diffusion node FD111 and the second floating diffusion node FD112 as the pixel signal VOUT. That is, the pixel PX11 may operate in the low conversion gain (LCG) mode.

At t119, the first transmission control signal TGS11 may transition from the low level L to the high level H. Thereafter, at t121, the first transmission control signal TGS11 may transition from the high level H to the low level L. The first transmission transistor TX11 may be turned on by the first transmission control signal TGS11 of the high level H, and the photoelectric charge generated by the first photoelectric element PD11 may be transferred to the first floating diffusion node FD111 and the second floating diffusion node FD112.

Between t121 and t123, when the image sensor 100 operates in the low conversion gain (LCG) mode with respect to the first photoelectric element PD11, the pixel PX11 may output a signal (i.e., image signal) corresponding to the first floating diffusion node FD111 and the second floating diffusion node FD112 as the pixel signal VOUT.

At t123, the reset control signal RGS may transition from the low level L to the high level H. At t125, the reset control signal RGS may transition from the high level H to the low level L.

Between t125 and t127, when the image sensor 100 operates in the low conversion gain (LCG) mode with respect to the first photoelectric element PD11, the pixel PX11 may output a signal (i.e., reset signal) corresponding to the first floating diffusion node FD111 and the second floating diffusion node FD112 as the pixel signal VOUT.

At t127, the reset control signal RGS may transition from the low level L to the high level H. Thereafter, at t129, the reset control signal RGS may transition from the high level H to the low level L.

The first floating diffusion node FD111 and the second floating diffusion node FD112 may be reset to the power source voltage VPIX by the gain control signal DRGS and the reset control signal RGS of the high level H.

At t131, the first switch control signal SW11 may transition from the low level L to the high level H.

Since the first switch transistor SX11 is turned on by the first switch control signal SW11 of the high level H, the second floating diffusion node FD112 and the third floating diffusion node FD113 may be connected.

Between t131 and t133, the pixel PX11 may output signals (i.e., reset signals) corresponding to the first floating diffusion node FD111, the second floating diffusion node FD112, and the third floating diffusion node FD113, as the pixel signal VOUT.

At t133, the second transmission control signal TGS12 may transition from the low level L to the high level H. Thereafter, at t135, the second transmission control signal TGS12 may transition from the high level H to the low level L. The plurality of second transmission transistors TX21a, TX22a, and TX23a and the third transmission transistor TX3a may be turned on by the second transmission control signal TGS12 of the high level H. Accordingly, the photoelectric charge generated by the plurality of second photodiodes PD21a, PD22a, and PD23a and the photoelectric charge generated by the third photodiode PD3a may be transferred to the first floating diffusion node FD111, the second floating diffusion node FD112, and the third floating diffusion node FD113.

Between t135 and t137, the pixel PX11 may output signals (i.e., image signals) corresponding to the first floating diffusion node FD111, the second floating diffusion node FD112, and the third floating diffusion node FD113, as the pixel signal VOUT.

At t137, the second switch control signal SW12 may transition from the low level L to the high level H.

Since the second switch transistor SX12 is turned on by the second switch control signal SW12 of the high level H, the third floating diffusion node FD113 and the fourth floating diffusion node FD114 may be connected. Accordingly, the charge stored in the first capacitor C1 may be transferred to the first floating diffusion node FD111, the second floating diffusion node FD112, and the third floating diffusion node FD113. Here, the charge generated and overflowed from the third photodiode PD3a may be stored in the first capacitor C1.

Between t137 and t139, the pixel PX11 may output signals (i.e., image signals) corresponding to the first floating diffusion node FD111, the second floating diffusion node FD112, and the third floating diffusion node FD113, and the fourth floating diffusion node FD114, as the pixel signal VOUT.

At t139, the reset control signal RGS may transition from the low level L to the high level H. At t141, the reset control signal RGS may transition from the high level H to the low level L.

The first floating diffusion node FD111, the second floating diffusion node FD112, the third floating diffusion node FD113, and the fourth floating diffusion node FD114 may be reset to the power source voltage VPIX by the gain control signal DRGS and the reset control signal RGS of the high level H.

Between t141 and t143, the pixel PX11 may output signals (i.e., reset signals) corresponding to the first floating diffusion node FD111, the second floating diffusion node FD112, the third floating diffusion node FD113, and the fourth floating diffusion node FD114, as the pixel signal VOUT.

At t143, the reset control signal RGS may transition from the low level L to the high level H.

At t145, the second switch control signal SW12 and the first switch control signal SW11 may transition from the high level H to the low level L.

At t147, the selection control signal SEL may transition from the high level H to the low level L.

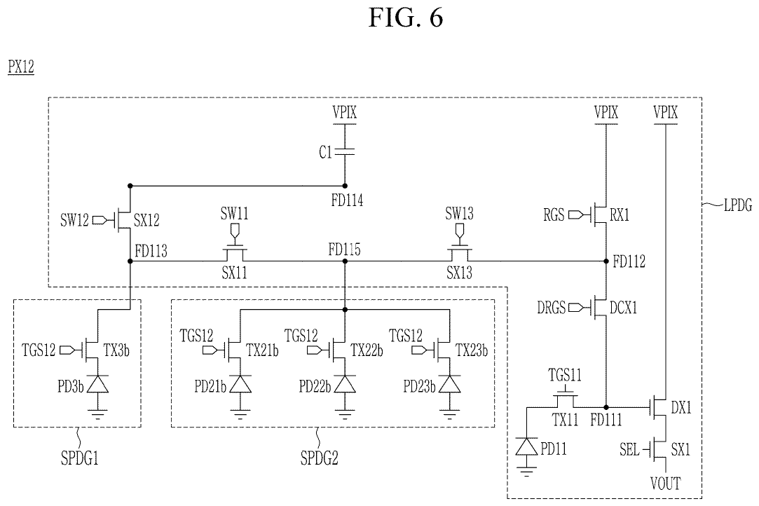

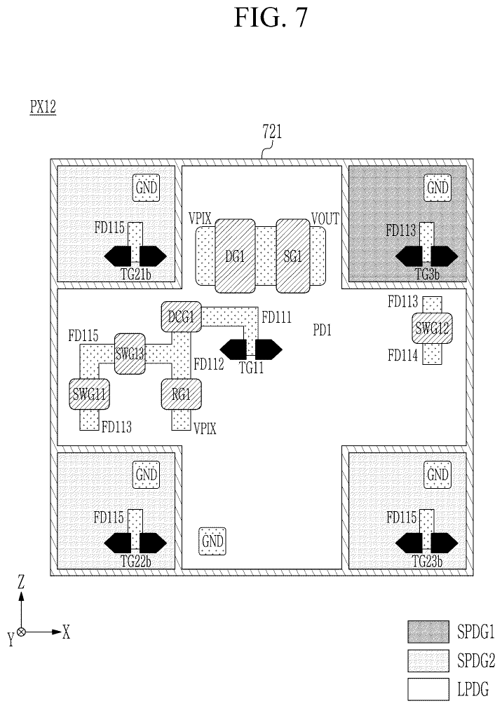

FIG. 6 is a circuit diagram of a pixel according to one or more embodiments. Specifically, FIG. 6 is a circuit diagram of the pixel PX of FIG. 1. FIG. 7 is a top plan view schematically showing the pixel according to FIG. 6.

Referring to FIG. 6, a pixel PX12 may include the first small photodiode group SPDG1 including a third photodiode PD3b, the second small photodiode group SPDG2 including a plurality of second photodiodes PD21b, PD22b, and PD23b, and the large photodiode group LPDG including the first photoelectric element PD11.

The plurality of second photodiodes PD21b, PD22b, and PD23b and the third photodiode PD3b may be a small photodiode, and the first photoelectric element PD11 may be a large photodiode.

The large photodiode group LPDG may include a plurality of transistors, for example, the first transmission transistor TX11, the reset transistor RX1, the driving transistor DX1, the selection transistor SX1, the gain control transistor DCX1, the first switch transistor SX11, the second switch transistor SX12, a third switch transistor SX13, and the first capacitor C1. Control signals TGS11, RGS, SEL, DRGS, SW11, SW12, and SW13 may be applied to the large photodiode group LPDG. In one or more embodiments, the control signals may be generated by the row driver 130 (see FIG. 1) based on the control of the timing controller 120.

The third switch transistor SX13 may be connected between the second floating diffusion node FD112 and a fifth floating diffusion node FD115. The third switch transistor SX13 may be controlled by a third switch control signal SW13. When the third switch transistor SX13 is turned on, the second floating diffusion node FD112 and the fifth floating diffusion node FD115 may be connected.

The first small photodiode group SPDG1 may include a third transmission transistor TX3b. The control signal TGS12 may be applied to the first small photodiode group SPDG1.

The second small photodiode group SPDG2 may include a plurality of transistors, for example, second transmission transistors TX21b, TX22b, and TX23b. The control signal TGS12 may be applied to the second small photodiode group SPDG2.

Referring to FIG. 7 together, the pixel PX12 may include the first small photodiode group SPDG1, the second small photodiode group SPDG2, the large photodiode group LPDG.

As shown in FIG. 7, a separation pattern 721 may be disposed on the outer surface of the pixel PX12, and between the first small photodiode group SPDG1, the second small photodiode group SPDG2, and the large photodiode group LPDG of the pixel PX12.

The separation pattern 721 may divide regions of the first small photodiode group SPDG1, the second small photodiode group SPDG2, and the large photodiode group LPDG, on a two-dimensional plane.

The first switch gate SWG11, the second switch gate SWG12, a third switch gate SWG13, the reset gate RG1, the gain control gate DRG1, the driving gate DG1, the selection gate SG1, the first transfer gate TG11 may be formed within the large photodiode group LPDG. The first switch gate SWG11 may be a gate of the first switch transistor SX11. The second switch gate SWG12 may be a gate of the second switch transistor SX12. The third switch gate SWG13 may be a gate of the third switch transistor SX13. The reset gate RG1 may be a gate of the reset transistor RX1. The gain control gate DRG1 may be a gate of the gain control transistor DCX1. The driving gate DG1 may be a gate of the driving transistor DX1. The selection gate SG1 may be a gate of the selection transistor SX1. The first transfer gate TG11 may be a gate of the first transmission transistor TX11.

In addition, the first floating diffusion node FD111, the second floating diffusion node FD112, the third floating diffusion node FD113, the fourth floating diffusion node FD114, and the fifth floating diffusion node FD115 may be formed within the large photodiode group LPDG. The ground region GND and the power source voltage region VPIX, the pixel voltage region VOUT may be formed within the large photodiode group LPDG.

In one or more embodiments, the second switch gate SWG12 may be formed in the first small photodiode group SPDG1 rather than the large photodiode group LPDG. Meanwhile, the present disclosure is not limited thereto, and the plurality of transistors within the pixel may be formed in various arrangements.

A third transfer gate TG3b may be formed within the first small photodiode group SPDG1. The third transfer gate TG3b may be a gate of the third transmission transistor TX3b. The third floating diffusion node FD113 may be formed within the first small photodiode group SPDG1. In addition, the ground region GND may be formed within the first small photodiode group SPDG1.

A plurality of second transfer gates TG21b, TG22b, and TG23b may be formed within the second small photodiode group SPDG2. Each of the plurality of second transfer gates TG21b, TG22b, and TG23b may be gates of plurality of second transmission transistors TX21b, TX22b, and TX23b, respectively. The fifth floating diffusion node FD115 may be formed within the second small photodiode group SPDG2. In addition, the ground region GND may be formed within the second small photodiode group SPDG2.

The large photodiode group LPDG may be formed in the central region of the pixel PX12, and the first small photodiode group SPDG1 and the second small photodiode group SPDG2 may be disposed symmetrically to each other in a peripheral area (e.g., edge) of the pixel PX12. The first small photodiode group SPDG1 and the second small photodiode group SPDG2 may have a rectangular shape. As shown in FIG. 7, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

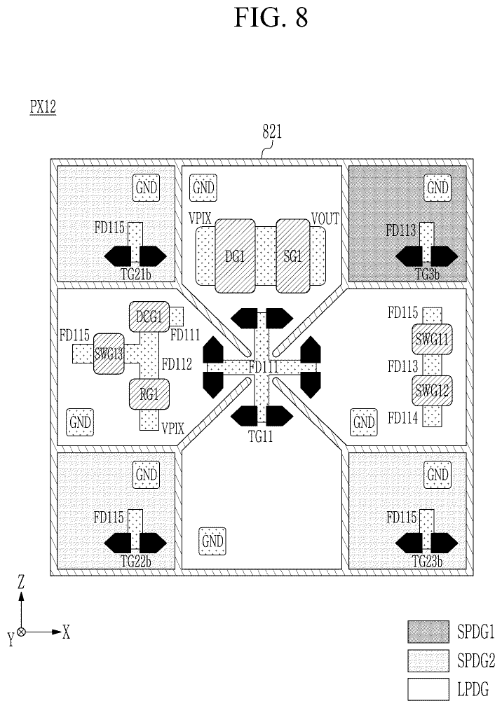

FIG. 8 is a top plan view showing an example of the pixel according to FIG. 6.

As shown in FIG. 8, a separation pattern 821 may be disposed on the outer surface of the pixel PX12, and between the first small photodiode group SPDG1, the second small photodiode group SPDG2, and the large photodiode group LPDG of the pixel PX12.

The separation pattern 821 may divide regions of the first small photodiode group SPDG1, the second small photodiode group SPDG2, and the large photodiode group LPDG, on a two-dimensional plane.

The large photodiode group LPDG may be formed in the central region of the pixel PX12, and the first small photodiode group SPDG1 and the second small photodiode group SPDG2 may be disposed symmetrically to each other in a peripheral area (e.g., edge) of the pixel PX12. The first small photodiode group SPDG1 and the second small photodiode group SPDG2 may have a rectangular shape.

As shown in FIG. 8, the separation pattern 821 may be disposed to extend in the third direction crossing the first direction X and the second direction Z from an edge of the first small photodiode group SPDG1 and the second small photodiode group SPDG2. The separation pattern 821 may be symmetrical about the first direction X and/or the second direction Z.

The first floating diffusion node FD111 may be formed at a center of the large photodiode group LPDG. In addition, the first transfer gate TG11 may be disposed to extend from the center of the large photodiode group LPDG in the first direction X and the second direction Z.

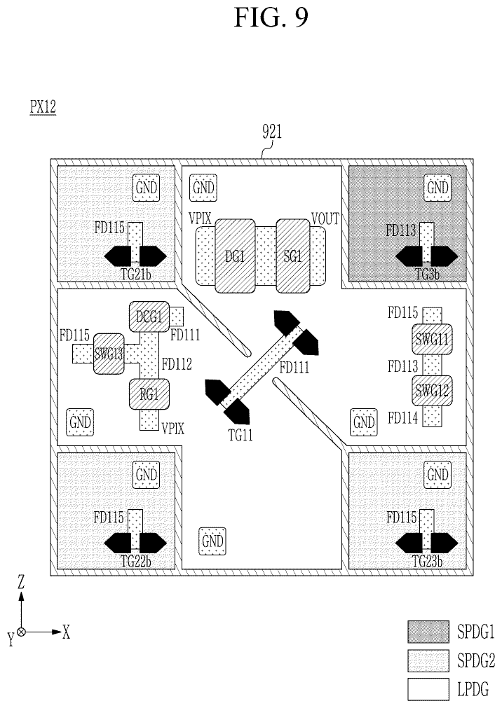

FIG. 9 is a top plan view schematically showing the pixel according to FIG. 6.

As shown in FIG. 9, a separation pattern 921 may be disposed on the outer surface of the pixel PX12, and between the first small photodiode group SPDG1, the second small photodiode group SPDG2, and the large photodiode group LPDG of the pixel PX12.

The separation pattern 921 may divide regions of the first small photodiode group SPDG1, the second small photodiode group SPDG2, and the large photodiode group LPDG, on a two-dimensional plane.

The large photodiode group LPDG may be formed in the central region of the pixel PX12, and may be disposed symmetrically to each other in a peripheral area (e.g., edge) of the first small photodiode group SPDG1 and the second small photodiode group SPDG2 the pixel PX12. The first small photodiode group SPDG1 and the second small photodiode group SPDG2 may have a rectangular shape.

As shown in FIG. 9, the separation pattern 921 may be disposed to extend in the third direction crossing the first direction X and the second direction Z from some edges among the edges of the first small photodiode group SPDG1 and the second small photodiode group SPDG2. The separation pattern 921 may be symmetrical about the first direction X and/or the second direction Z.

The first floating diffusion node FD111 may be formed at the center of the large photodiode group LPDG. In addition, the first transfer gate TG11 may be disposed to extend from the center of the large photodiode group LPDG in a direction perpendicular to the third direction.

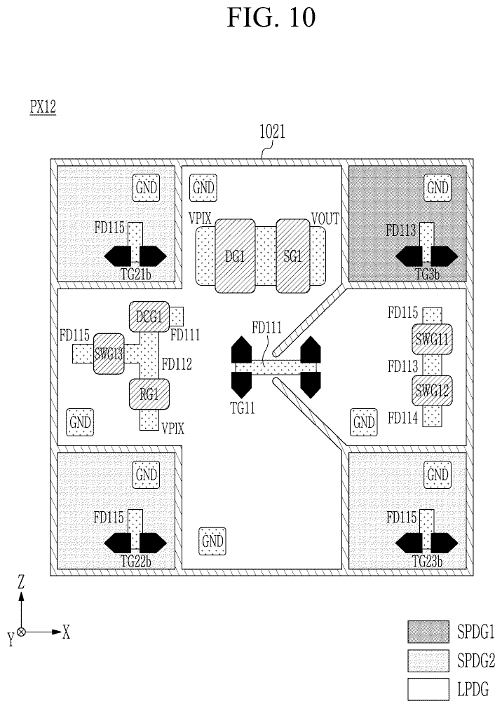

FIG. 10 is a top plan view schematically showing the pixel according to FIG. 6.

As shown in FIG. 10, a separation pattern 1021 may be disposed on the outer surface of the pixel PX12, and between the first small photodiode group SPDG1, the second small photodiode group SPDG2, and the large photodiode group LPDG of the pixel PX12.

The separation pattern 1021 may divide regions of the first small photodiode group SPDG1, the second small photodiode group SPDG2, and the large photodiode group LPDG, on a two-dimensional plane.

The large photodiode group LPDG may be formed in the central region of the pixel PX12, and the first small photodiode group SPDG1 and the second small photodiode group SPDG2 may be disposed symmetrically to each other in a peripheral area (e.g., edge) of the pixel PX12. The first small photodiode group SPDG1 and the second small photodiode group SPDG2 may have a rectangular shape.

As shown in FIG. 10, the separation pattern 1021 may be disposed to extend in the third direction crossing the first direction X and the second direction Z from some edges among the edges of the first small photodiode group SPDG1 and the second small photodiode group SPDG2. The separation pattern 1021 may be symmetrical about the first direction X. Meanwhile, the present disclosure is not limited thereto, and the separation pattern 1021 may be symmetrical about the second direction Z.

The first floating diffusion node FD111 may be formed at the center of the large photodiode group LPDG. In addition, the first transfer gate TG11 may be disposed to extend from the center of the large photodiode group LPDG in the first direction X.

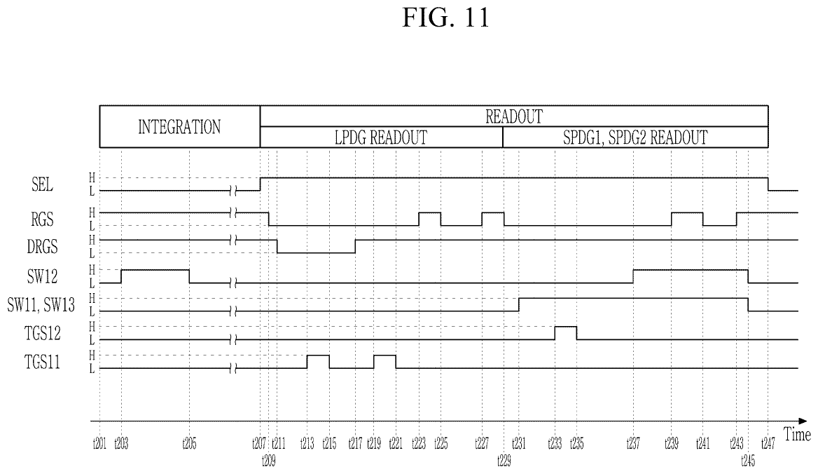

FIG. 11 is a timing diagram showing the operation of the image sensor according to one or more embodiments.

In more detail, FIG. 11 may be one scan period for driving the pixel PX12 according to FIG. 6. One scan period may sequentially include the integration period INTEGRATION and the readout period READOUT.

The integration period INTEGRATION (i.e., t201 to t207) may be a period where the first photoelectric element PD11, the plurality of second photodiodes PD21a, PD22a, and PD23a, and the third photodiode PD3a are exposed to light and thereby generates charges. Unless otherwise stated, the description of the integration period INTEGRATION (i.e., t101 to t107) made with reference to FIG. 5 may be equally applied to the integration period INTEGRATION (i.e., t201 to t207).

The readout period READOUT (i.e., t207 to t247) may be a period where the pixel signal VOUT generated by the pixel PX11 is transferred to the readout circuit 150 (see FIG. 1). The readout period READOUT may include the large photodiode group readout period LPDG READOUT (i.e., t207 to t229), the first and second small photodiode group readout periods SPDG1 and SPDG2 READOUT (i.e., t229 to t247). Unless otherwised stated, the description of the readout period READOUT (i.e., t107 to t147) made with reference to FIG. 5 may be equally applied to the readout period READOUT (i.e., t207 to t247).

Meanwhile, the third switch control signal SW13 may be the same as the first switch control signal SW11.

In more detail, at t231, the first switch control signal SW11 and the third switch control signal SW13 may transition from the low level L to the high level H.

Since the first switch transistor SX11 and the third switch transistor SX13 is turned on by the first switch control signal SW11 and the third switch control signal SW13 of the high level H, the second floating diffusion node FD112, the third floating diffusion node FD113, and the fifth floating diffusion node FD115 may be connected.

Between t231 and t233, the pixel PX12 may output signals (i.e., reset signals) corresponding to the first floating diffusion node FD111, the second floating diffusion node FD112, the third floating diffusion node FD113, and the fifth floating diffusion node FD115, as the pixel signal VOUT.

Thereafter, at t245, the first switch control signal SW11, the second switch control signal SW12, and the third switch control signal SW13 may transition from the high level H to the low level L.

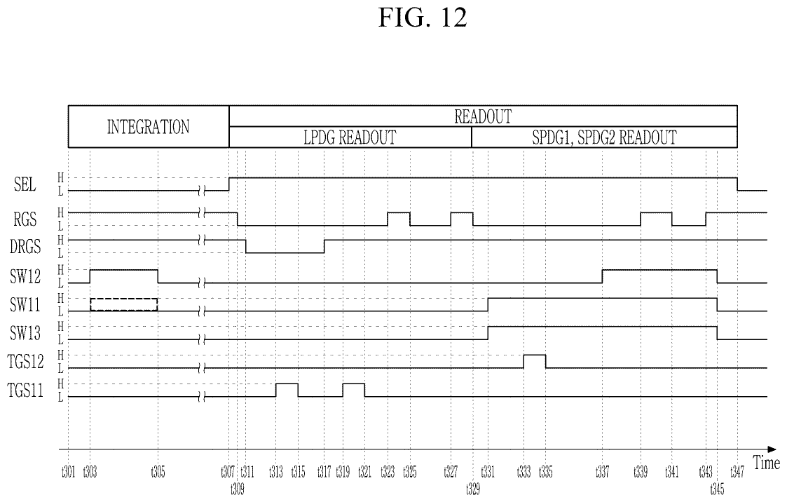

FIG. 12 is a timing diagram showing the operation of the image sensor according to one or more embodiments.

In more detail, FIG. 12 may be one scan period for driving the pixel PX12 according to FIG. 6. One scan period may sequentially include the integration period INTEGRATION and the readout period READOUT.

The integration period INTEGRATION (i.e., t301 to t307) may be a period where the first photoelectric element PD11, the plurality of second photodiodes PD21a, PD22a, and PD23a, and the third photodiode PD3a are exposed to light and thereby generates charges. Unless otherwise stated, the description of the integration period INTEGRATION (i.e., t101 to t107) made with reference to FIG. 5 may be equally applied to the integration period INTEGRATION (i.e., t301 to t307).

Meanwhile, at t303, the first switch control signal SW11 may transition from the low level L to the high level H.

The first switch control signal SW11 and while the second switch control signal SW12 maintains the high level H, the third floating diffusion node FD113, the fourth floating diffusion node FD114, and the fifth floating diffusion node FD115 may be connected. Accordingly, the overflowed photoelectric charge among the photoelectric charge generated from the plurality of second photodiodes PD21a, PD22a, and PD23a, and the third photodiode PD3a may be accumulated in the first capacitor C1.

At t305, the first switch control signal SW11 and the second switch control signal SW12 may transition from the high level H to the low level L.the readout period READOUT (i.e., t307 to t347) may be a period where the pixel signal VOUT generated by the pixel PX11 is transferred to the readout circuit 150 (see FIG. 1). The readout period READOUT may include the large photodiode group readout period LPDG READOUT (i.e., t307 to t329), the first and second small photodiode group readout periods SPDG1 and SPDG2 READOUT (i.e., t329 to t347). Unless otherwise stated, the description of the readout period READOUT (i.e., t107 to t147) made with reference to FIG. 5 may be equally applied to the readout period READOUT (i.e., t307 to t347).

In the readout period READOUT (i.e., t307 to t347), the third switch control signal SW13 may be the same as the first switch control signal SW11.

In more detail, at t331, the first switch control signal SW11 and the third switch control signal SW13 may transition from the low level L to the high level H.

Since the first switch transistor SX11 and the third switch transistor SX13 is turned on by the first switch control signal SW11 and the third switch control signal SW13 of the high level H, the second floating diffusion node FD112, the third floating diffusion node FD113, and the fifth floating diffusion node FD115 may be connected.

Between t331 and t333, the pixel PX12 may output signals (i.e., reset signals) corresponding to the first floating diffusion node FD111, the second floating diffusion node FD112, the third floating diffusion node FD113, and the fifth floating diffusion node FD115, as the pixel signal VOUT.

Meanwhile, the plurality of second photodiodes PD21a, PD22a, and PD23a and the charge generated and overflow from the third photodiode PD3a may be stored in the first capacitor C1.

Between t337 and t339, the pixel PX12 may output signals (i.e., image signals) corresponding to the first floating diffusion node FD111, the second floating diffusion node FD112, and the third floating diffusion node FD113, the fourth floating diffusion node FD114, and the fifth floating diffusion node FD115, as the pixel signal VOUT.

Thereafter, at t345, at the first switch control signal SW11, the second switch control signal SW12, and the third switch control signal SW13 may transition from the high level H to the low level L.

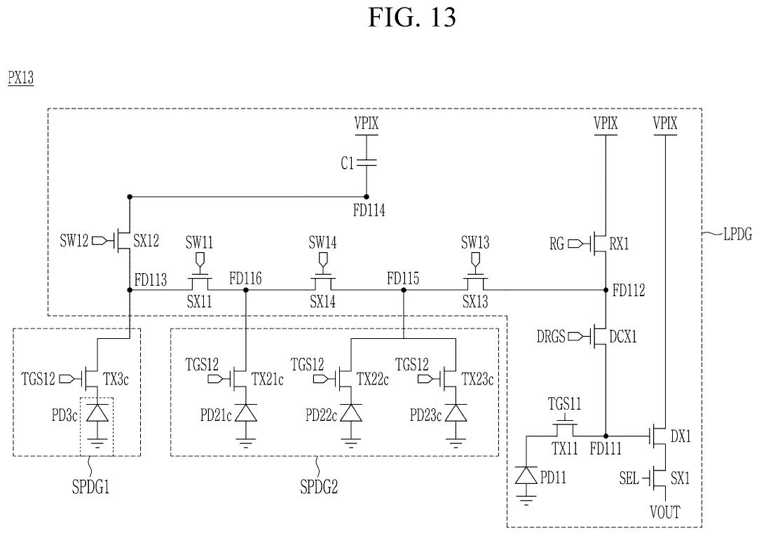

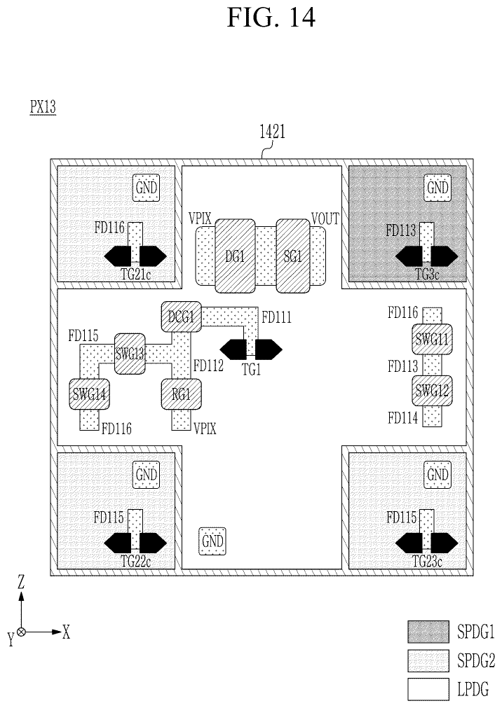

FIG. 13 is a circuit diagram of a pixel according to one or more embodiments. Specifically, FIG. 13 is a circuit diagram of the pixel PX of FIG. 1. FIG. 14 is a top plan view schematically showing the pixel according to FIG. 13.

Referring to FIG. 13, a pixel PX13 may include the first small photodiode group SPDG1 including a third photodiode PD3c, the second small photodiode group SPDG2 including a plurality of second photodiodes PD21c, PD22c, and PD23c, and the large photodiode group LPDG including the first photoelectric element PD11.

The plurality of second photodiodes PD21c, PD22c, and PD23c and the third photodiode PD3c may be a small photodiode, and the first photoelectric element PD11 may be a large photodiode.

The large photodiode group LPDG may include a plurality of transistors, for example, the first transmission transistor TX11, the reset transistor RX1, the driving transistor DX1, the selection transistor SX1, the gain control transistor DCX1, the first switch transistor SX11, the second switch transistor SX12, the third switch transistor SX13, a fourth switch transistor SX14, and the first capacitor C1. Control signals TGS11, RGS, SEL, DRGS, SW11, SW12, SW13, and SW14 may be applied to the large photodiode group LPDG. In one or more embodiments, the control signals may be generated by the row driver 130 (see FIG. 1) based on the control of the timing controller 120.

The fourth switch transistor SX14 may be connected between the fifth floating diffusion node FD115 and a sixth floating diffusion node FD116. The fourth switch transistor SX14 may be controlled by a fourth switch control signal SW14. When the fourth switch transistor SX14 is turned on, the fifth floating diffusion node FD115 and the sixth floating diffusion node FD116 may be connected.

The first small photodiode group SPDG1 may include a third transmission transistor TX3c. The control signal TGS12 may be applied to the first small photodiode group SPDG1.

The second small photodiode group SPDG2 may include a plurality of transistors, for example, second transmission transistors TX21c, TX22c, and TX23c. The control signal TGS12 may be applied to the second small photodiode group SPDG2.

Referring to FIG. 14 together, the pixel PX13 may include the first small photodiode group SPDG1, the second small photodiode group SPDG2, the large photodiode group LPDG.

As shown in FIG. 14, a separation pattern 1421 may be disposed on the outer surface of the pixel PX13, and between the first small photodiode group SPDG1, the second small photodiode group SPDG2, and the large photodiode group LPDG of the pixel PX13.

The separation pattern 1421 may divide regions of the first small photodiode group SPDG1, the second small photodiode group SPDG2, and the large photodiode group LPDG, on a two-dimensional plane.

The first switch gate SWG11, the second switch gate SWG12, the third switch gate SWG13, a fourth switch gate SWG14, the reset gate RG1, the gain control gate DRG1, the driving gate DG1, the selection gate SG1, the first transfer gate TG11 may be formed within the large photodiode group LPDG. The first switch gate SWG11 may be a gate of the first switch transistor SX11. The second switch gate SWG12 may be a gate of the second switch transistor SX12. The third switch gate SWG13 may be a gate of the third switch transistor SX13. The fourth switch gate SWG14 may be a gate of the fourth switch transistor SX14. The reset gate RG1 may be a gate of the reset transistor RX1. The gain control gate DRG1 may be a gate of the gain control transistor DCX1. The driving gate DG1 may be a gate of the driving transistor DX1. The selection gate SG1 may be a gate of the selection transistor SX1. The first transfer gate TG11 may be a gate of the first transmission transistor TX11.

In addition, the first floating diffusion node FD111, the second floating diffusion node FD112, the third floating diffusion node FD113, the fourth floating diffusion node FD114, the fifth floating diffusion node FD115, and the sixth floating diffusion node FD116 may be formed within the large photodiode group LPDG. The ground region GND and the power source voltage region VPIX, the pixel voltage region VOUT may be formed within the large photodiode group LPDG.

In one or more embodiments, the second switch gate SWG12 may be formed in the first small photodiode group SPDG1 rather than the large photodiode group LPDG. Meanwhile, the present disclosure is not limited thereto, and the plurality of transistors within the pixel may be formed in various arrangements.

A third transfer gate TG3c may be formed within the first small photodiode group SPDG1. The third transfer gate TG3c may be a gate of the third transmission transistor TX3c. The third floating diffusion node FD113 may be formed within the first small photodiode group SPDG1. In addition, the ground region GND may be formed within the first small photodiode group SPDG1.

A plurality of second transfer gates TG21c, TG22c, and TG23c may be formed within the second small photodiode group SPDG2. Each of the plurality of second transfer gates TG21c, TG22c, and TG23c may be gates of plurality of second transmission transistors TX21c, TX22c, and TX23c, respectively. The sixth floating diffusion node FD116 may be formed in a region where the second transmission transistor TX21c is formed among the second small photodiode group SPDG2. Meanwhile, the fifth floating diffusion node FD115 may be formed in a region where the second transmission transistors TX22c and TX23c are formed among the second small photodiode group SPDG2. In addition, the ground region GND may be formed within the second small photodiode group SPDG2.

The large photodiode group LPDG may be formed in the central region of the pixel PX13, and the first small photodiode group SPDG1 and the second small photodiode group SPDG2 may be disposed symmetrically to each other in a peripheral area (e.g., edge) of the pixel PX13. The first small photodiode group SPDG1 and the second small photodiode group SPDG2 may have a rectangular shape. As shown in FIG. 14, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

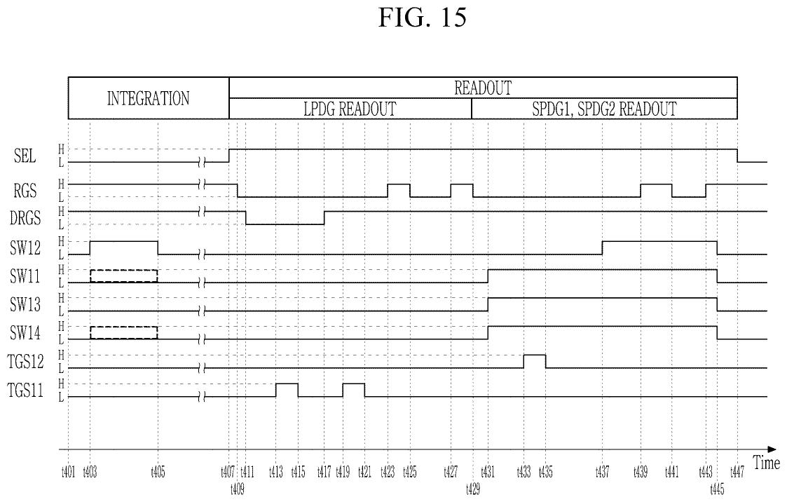

FIG. 15 is a timing diagram showing the operation of the image sensor according to one or more embodiments.

In more detail, FIG. 15 may be one scan period for driving the pixel PX13 according to FIG. 13. One scan period may sequentially include the integration period INTEGRATION and the readout period READOUT.

The integration period INTEGRATION (i.e., t401 to t407) may be a period where the first photoelectric element PD11, the plurality of second photodiodes PD21c, PD22c, and PD23c, and the third photodiode PD3c are exposed to light and thereby generates charges. Unless otherwise stated, the description of the integration period INTEGRATION (i.e., t301 to t307) made with reference to FIG. 12 may be equally applied to the integration period INTEGRATION (i.e., t401 to t407).

Meanwhile, at t403, at the fourth switch control signal SW14 may transition from the low level L to the high level H.

While the first switch control signal SW11, the second switch control signal SW12, and the fourth switch control signal SW14 maintain the high level H, the third floating diffusion node FD113, the fourth floating diffusion node FD114, the fifth floating diffusion node FD115, and the sixth floating diffusion node FD116 may be connected. Accordingly, the overflowed photoelectric charge among the photoelectric charge generated from the plurality of second photodiodes PD21c, PD22c, and PD23c, and the third photodiode PD3c may be accumulated in the first capacitor C1.

At t405, at the first switch control signal SW11, the second switch control signal SW12, and the fourth switch control signal SW14 may transition from the high level H to the low level L. The readout period READOUT (i.e., t407 to t447) may be a period where the pixel signal VOUT generated by the pixel PX11 is transferred to the readout circuit 150 (see FIG. 1). The readout period READOUT may include the large photodiode group readout period LPDG READOUT (i.e., t407 to t429), the first and second small photodiode group readout periods SPDG1 and SPDG2 READOUT (i.e., t429 to t447). Unless otherwise stated, the description of the readout period READOUT (i.e., t307 to t347) made with reference to FIG. 12 may be equally applied to the readout period READOUT (i.e., t407 to t447).

In the readout period READOUT (i.e., t407 to t447), the fourth switch control signal SW14 may be the same as the first switch control signal SW11.

In more detail, at t431, at the first switch control signal SW11, the third switch control signal SW13, and the fourth switch control signal SW14 may transition from the low level L to the high level H.

Since the first switch transistor SX11, the thirs switch transistor SX13, and the fourth switch transistor SX14 are turned on by the first switch control signal SW11, the third switch control signal SW13, and the fourth switch control signal SW14 of the high level H, the second floating diffusion node FD112, the third floating diffusion node FD113, the fifth floating diffusion node FD115, and the sixth floating diffusion node FD116 may be connected.

Between t431 and t433, the pixel PX13 may output signals (i.e., reset signals) corresponding to the first floating diffusion node FD111, the second floating diffusion node FD112, the third floating diffusion node FD113, the fifth floating diffusion node FD115, and the sixth floating diffusion node FD116, as the pixel signal VOUT.

Meanwhile, the charge generated and overflowed from the plurality of second photodiodes PD21c, PD22c, and PD23c and the third photodiode PD3c may be stored in the first capacitor C1.

Between t437 and t439, the pixel PX13 may output signals (i.e., image signals) corresponding to the first floating diffusion node FD111, the second floating diffusion node FD112, and the third floating diffusion node FD113, the fourth floating diffusion node FD114, the fifth floating diffusion node FD115, and the sixth floating diffusion node FD116, as the pixel signal VOUT.

Thereafter, at t445, at the first switch control signal SW11, the second switch control signal SW12, the third switch control signal SW13, and the fourth switch control signal SW14 may transition from the high level H to the low level L.

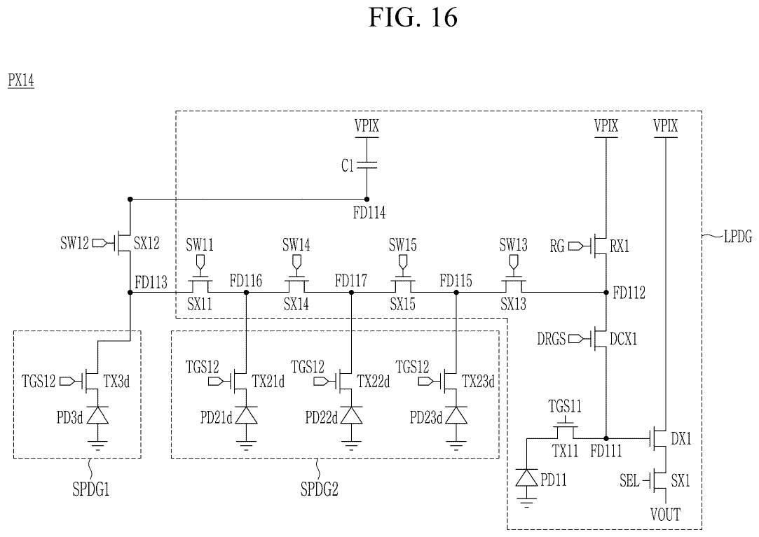

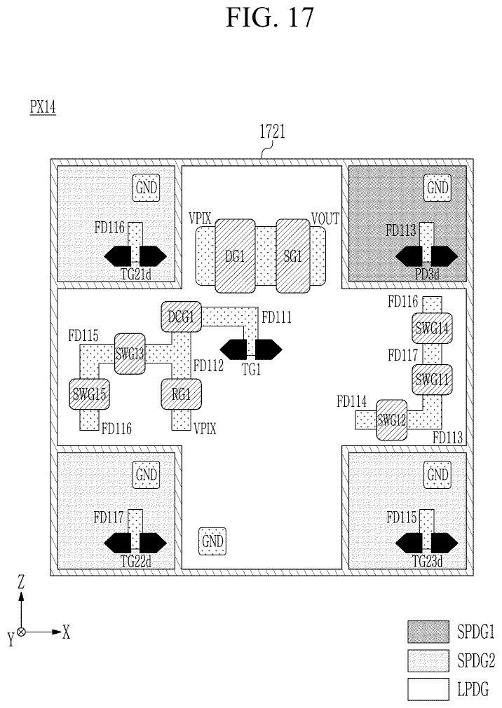

FIG. 16 is a circuit diagram of a pixel according to one or more embodiments. Specifically, FIG. 16 is a circuit diagram of the pixel PX of FIG. 1. FIG. 17 is a top plan view schematically showing the pixel according to FIG. 16.

Referring to FIG. 16, a pixel PX14 may include the first small photodiode group SPDG1 including a third photodiode PD3d, the second small photodiode group SPDG2 including a plurality of second photodiodes PD21d, PD22d, and PD23d, and the large photodiode group LPDG including the first photoelectric element PD11.

The plurality of second photodiodes PD21d, PD22d, and PD23d and the third photodiode PD3d may be a small photodiode, and the first photoelectric element PD11 may be a large photodiode.

The large photodiode group LPDG may include a plurality of transistors, for example, the first transmission transistor TX11, the reset transistor RX1, the driving transistor DX1, the selection transistor SX1, the gain control transistor DCX1, the first switch transistor SX11, the second switch transistor SX12, the third switch transistor SX13, the fourth switch transistor SX14, a fifth switch transistor SX15, and the first capacitor C1. Control signals TGS11, RGS, SEL, DRGS, SW11, SW12, SW13, SW14, and SW15 may be applied to the large photodiode group LPDG. In one or more embodiments, the control signals may be generated by the row driver 130 (see FIG. 1) based on the control of the timing controller 120.

The fifth switch transistor SX15 may be connected between the fifth floating diffusion node FD115 and a seventh floating diffusion node FD117. The fifth switch transistor SX15 may be controlled by a fifth switch control signal SW15. When the fifth switch transistor SX15 is turned on, the fifth floating diffusion node FD115 and the seventh floating diffusion node FD117 may be connected.

The first small photodiode group SPDG1 may include a third transmission transistor TX3d. The control signal TGS12 may be applied to the first small photodiode group SPDG1.

The second small photodiode group SPDG2 may include a plurality of transistors, for example, second transmission transistors TX21d, TX22d, and TX23d. The control signal TGS12 may be applied to the second small photodiode group SPDG2.

Referring to FIG. 17 together, the pixel PX14 may include the first small photodiode group SPDG1, the second small photodiode group SPDG2, the large photodiode group LPDG.

As shown in FIG. 17, a separation pattern 1721 may be disposed on the outer surface of the pixel PX14, and between the first small photodiode group SPDG1, the second small photodiode group SPDG2, and the large photodiode group LPDG of the pixel PX14.

The separation pattern 1421 may divide regions of the first small photodiode group SPDG1, the second small photodiode group SPDG2, and the large photodiode group LPDG, on a two-dimensional plane.

The first switch gate SWG11, the second switch gate SWG12, the third switch gate SWG13, the fourth switch gate SWG14, a fifth switch gate SWG15, the reset gate RG1, the gain control gate DRG1, the driving gate DG1, the selection gate SG1, the first transfer gate TG11 may be formed within the large photodiode group LPDG. The first switch gate SWG11 may be a gate of the first switch transistor SX11. The second switch gate SWG12 may be a gate of the second switch transistor SX12. The third switch gate SWG13 may be a gate of the third switch transistor SX13. The fourth switch gate SWG14 may be a gate of the fourth switch transistor SX14. The fifth switch gate SWG15 may be a gate of the fifth switch transistor SX15. The reset gate RG1 may be a gate of the reset transistor RX1. The gain control gate DRG1 may be a gate of the gain control transistor DCX1. The driving gate DG1 may be a gate of the driving transistor DX1. The selection gate SG1 may be a gate of the selection transistor SX1. The first transfer gate TG11 may be a gate of the first transmission transistor TX11.

In addition, the first floating diffusion node FD111, the second floating diffusion node FD112, the third floating diffusion node FD113, the fourth floating diffusion node FD114, the fifth floating diffusion node FD115, the sixth floating diffusion node FD116, and the seventh floating diffusion node FD117 may be formed within the large photodiode group LPDG. The ground region GND and the power source voltage region VPIX, the pixel voltage region VOUT may be formed within the large photodiode group LPDG.

In one or more embodiments, the second switch gate SWG12 may be formed in the first small photodiode group SPDG1 rather than the large photodiode group LPDG. Meanwhile, the present disclosure is not limited thereto, and the plurality of transistors within the pixel may be formed in various arrangements.

A third transfer gate TG3d may be formed within the first small photodiode group SPDG1. The third transfer gate TG3d may be a gate of the third transmission transistor TX3d. The third floating diffusion node FD113 may be formed within the first small photodiode group SPDG1. In addition, the ground region GND may be formed within the first small photodiode group SPDG1.

A plurality of second transfer gates TG21d, TG22d, and TG23d may be formed within the second small photodiode group SPDG2. Each of the plurality of second transfer gates TG21d, TG22d, and TG23d may be gates of plurality of second transmission transistors TX21d, TX22d, and TX23d, respectively. The sixth floating diffusion node FD116 may be formed in a region where the second transmission transistor TX21d is formed among the second small photodiode group SPDG2. The seventh floating diffusion node FD117 may be formed in a region where the second transmission transistor TX22d is formed among the second small photodiode group SPDG2. The fifth floating diffusion node FD115 may be formed in a region where the second transmission transistor TX23d is formed among the second small photodiode group SPDG2. In addition, the ground region GND may be formed within the second small photodiode group SPDG2.

The large photodiode group LPDG may be formed in the central region of the pixel PX14, and the first small photodiode group SPDG1 and the second small photodiode group SPDG2 may be disposed symmetrically to each other in a peripheral area (e.g., edge) of the pixel PX14. The first small photodiode group SPDG1 and the second small photodiode group SPDG2 may have a rectangular shape. As shown in FIG. 17, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

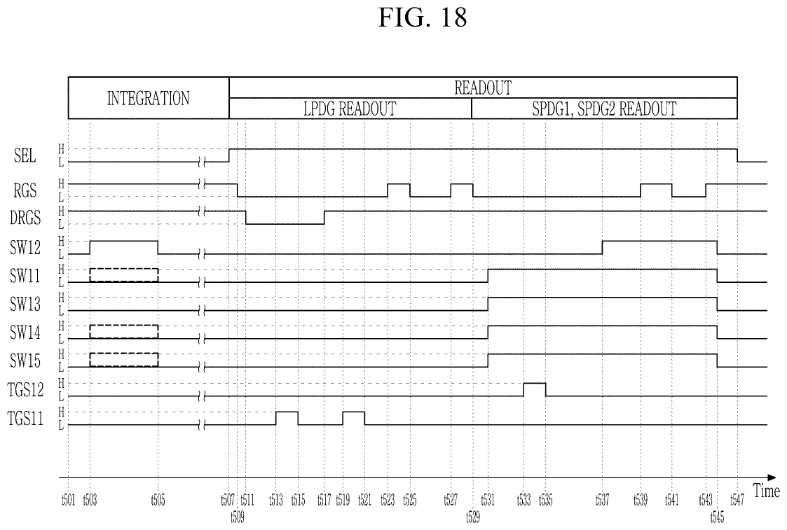

FIG. 18 is a timing diagram showing the operation of the image sensor according to one or more embodiments.

In more detail, FIG. 18 may be one scan period for driving the pixel PX14 according to FIG. 16. One scan period may sequentially include the integration period INTEGRATION and the readout period READOUT.

The integration period INTEGRATION (i.e., t501 to t507) may be a period where the first photoelectric element PD11, the plurality of second photodiodes PD21d, PD22d, and PD23d, and the third photodiode PD3d are exposed to light and thereby generates charges. Unless otherwise stated, the description of the integration period INTEGRATION (i.e., t401 to t407) made with reference to FIG. 15 may be equally applied to the integration period INTEGRATION (i.e., t501 to t507).

Meanwhile, at t503, at the fifth switch control signal SW15 may transition from the low level L to the high level H.

While the first switch control signal SW11, the second switch control signal SW12, the fourth switch control signal SW14, the fifth switch control signal SW15 maintain the high level H, the third floating diffusion node FD113, the fourth floating diffusion node FD114, the fifth floating diffusion node FD115, the sixth floating diffusion node FD116, and the seventh floating diffusion node FD117 may be connected. Accordingly, the overflowed photoelectric charge among the photoelectric charge generated from the plurality of second photodiodes PD21d, PD22d, and PD23d, and the third photodiode PD3d may be accumulated in the first capacitor C1.

At t505, at the first switch control signal SW11, the second switch control signal SW12, the fourth switch control signal SW14, and the fifth switch control signal SW15 may transition from the high level H to the low level L. The readout period READOUT (i.e., t507 to t547) may be a period where the pixel signal VOUT generated by the pixel PX11 is transferred to the readout circuit 150 (see FIG. 1). The readout period READOUT may include the large photodiode group readout period LPDG READOUT (i.e., t507 to t529), the first and second small photodiode group readout periods SPDG1 and SPDG2 READOUT (i.e., t529 to t547). Unless otherwise stated, the description of the readout period READOUT (i.e., t407 to t447) made with reference to FIG. 15 may be equally applied to the readout period READOUT (i.e., t507 to t547).

In the readout period READOUT (i.e., t507 to t547), the fifth switch control signal SW15 may be the same as the first switch control signal SW11.

In more detail, at t531, at the first switch control signal SW11, the third switch control signal SW13, the fourth switch control signal SW14, and the fifth switch control signal SW15 may transition from the low level L to the high level H.

Since the first switch transistor SX11, the thirs switch transistor SX13, the fourth switch transistor SX14, and a fourth switch transistor SX15 are turned on by the first switch control signal SW11, the third switch control signal SW13, the fourth switch control signal SW14, and the fifth switch control signal SW15 of the high level H, the second floating diffusion node FD112, the third floating diffusion node FD113, the fifth floating diffusion node FD115, the sixth floating diffusion node FD116, and the seventh floating diffusion node FD117 may be connected.

Between t531 and t533, the pixel PX14 may output signals (i.e., reset signals) corresponding to the first floating diffusion node FD111, the second floating diffusion node FD112, the third floating diffusion node FD113, the fifth floating diffusion node FD115, the sixth floating diffusion node FD116, and the seventh floating diffusion node FD117, as the pixel signal VOUT.

Meanwhile, the charge generated and overflowed from the plurality of second photodiodes PD21d, PD22d, and PD23d and the third photodiode PD3d may be stored in the first capacitor C1.

Between t537 and t539, the pixel PX14 may output signals (i.e., image signals) corresponding to the first floating diffusion node FD111, the second floating diffusion node FD112, and the third floating diffusion node FD113, the fourth floating diffusion node FD114, the fifth floating diffusion node FD115, the sixth floating diffusion node FD116, and the seventh floating diffusion node FD117, as the pixel signal VOUT.

Thereafter, at t545, at the first switch control signal SW11, the second switch control signal SW12, the third switch control signal SW13, the fourth switch control signal SW14, and the fifth switch control signal SW15 may transition from the high level H to the low level L.

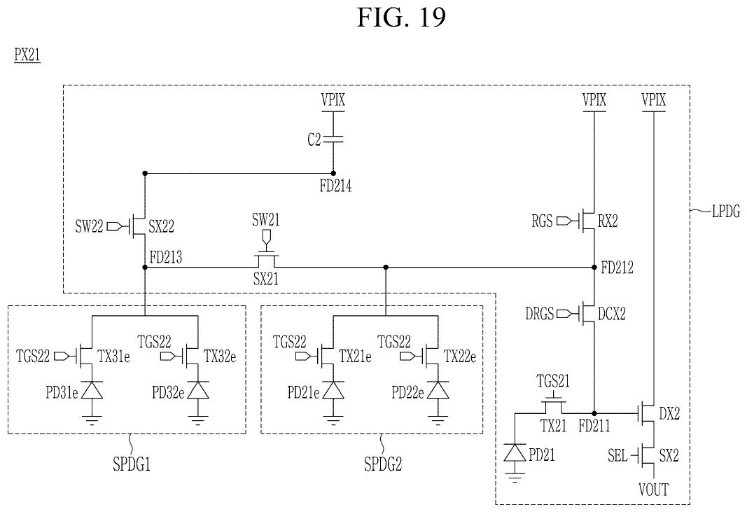

FIG. 19 is a circuit diagram of a pixel according to one or more embodiments. Specifically, FIG. 19 is a circuit diagram of the pixel PX of FIG. 1.

Referring to FIG. 19, a pixel PX21 may include the first small photodiode group SPDG1 including a plurality of third photodiodes PD31e and PD32e, the second small photodiode group SPDG2 including a plurality of second photodiodes PD21e and PD22e, and the large photodiode group LPDG including a first photoelectric element PD21.

The plurality of second photodiodes PD21e and PD22e and the plurality of third photodiodes PD31e and PD32e may be a small photodiode, and the first photoelectric element PD21 may be a large photodiode.

The large photodiode group LPDG may include a plurality of transistors, for example, a first transmission transistor TX21, a reset transistor RX2, a driving transistor DX2, a selection transistor SX2, a gain control transistor DCX2, a first switch transistor SX21, a second switch transistor SX22, and a second capacitor C2. Control signals TGS21, RGS, SEL, DRGS, SW21, and SW22 may be applied to the large photodiode group LPDG. In one or more embodiments, the control signals may be generated by the row driver 130 (see FIG. 1) based on the control of the timing controller 120.

The first transmission transistor TX21 may be connected between the first photoelectric element PD21 and a first floating diffusion node FD211. The first transmission transistor TX21 may be controlled by a first transmission control signal TGS21. When the first transmission transistor TX21 is turned on, the charge generated by the first photoelectric element PD21 may be transferred to the first floating diffusion node FD211.

The reset transistor RX2 may be connected between a second floating diffusion node FD212 and the power source voltage line supplying the power source voltage VPIX. The reset transistor RX2 may be controlled by the reset control signal RGS. When the reset transistor RX2 is turned on, the power source voltage VPIX may be applied to the second floating diffusion node FD212, and thereby the second floating diffusion node FD212 may be reset. When the switch transistor SX21 is turned on while the reset transistor RX2 is turned on, a third floating diffusion node FD213 and the second floating diffusion node FD212 may be reset to the power source voltage VPIX. When the switch transistor SX21 and the switch transistor SX22 is turned on while the reset transistor RX2 is turned on, the second floating diffusion node FD212, the third floating diffusion node FD213, and a fourth floating diffusion node FD214 may be reset to the power source voltage VPIX. When the gain control transistor DCX2 is turned on while the reset transistor RX2 is turned on, the first floating diffusion node FD211 and the second floating diffusion node FD212 may be reset to the power source voltage VPIX.

A gate of the driving transistor DX2 may be connected to the first floating diffusion node FD211. A first end of the driving transistor DX2 may be connected to the power source voltage VPIX, and a second end thereof may be connected to a first end of the selection transistor SX2. The driving transistor DX2 may operate as a source-follower amplifier with respect to a voltage of the first floating diffusion node FD211. In response to the voltage of the first floating diffusion node FD211, the driving transistor DX2 may output the pixel voltage VOUT to the column line CL (see FIG. 1) through the selection transistor SX2.

The selection transistor SX2 may be connected to the first end of the driving transistor DX2 and the column line CL, and may be controlled by the selection control signal SEL. When the selection transistor SX2 is turned on, the pixel voltage VOUT output from the driving transistor DX2 may be output to the readout circuit 150 (see FIG. 1) through the column line CL connected to the selection transistor SX2. For example, when the selection transistor SX2 is turned on in the readout operation, a pixel signal including a reset signal corresponding to a reset operation or an image signal corresponding to a charge accumulation operation may be output through the column line CL.

The gain control transistor DCX2 may be connected between the first floating diffusion node FD211 and the second floating diffusion node FD212. The gain control transistor DCX2 may be controlled by the gain control signal DRGS. When the gain control transistor DCX2 is turned on, the first floating diffusion node FD211 and the second floating diffusion node FD212 are connected to each other such that the capacitance may increase, and a conversion gain, which is a ratio of charges converted to voltage may decrease. That is, when a conversion gain transistor DCX2 is turned on, the first photoelectric element PD21 may operate in the low conversion gain (LCG) mode. To the contrary, when the conversion gain transistor DCX2 is turned off, the first photoelectric element PD21 may operate in the high conversion gain (HCG) mode.

The first switch transistor SX21 may be connected between the second floating diffusion node FD212 and the third floating diffusion node FD213. The first switch transistor SX21 may be controlled by a first switch control signal SW21. When the first switch transistor SX21 is turned on, the first floating diffusion node FD211 and the third floating diffusion node FD213 may be connected.

The second switch transistor SX22 may be connected between the third floating diffusion node FD213 and the fourth floating diffusion node FD214. The second switch transistor SX22 may be controlled by a second switch control signal SW22. When the second switch transistor SX22 is turned on, the third floating diffusion node FD213 and the fourth floating diffusion node FD214 are connected, so that the second capacitor C2 is connected to the third floating diffusion node FD213, thereby increasing the capacitance.

The second capacitor C2 may be connected between the fourth floating diffusion node FD214 and the power source voltage line supplying the power source voltage VPIX. When the second switch transistor SX22 is turned on while the first switch transistor SX21 is turned on, the second floating diffusion node FD212, the third floating diffusion node FD213, and the fourth floating diffusion node FD214 may be connected to each other, thereby increasing a capacitance of the second floating diffusion node FD212. That is, the second capacitor C2 may be used to adjust the capacitance of the second floating diffusion node FD212. In one or more embodiments, the photoelectric charge generated from the third photodiodes PD31e and PD32e during the integration period may overflow, and the overflowed charge may be accumulated in the second capacitor C2 by passing through the third floating diffusion node FD213 and the fourth floating diffusion node FD214.

The second capacitor C2 may include a lateral overflow integration capacitor (LOFIC). When the second capacitor C2 includes LOFIC, overflowed charges among charges transferred from the first photoelectric element PD21, the second photodiodes PD21e and PD22e, and the third photodiodes PD31e and PD32e to the first floating diffusion node FD211 may be stored. That is, a large amount of charge that overflows may be accumulated into the second capacitor C2 without being discarded.

The first small photodiode group SPDG1 may include a plurality of third transmission transistors TX31e and TX32e. Control signal TGS22 may be applied to the first small photodiode group SPDG1.

The plurality of third transmission transistors TX31e and TX32e may be connected between the plurality of third photodiodes PD31e and PD32e corresponding thereto and the third floating diffusion node FD213. The plurality of third transmission transistors TX31e and TX32e may be controlled by a second transmission control signal TGS22. When the plurality of third transmission transistors TX31e and TX32e are turned on, the charge generated by the third photodiodes PD31e and PD32e may be transferred to the third floating diffusion node FD213.

The second small photodiode group SPDG2 may include a plurality of transistors, for example, second transmission transistors TX21e and TX22e. Control signal TGS22 may be applied to the second small photodiode group SPDG2.

A plurality of second transmission transistors TX21e and TX22e may be connected between the plurality of second photodiodes PD21e and PD22e corresponding thereto and the second floating diffusion node FD212. Each of the plurality of second transmission transistors TX21e and TX22e may be controlled by the second transmission control signal TGS22. When the plurality of second transmission transistors TX21e and TX22e are turned on, the charge generated by the plurality of second photodiodes PD21e and PD22e may be transferred to the second floating diffusion node FD212.

The photoelectric charges generated by the large photodiode group LPDG, the first small photodiode group SPDG1, and the second small photodiode group SPDG2 may be transmitted to and accumulated in at least one among the first floating diffusion node FD211, the second floating diffusion node FD212, the third floating diffusion node FD213, the second capacitor C2. Although not shown in FIG. 19, in each of the first floating diffusion node FD211, the second floating diffusion node FD212, and the third floating diffusion node FD213, a parasitic capacitor (not shown) may be formed, or an actual capacitor element may be connected.

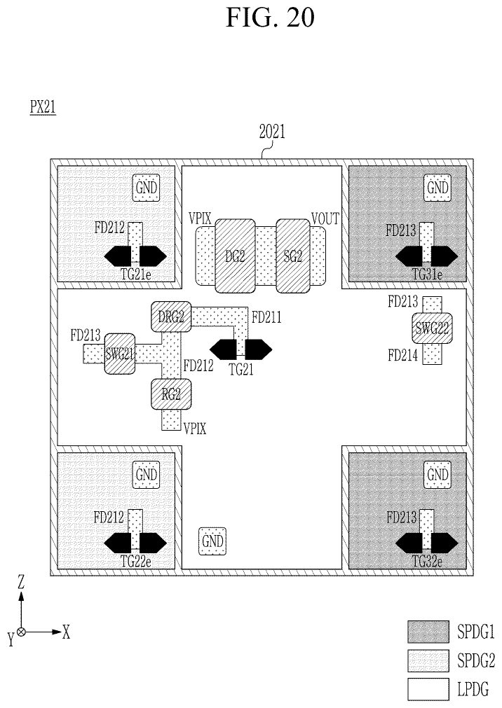

FIG. 20 is a top plan view schematically showing the pixel according to FIG. 19.

Referring to FIG. 20, the pixel PX21 may include the first small photodiode group SPDG1, the second small photodiode group SPDG2, the large photodiode group LPDG.

As shown in FIG. 20, a separation pattern 2021 may be disposed on the outer surface of the pixel PX21, and between the first small photodiode group SPDG1, the second small photodiode group SPDG2, and the large photodiode group LPDG of the pixel PX21.

The separation pattern 2021 may divide regions of the first small photodiode group SPDG1, the second small photodiode group SPDG2, and the large photodiode group LPDG, on a two-dimensional plane.

A first switch gate SWG21, a second switch gate SWG22, a reset gate RG2, a gain control gate DRG2, a driving gate DG2, a selection gate SG2, a first transfer gate TG21 may be formed within the large photodiode group LPDG. The first switch gate SWG21 may be a gate of the first switch transistor SX21. The second switch gate SWG22 may be a gate of the second switch transistor SX22. The reset gate RG2 may be a gate of the reset transistor RX2. The gain control gate DRG2 may be a gate of the gain control transistor DCX2. The driving gate DG2 may be a gate of the driving transistor DX2. The selection gate SG2 may be a gate of the selection transistor SX2. First transfer gate TG21 may be a gate of the first transmission transistor TX21.

In addition, the first floating diffusion node FD211, the second floating diffusion node FD212, the third floating diffusion node FD213, and the fourth floating diffusion node FD214 may be formed within the large photodiode group LPDG. The ground region GND and the power source voltage region VPIX, the pixel voltage region VOUT may be formed within the large photodiode group LPDG.

In one or more embodiments, the second switch gate SWG22 may be formed in the first small photodiode group SPDG1 rather than the large photodiode group LPDG. Meanwhile, the present disclosure is not limited thereto, and the plurality of transistors within the pixel may be formed in various arrangements.

A plurality of third transfer gates TG31e and TG32e may be formed within the first small photodiode group SPDG1. The plurality of third transfer gates TG31e and TG32e may be gates of plurality of third transmission transistors TX31e and TX32e, respectively. The third floating diffusion node FD213 may be formed within the first small photodiode group SPDG1. In addition, the ground region GND may be formed within the first small photodiode group SPDG1.

A plurality of second transfer gates TG21e and TG22e may be formed within the second small photodiode group SPDG2. Each of the plurality of second transfer gates TG21e and TG22e may be gates of plurality of second transmission transistors TX21e and TX22e, respectively. The second floating diffusion node FD212 may be formed within the second small photodiode group SPDG2. In addition, the ground region GND may be formed within the second small photodiode group SPDG2.

The large photodiode group LPDG may be formed in the central region of the pixel PX21, and the first small photodiode group SPDG1 and the second small photodiode group SPDG2 may be disposed symmetrically to each other in a peripheral area (e.g., edge) of the pixel PX21. The first small photodiode group SPDG1 and the second small photodiode group SPDG2 may have a rectangular shape. As shown in FIG. 20, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

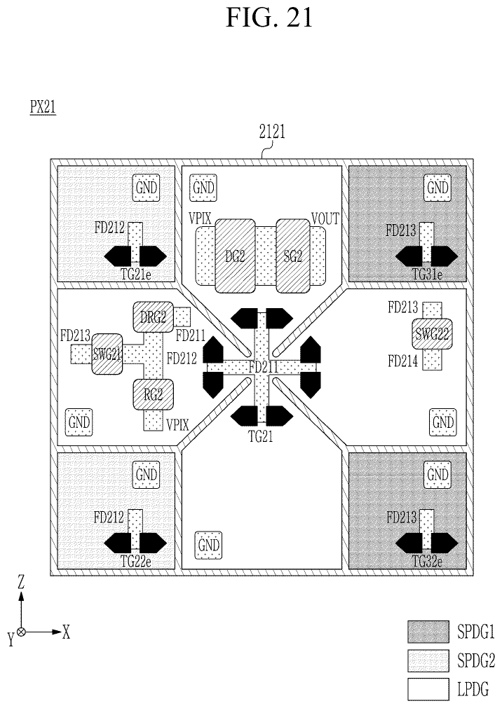

FIG. 21 is a top plan view schematically showing the pixel according to FIG. 19.

As shown in FIG. 21, a separation pattern 2121 may be disposed on the outer surface of the pixel PX21, and between the first small photodiode group SPDG1, the second small photodiode group SPDG2, and the large photodiode group LPDG of the pixel PX21.

The separation pattern 2121 may divide regions of the first small photodiode group SPDG1, the second small photodiode group SPDG2, and the large photodiode group LPDG, on a two-dimensional plane.

The large photodiode group LPDG may be formed in the central region of the pixel PX21, and the first small photodiode group SPDG1 and the second small photodiode group SPDG2 may be disposed symmetrically to each other in a peripheral area (e.g., edge) of the pixel PX21. The first small photodiode group SPDG1 and the second small photodiode group SPDG2 may have a rectangular shape.

As shown in FIG. 21, the separation pattern 2121 may be disposed to extend in the third direction crossing the first direction X and the second direction Z from the edge of the first small photodiode group SPDG1 and the second small photodiode group SPDG2. The separation pattern 2121 may be symmetrical about the first direction X and/or the second direction Z.

The first floating diffusion node FD211 may be formed at the center of the large photodiode group LPDG. In addition, the first transfer gate TG21 may be disposed to extend from the center of the large photodiode group LPDG in the first direction X and the second direction Z.

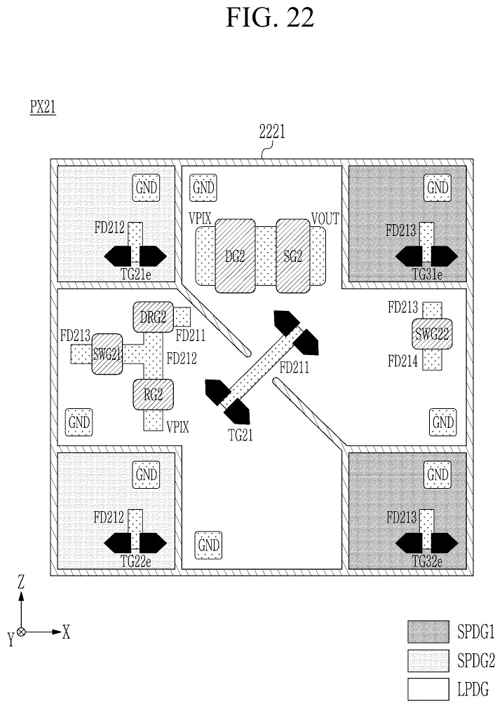

FIG. 22 is a top plan view schematically showing the pixel according to FIG. 19.

As shown in FIG. 22, a separation pattern 2221 may be disposed on the outer surface of the pixel PX21, and between the first small photodiode group SPDG1, the second small photodiode group SPDG2, and the large photodiode group LPDG of the pixel PX21.

The separation pattern 2221 may divide regions of the first small photodiode group SPDG1, the second small photodiode group SPDG2, and the large photodiode group LPDG, on a two-dimensional plane.

The large photodiode group LPDG may be formed in the central region of the pixel PX21, and the first small photodiode group SPDG1 and the second small photodiode group SPDG2 may be disposed symmetrically to each other in a peripheral area (e.g., edge) of the pixel PX21. The first small photodiode group SPDG1 and the second small photodiode group SPDG2 may have a rectangular shape.

As shown in FIG. 22, the separation pattern 2221 may be disposed to extend in the third direction crossing the first direction X and the second direction Z from some edges among the edges of the first small photodiode group SPDG1 and the second small photodiode group SPDG2. The separation pattern 2221 may be symmetrical about the first direction X and/or the second direction Z.

The first floating diffusion node FD211 may be formed at the center of the large photodiode group LPDG. In addition, the first transfer gate TG21 may be disposed to extend from the center of the large photodiode group LPDG in a direction perpendicular to the third direction.

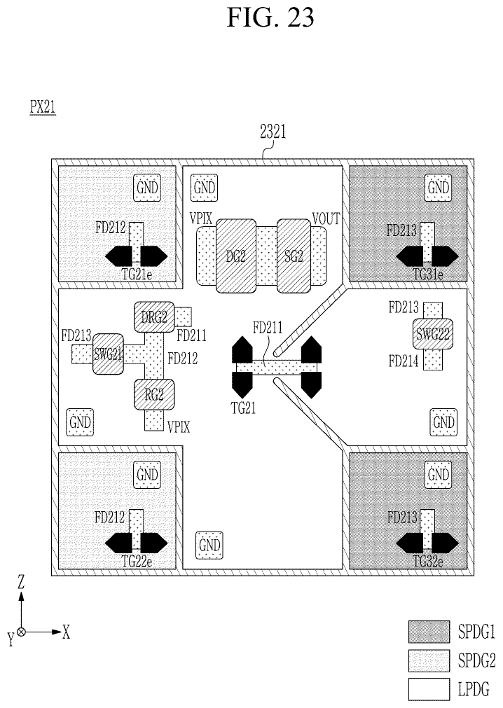

FIG. 23 is a top plan view schematically showing the pixel according to FIG. 19.

As shown in FIG. 23, a separation pattern 2321 may be disposed on the outer surface of the pixel PX21, and between the first small photodiode group SPDG1, the second small photodiode group SPDG2, and the large photodiode group LPDG of the pixel PX21.

The separation pattern 2321 may divide regions of the first small photodiode group SPDG1, the second small photodiode group SPDG2, and the large photodiode group LPDG, on a two-dimensional plane.

The large photodiode group LPDG may be formed in the central region of the pixel PX21, and the first small photodiode group SPDG1 and the second small photodiode group SPDG2 may be disposed symmetrically to each other in a peripheral area (e.g., edge) of the pixel PX21. The first small photodiode group SPDG1 and the second small photodiode group SPDG2 may have a rectangular shape.

As shown in FIG. 23, the separation pattern 2321 may be disposed to extend in the third direction crossing the first direction X and the second direction Z from some edges among the edges of the first small photodiode group SPDG1 and the second small photodiode group SPDG2. The separation pattern 2321 may be symmetrical about the first direction X. Meanwhile, the present disclosure is not limited thereto, and the separation pattern 2321 may be symmetrical about the second direction Z.

The first floating diffusion node FD211 may be formed at the center of the large photodiode group LPDG. In addition, the first transfer gate TG21 may be disposed to extend from the center of the large photodiode group LPDG in the first direction X.

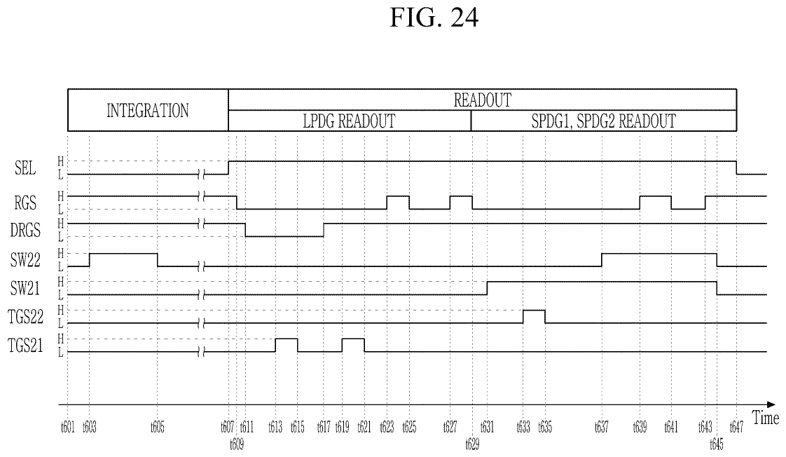

FIG. 24 is a timing diagram showing the operation of the image sensor according to one or more embodiments.

In more detail, FIG. 24 may be one scan period for driving the pixel PX21 according to FIG. 19. One scan period may sequentially include the integration period INTEGRATION and the readout period READOUT.

The integration period INTEGRATION (i.e., t601 to t607) may be a period where the first photoelectric element PD21, the plurality of second photodiodes PD21e and PD22e, and the third photodiodes PD31e and PD32e are exposed to light and thereby generates charges. Unless otherwise stated, the description of the integration period INTEGRATION (i.e., t101 to t107) made with reference to FIG. 5 may be equally applied to the integration period INTEGRATION (i.e., t601 to t607).

The readout period READOUT (i.e., t607 to t647) may be a period where the pixel signal VOUT generated by the pixel PX11 is transferred to the readout circuit 150 (see FIG. 1). The readout period READOUT may include the large photodiode group readout period LPDG READOUT (i.e., t607 to t629), the first and second small photodiode group readout periods SPDG1 and SPDG2 READOUT (i.e., t629 to t647). Unless otherwise stated, the description of the readout period READOUT (i.e., t107 to t147) made with reference to FIG. 5 may be equally applied to the readout period READOUT (i.e., t607 to t647).

Here, the first switch control signal SW21 may be the same as the first switch control signal SW11 of FIG. 5, the second switch control signal SW22 may be the same as the second switch control signal SW12 of FIG. 5, the first transmission control signal TGS21 may be the same as the first transmission control signal TGS11, and the second transmission control signal TGS22 may be the same as the second transmission control signal TGS12.

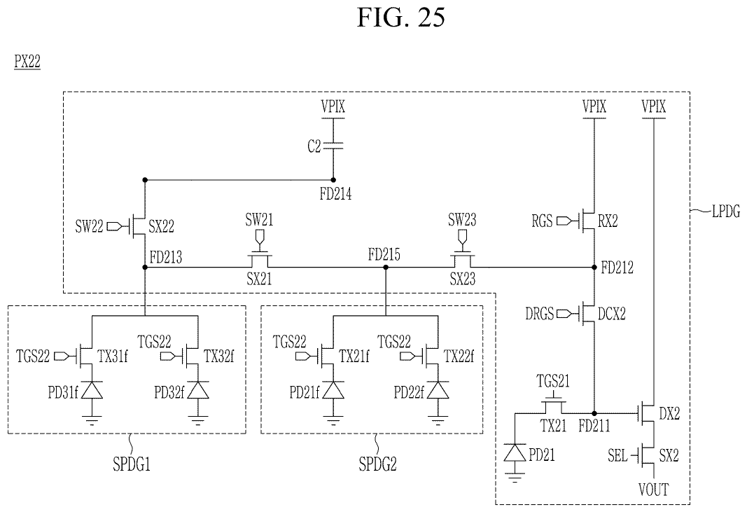

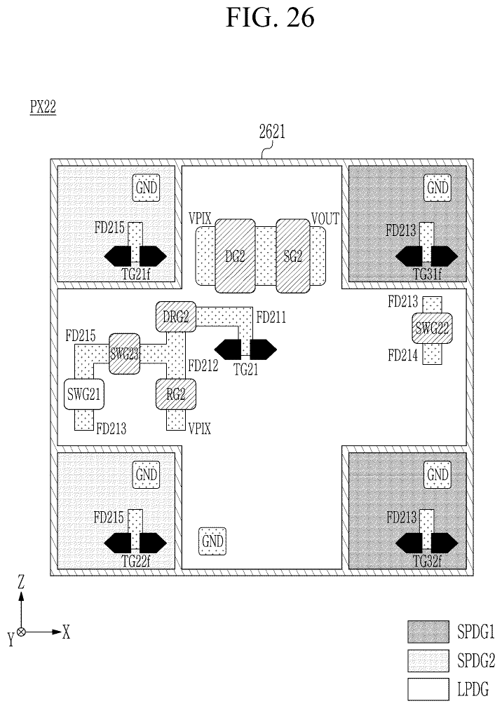

FIG. 25 is a circuit diagram of a pixel according to one or more embodiments. Specifically, FIG. 25 is a circuit diagram of the pixel PX of FIG. 1. FIG. 26 is a top plan view schematically showing the pixel according to FIG. 25.

Referring to FIG. 25, a pixel PX22 may include the first small photodiode group SPDG1 including the third photodiodes PD31f and PD32f, the second small photodiode group SPDG2 including a plurality of second photodiodes PD21f and PD22f, and the large photodiode group LPDG including the first photoelectric element PD21.

The plurality of second photodiodes PD21f and PD22f and the third photodiodes PD31f and PD32f may be a small photodiode, and the first photoelectric element PD21 may be a large photodiode.

The large photodiode group LPDG may include a plurality of transistors, for example, the first transmission transistor TX21, the reset transistor RX2, the driving transistor DX2, the selection transistor SX2, the gain control transistor DCX2, the first switch transistor SX21, the second switch transistor SX22, a third switch transistor SX23, and the second capacitor C2. Control signals TGS21, RGS, SEL, DRGS, SW21, SW22, and SW23 may be applied to the large photodiode group LPDG. In one or more embodiments, the control signals may be generated by the row driver 130 (see FIG. 1) based on the control of the timing controller 120.

The third switch transistor SX23 may be connected between the second floating diffusion node FD212 and a fifth floating diffusion node FD215. The third switch transistor SX23 may be controlled by a third switch control signal SW23. When the third switch transistor SX23 is turned on, the second floating diffusion node FD212 and the fifth floating diffusion node FD215 may be connected.

The first small photodiode group SPDG1 may include a plurality of third transmission transistors TX31f and TX32f. Control signal TGS22 may be applied to the first small photodiode group SPDG1.

The second small photodiode group SPDG2 may include a plurality of transistors, for example, second transmission transistors TX21f and TX22f. Control signal TGS22 may be applied to the second small photodiode group SPDG2.

Referring to FIG. 26 together, the pixel PX22 may include the first small photodiode group SPDG1, the second small photodiode group SPDG2, the large photodiode group LPDG.

As shown in FIG. 26, a separation pattern 2621 may be disposed on the outer surface of the pixel PX22, and between the first small photodiode group SPDG1, the second small photodiode group SPDG2, and the large photodiode group LPDG of the pixel PX22.

The separation pattern 2621 may divide regions of the first small photodiode group SPDG1, the second small photodiode group SPDG2, and the large photodiode group LPDG, on a two-dimensional plane.

The first switch gate SWG21, the second switch gate SWG22, a third switch gate SWG23, the reset gate RG2, the gain control gate DRG2, the driving gate DG2, the selection gate SG2, the first transfer gate TG21 may be formed within the large photodiode group LPDG. The first switch gate SWG21 may be a gate of the first switch transistor SX21. The second switch gate SWG22 may be a gate of the second switch transistor SX22. The third switch gate SWG23 may be a gate of the third switch transistor SX23. The reset gate RG2 may be a gate of the reset transistor RX2. The gain control gate DRG2 may be a gate of the gain control transistor DCX2. The driving gate DG2 may be a gate of the driving transistor DX2. The selection gate SG2 may be a gate of the selection transistor SX2. The first transfer gate TG21 may be a gate of the first transmission transistor TX21.

In addition, the first floating diffusion node FD211, the second floating diffusion node FD212, the third floating diffusion node FD213, the fourth floating diffusion node FD214, and the fifth floating diffusion node FD115 may be formed within the large photodiode group LPDG. The ground region GND and the power source voltage region VPIX, the pixel voltage region VOUT may be formed within the large photodiode group LPDG.

In one or more embodiments, the second switch gate SWG22 may be formed in the first small photodiode group SPDG1 rather than the large photodiode group LPDG. Meanwhile, the present disclosure is not limited thereto, and the plurality of transistors within the pixel may be formed in various arrangements.

A plurality of third transfer gates TG31f and TG32f may be formed within the first small photodiode group SPDG1. The plurality of third transfer gates TG31f and TG32f may be a gate of each of the plurality of third transmission transistors TX31f and TX32f. The third floating diffusion node FD213 may be formed within the first small photodiode group SPDG1. In addition, the ground region GND may be formed within the first small photodiode group SPDG1.

A plurality of second transfer gates TG21f and TG22f may be formed within the second small photodiode group SPDG2. Each of the plurality of second transfer gates TG21f and TG22f may be gates of plurality of second transmission transistors TX21f and TX22f, respectively. The fifth floating diffusion node FD215 may be formed within the second small photodiode group SPDG2. In addition, the ground region GND may be formed within the second small photodiode group SPDG2.

The large photodiode group LPDG may be formed in the central region of the pixel PX21, and the first small photodiode group SPDG1 and the second small photodiode group SPDG2 may be disposed symmetrically to each other in a peripheral area (e.g., edge) of the pixel PX21. The first small photodiode group SPDG1 and the second small photodiode group SPDG2 may have a rectangular shape. As shown in FIG. 20, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

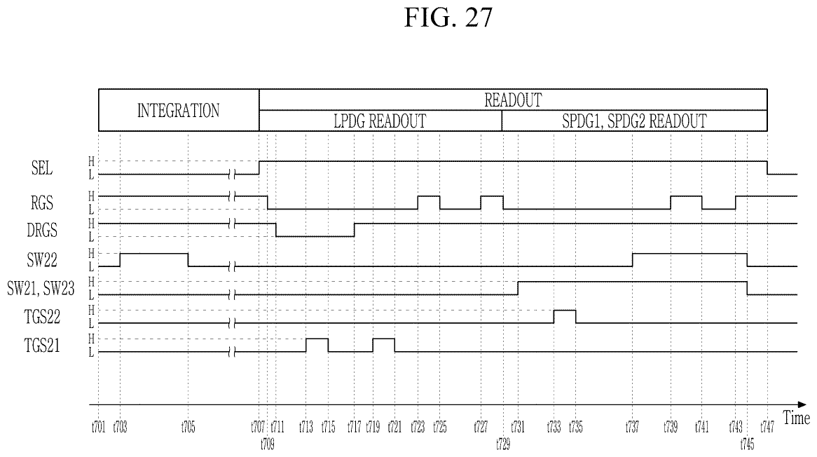

FIG. 27 is a timing diagram showing the operation of the image sensor according to one or more embodiments.

In more detail, FIG. 27 may be one scan period for driving the pixel PX22 according to FIG. 25. One scan period may sequentially include the integration period INTEGRATION and the readout period READOUT.

The integration period INTEGRATION (i.e., t701 to t707) may be a period where the first photoelectric element PD21, the plurality of second photodiodes PD21e and PD22e, and the third photodiodes PD31e and PD32e are exposed to light and thereby generates charges. Unless otherwise stated, the description of the integration period INTEGRATION (i.e., t601 to t607) made with reference to FIG. 24 may be equally applied to the integration period INTEGRATION (i.e., t701 to t707).

The readout period READOUT (i.e., t707 to t747) may be a period where the pixel signal VOUT generated by the pixel PX11 is transferred to the readout circuit 150 (see FIG. 1). The readout period READOUT may include the large photodiode group readout period LPDG READOUT (i.e., t707 to t729), the first and second small photodiode group readout periods SPDG1 and SPDG2 READOUT (i.e., t729 to t747). Unless otherwise stated, the description of the readout period READOUT (i.e., t607 to t647) made with reference to FIG. 24 may be equally applied to the readout period READOUT (i.e., t707 to t747).

Meanwhile, the third switch control signal SW23 may be the same as the first switch control signal SW21.

In more detail, at t731, at the first switch control signal SW21 and the third switch control signal SW23 may transition from the low level L to the high level H.

Since the first switch transistor SX21 and the third switch transistor SX23 is turned on by the first switch control signal SW21 and the third switch control signal SW23 of the high level H, the second floating diffusion node FD212, the third floating diffusion node FD213, and the fifth floating diffusion node FD215 may be connected.

Between t731 and t733, the pixel PX22 may output signals (i.e., reset signals) corresponding to the first floating diffusion node FD211, the second floating diffusion node FD212, the third floating diffusion node FD213, and the fifth floating diffusion node FD215, as the pixel signal VOUT.

Thereafter, at t745, at the first switch control signal SW21, the second switch control signal SW22, and the third switch control signal SW23 may transition from the high level H to the low level L.

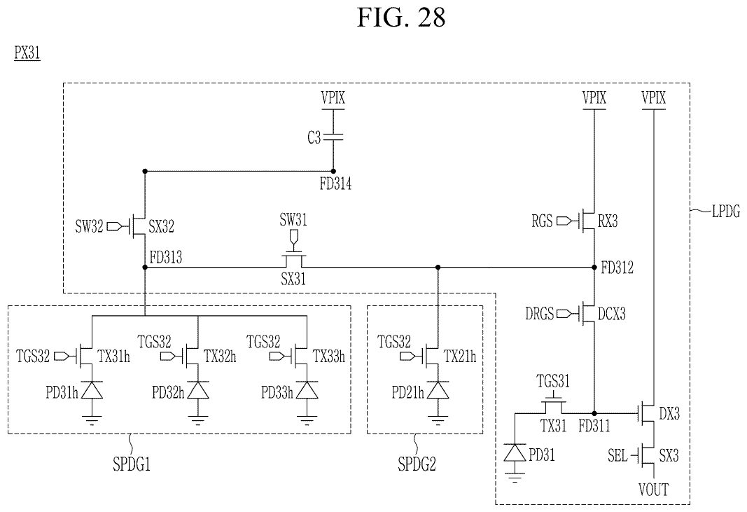

FIG. 28 is a circuit diagram of a pixel according to one or more embodiments. Specifically, FIG. 28 is a circuit diagram of the pixel PX of FIG. 1.

Referring to FIG. 28, a pixel PX31 may include the first small photodiode group SPDG1 including a plurality of third photodiodes PD31h, PD32h, and PD33h, the second small photodiode group SPDG2 including a second photodiode PD21h, and the large photodiode group LPDG including a first photoelectric element PD31.

The second photodiode PD21h and the plurality of third photodiodes PD31h, PD32h, and PD33h may be a small photodiode, and the first photoelectric element PD31 may be a large photodiode.

The large photodiode group LPDG may include a plurality of transistors, for example, a first transmission transistor TX31, a reset transistor RX3, a driving transistor DX3, a selection transistor SX3, a gain control transistor DCX3, a first switch transistor SX31, a second switch transistor SX32, and a third capacitor C3. Control signals TGS31, RGS, SEL, DRGS, SW31, and SW32 may be applied to the large photodiode group LPDG. In one or more embodiments, the control signals may be generated by the row driver 130 (see FIG. 1) based on the control of the timing controller 120.

The first transmission transistor TX31 may be connected between the first photoelectric element PD31 and a first floating diffusion node FD311. The first transmission transistor TX31 may be controlled by a first transmission control signal TGS31. When the first transmission transistor TX31 is turned on, the charge generated by the first photoelectric element PD31 may be transferred to the first floating diffusion node FD311.

The reset transistor RX3 may be connected between a second floating diffusion node FD312 and the power source voltage line supplying the power source voltage VPIX. The reset transistor RX3 may be controlled by the reset control signal RGS. When the reset transistor RX3 is turned on, the power source voltage VPIX may be applied to the second floating diffusion node FD312, and thereby the second floating diffusion node FD312 may be reset. When the switch transistor SX31 is turned on while the reset transistor RX3 is turned on, a third floating diffusion node FD313 and the second floating diffusion node FD312 may be reset to the power source voltage VPIX. When the switch transistor SX31 and the switch transistor SX32 is turned on while the reset transistor RX3 is turned on, the second floating diffusion node FD312, the third floating diffusion node FD313, and a fourth floating diffusion node FD314 may be reset to the power source voltage VPIX. When the gain control transistor DCX3 is turned on while the reset transistor RX3 is turned on, the first floating diffusion node FD311 and the second floating diffusion node FD312 may be reset to the power source voltage VPIX.

A gate of the driving transistor DX3 may be connected to the first floating diffusion node FD311. A first end of the driving transistor DX3 may be connected to the power source voltage VPIX, and a second end thereof may be connected to a first end of the selection transistor SX3. The driving transistor DX3 may operate as a source-follower amplifier with respect to a voltage of the first floating diffusion node FD311. In response to the voltage of the first floating diffusion node FD311, the driving transistor DX3 may output the pixel voltage VOUT to the column line CL (see FIG. 1) through the selection transistor SX3.

The selection transistor SX3 may be connected to the first end of the driving transistor DX3 and the column line CL, and may be controlled by the selection control signal SEL. When the selection transistor SX3 is turned on, the pixel voltage VOUT output from the driving transistor DX3 may be output to the readout circuit 150 (see FIG. 1) through the column line CL connected to the selection transistor SX3. For example, when the selection transistor SX3 is turned on in the readout operation, a pixel signal including a reset signal corresponding to a reset operation or an image signal corresponding to a charge accumulation operation may be output through the column line CL.

The gain control transistor DCX3 may be connected between the first floating diffusion node FD311 and the second floating diffusion node FD312. The gain control transistor DCX3 may be controlled by the gain control signal DRGS. When the gain control transistor DCX3 is turned on, the first floating diffusion node FD311 and the second floating diffusion node FD312 are connected to each other such that the capacitance may increase, and a conversion gain, which is a ratio of charges converted to voltage may decrease. That is, when a conversion gain transistor DCX3 is turned on, the first photoelectric element PD31 may operate in the low conversion gain (LCG) mode. To the contrary, when the conversion gain transistor DCX3 is turned off, the first photoelectric element PD31 may operate in the high conversion gain (HCG) mode.

The first switch transistor SX31 may be connected between the second floating diffusion node FD312 and the third floating diffusion node FD313. The first switch transistor SX31 may be controlled by a first switch control signal SW31. When the first switch transistor SX31 is turned on, the first floating diffusion node FD311 and the third floating diffusion node FD313 may be connected.

The second switch transistor SX32 may be connected between the third floating diffusion node FD313 and the fourth floating diffusion node FD314. The second switch transistor SX32 may be controlled by a second switch control signal SW32. When the second switch transistor SX32 is turned on, the third floating diffusion node FD313 and the fourth floating diffusion node FD314 are connected, so that the third capacitor C3 is connected to the third floating diffusion node FD313, thereby increasing the capacitance.

The third capacitor C3 may be connected between the fourth floating diffusion node FD314 and the power source voltage line supplying the power source voltage VPIX. When the second switch transistor SX32 is turned on while the first switch transistor SX31 is turned on, the second floating diffusion node FD312, the third floating diffusion node FD313, and the fourth floating diffusion node FD314 may be connected to each other, thereby increasing a capacitance of the second floating diffusion node FD312. That is, the third capacitor C3 may be used to adjust the capacitance of the second floating diffusion node FD312. In one or more embodiments, the photoelectric charge generated from the third photodiodes PD31h, PD32h, and PD33h during the integration period may overflow, and the overflowed charge may be accumulated in the third capacitor C3 by passing through the third floating diffusion node FD313 and the fourth floating diffusion node FD314.

The third capacitor C3 may include a lateral overflow integration capacitor (LOFIC). When the third capacitor C3 includes LOFIC, overflowed charges among charges transferred from the first photoelectric element PD31, the second photodiode PD21h, and the third photodiodes PD31h, PD32h, and PD33h to the first floating diffusion node FD311 may be stored. That is, a large amount of charge that overflows may be accumulated into the third capacitor C3 without being discarded.

The first small photodiode group SPDG1 may include a plurality of third transmission transistors TX31h, TX32h, and TX33h. Control signal TGS32 may be applied to the first small photodiode group SPDG1.

The plurality of third transmission transistors TX31h, TX32h, and TX33h may be connected between the plurality of third photodiodes PD31h, PD32h, and PD33h corresponding thereto and the third floating diffusion node FD313. The plurality of third transmission transistors TX31h, TX32h, and TX33h may be controlled by a second transmission control signal TGS32. When the plurality of third transmission transistors TX31h, TX32h, and TX33h are turned on, the charge generated by the third photodiodes PD31h, PD32h, and PD33h may be transferred to the third floating diffusion node FD313.

The second small photodiode group SPDG2 may include a plurality of transistors, for example, a second transmission transistor TX21h. Control signal TGS32 may be applied to the second small photodiode group SPDG2.

The second transmission transistor TX21h may be connected between the second photodiode PD21h corresponding thereto and the second floating diffusion node FD312. The second transmission transistor TX21h may be controlled by the second transmission control signal TGS32. When the second transmission transistor TX21h is turned on, the charge generated by the second photodiode PD21h may be transferred to the second floating diffusion node FD312.

The photoelectric charges generated by the large photodiode group LPDG, the first small photodiode group SPDG1, and the second small photodiode group SPDG2 may be transmitted to and accumulated in at least one among the first floating diffusion node FD311, the second floating diffusion node FD312, the third floating diffusion node FD313, the third capacitor C3. Although not shown in FIG. 28, in each of the first floating diffusion node FD311, the second floating diffusion node FD312, and the third floating diffusion node FD313, a parasitic capacitor (not shown) may be formed, or an actual capacitor element may be connected.

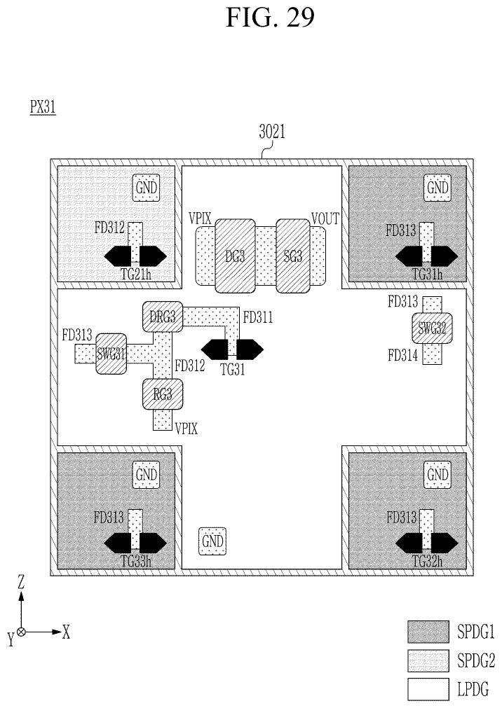

FIG. 29 is a top plan view schematically showing the pixel according to FIG. 28.

Referring to FIG. 29, the pixel PX31 may include the first small photodiode group SPDG1, the second small photodiode group SPDG2, the large photodiode group LPDG.

As shown in FIG. 29, a separation pattern 3021 may be disposed on the outer surface of the pixel PX31, and between the first small photodiode group SPDG1, the second small photodiode group SPDG2, and the large photodiode group LPDG of the pixel PX31.

The separation pattern 3021 may divide regions of the first small photodiode group SPDG1, the second small photodiode group SPDG2, and the large photodiode group LPDG, on a two-dimensional plane.

A first switch gate SWG31, a second switch gate SWG32, a reset gate RG3, a gain control gate DRG3, a driving gate DG3, a selection gate SG3, a first transfer gate TG31 may be formed within the large photodiode group LPDG. The first switch gate SWG31 may be a gate of the first switch transistor SX31. The second switch gate SWG32 may be a gate of the second switch transistor SX32. The reset gate RG3 may be a gate of the reset transistor RX3. The gain control gate DRG3 may be a gate of the gain control transistor DCX3. The driving gate DG3 may be a gate of the driving transistor DX3. The selection gate SG3 may be a gate of the selection transistor SX3. The first transfer gate TG31 may be a gate of the first transmission transistor TX31.

In addition, the first floating diffusion node FD311, the second floating diffusion node FD312, the third floating diffusion node FD313, and the fourth floating diffusion node FD314 may be formed within the large photodiode group LPDG. The ground region GND and the power source voltage region VPIX, the pixel voltage region VOUT may be formed within the large photodiode group LPDG.

In one or more embodiments, the second switch gate SWG32 may be formed in the first small photodiode group SPDG1 rather than the large photodiode group LPDG. Meanwhile, the present disclosure is not limited thereto, and the plurality of transistors within the pixel may be formed in various arrangements.

A plurality of third transfer gates TG31h, TG32h, and TG33h may be formed within the first small photodiode group SPDG1. The plurality of third transfer gates TG31h, TG32h, and TG33h may be gates of plurality of third transmission transistors TX31h, TX32h, and TX33h, respectively. The third floating diffusion node FD313 may be formed within the first small photodiode group SPDG1. In addition, the ground region GND may be formed within the first small photodiode group SPDG1.

A second transfer gate TG21h may be formed within the second small photodiode group SPDG2. The second transfer gate TG21h may be a gate of the second transmission transistor TX21h. The second floating diffusion node FD312 may be formed within the second small photodiode group SPDG2. In addition, the ground region GND may be formed within the second small photodiode group SPDG2.

The large photodiode group LPDG may be formed in the central region of the pixel PX31, and the first small photodiode group SPDG1 and the second small photodiode group SPDG2 may be disposed symmetrically to each other in a peripheral area (e.g., edge) of the pixel PX31. The first small photodiode group SPDG1 and the second small photodiode group SPDG2 may have a rectangular shape. As shown in FIG. 29, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

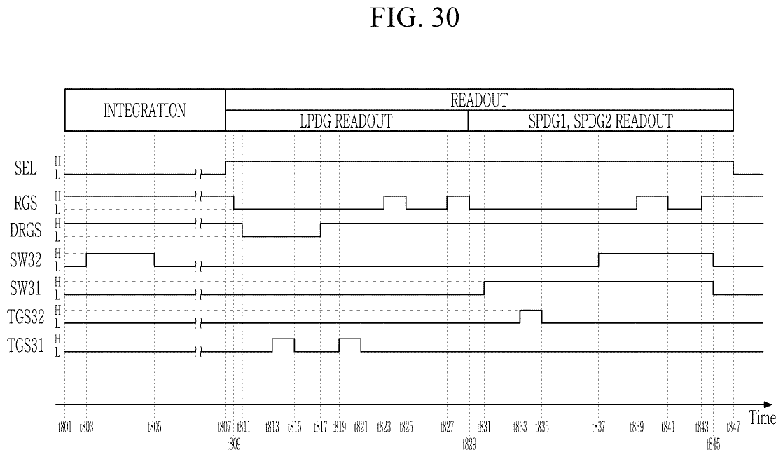

FIG. 30 is a timing diagram showing the operation of the image sensor according to one or more embodiments.

In more detail, FIG. 30 may be one scan period for driving the pixel PX31 according to FIG. 28. One scan period may sequentially include the integration period INTEGRATION and the readout period READOUT.

The integration period INTEGRATION (i.e., t801 to t807) may be a period where the first photoelectric element PD31, the second photodiode PD21h, and the third photodiodes PD31h, PD32h, and PD33h are exposed to light and thereby generates charges. Unless otherwise stated, the description of the integration period INTEGRATION (i.e., t101 to t107) made with reference to FIG. 5 may be equally applied to the integration period INTEGRATION (i.e., t801 to t807).

The readout period READOUT (i.e., t807 to t847) may be a period where the pixel signal VOUT generated by the pixel PX11 is transferred to the readout circuit 150 (see FIG. 1). The readout period READOUT may include the large photodiode group readout period LPDG READOUT (i.e., t807 to t829), the first and second small photodiode group readout periods SPDG1 and SPDG2 READOUT (i.e., t829 to t847). Unless otherwise stated, the description of the readout period READOUT (i.e., t107 to t147) made with reference to FIG. 5 may be equally applied to the readout period READOUT (i.e., t807 to t847).

Here, the first switch control signal SW31 may be the same as the first switch control signal SW11 of FIG. 5, the second switch control signal SW32 may be the same as the second switch control signal SW12 of FIG. 5, the first transmission control signal TGS31 may be the same as the first transmission control signal TGS11, and the second transmission control signal TGS32 may be the same as the second transmission control signal TGS12.

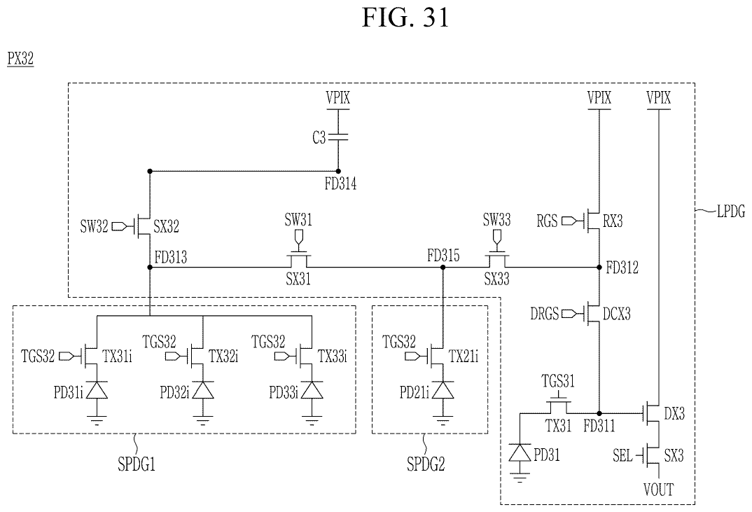

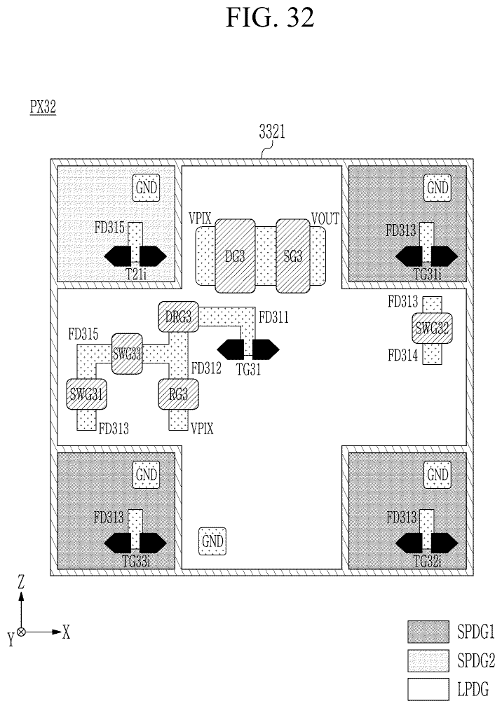

FIG. 31 is a circuit diagram of a pixel according to one or more embodiments. Specifically, FIG. 31 is a circuit diagram of the pixel PX of FIG. 1. FIG. 32 is a top plan view schematically showing the pixel according to FIG. 31.

Referring to FIG. 31, a pixel PX32 may include the first small photodiode group SPDG1 including a plurality of third photodiodes PD31i, PD32i, and PD33i, the second small photodiode group SPDG2 including the second photodiode PD21i, and the large photodiode group LPDG including the first photoelectric element PD31.

The second photodiode PD21i and the plurality of third photodiodes PD31i, PD32i, and PD33i may be a small photodiode, and the first photoelectric element PD31 may be a large photodiode.

The large photodiode group LPDG may include a plurality of transistors, for example, the first transmission transistor TX31, the reset transistor RX3, the driving transistor DX3, the selection transistor SX3, the gain control transistor DCX3, the first switch transistor SX31, the second switch transistor SX32, a third switch transistor SX33, and the third capacitor C3. Control signals TGS31, RGS, SEL, DRGS, SW31, SW32, and SW33 may be applied to the large photodiode group LPDG. In one or more embodiments, the control signals may be generated by the row driver 130 (see FIG. 1) based on the control of the timing controller 120.

The third switch transistor SX33 may be connected between the second floating diffusion node FD312 and a fifth floating diffusion node FD315. The third switch transistor SX33 may be controlled by a third switch control signal SW33. When the third switch transistor SX33 is turned on, the fifth floating diffusion node FD315 and the second floating diffusion node FD312 may be connected.

The first small photodiode group SPDG1 may include a plurality of third transmission transistors TX31i, TX32i, and TX33i. Control signal TGS32 may be applied to the first small photodiode group SPDG1.

The second small photodiode group SPDG2 may include a plurality of transistors, for example, a second transmission transistor TX21i. Control signal TGS32 may be applied to the second small photodiode group SPDG2.

Referring to FIG. 32 together, the pixel PX32 may include the first small photodiode group SPDG1, the second small photodiode group SPDG2, the large photodiode group LPDG.

As shown in FIG. 32, a separation pattern 3321 may be disposed on the outer surface of the pixel PX32, and between the first small photodiode group SPDG1, the second small photodiode group SPDG2, and the large photodiode group LPDG of the pixel PX32.

The separation pattern 3321 may divide regions of the first small photodiode group SPDG1, the second small photodiode group SPDG2, and the large photodiode group LPDG, on a two-dimensional plane.

The first switch gate SWG31, the second switch gate SWG32, a third switch gate SWG33, the reset gate RG3, the gain control gate DRG3, the driving gate DG3, the selection gate SG3, the first transfer gate TG31 may be formed within the large photodiode group LPDG. The first switch gate SWG31 may be a gate of the first switch transistor SX31. The second switch gate SWG32 may be a gate of the second switch transistor SX32. The third switch gate SWG33 may be a gate of the third switch transistor SX33. The reset gate RG3 may be a gate of the reset transistor RX3. The gain control gate DRG3 may be a gate of the gain control transistor DCX3. The driving gate DG3 may be a gate of the driving transistor DX3. The selection gate SG3 may be a gate of the selection transistor SX3. The first transfer gate TG31 may be a gate of the first transmission transistor TX31.

In addition, the first floating diffusion node FD311, the second floating diffusion node FD312, the third floating diffusion node FD313, the fourth floating diffusion node FD314 may be formed within the large photodiode group LPDG. The ground region GND and the power source voltage region VPIX, the pixel voltage region VOUT may be formed within the large photodiode group LPDG.

In one or more embodiments, the second switch gate SWG32 may be formed in the first small photodiode group SPDG1 rather than the large photodiode group LPDG. Meanwhile, the present disclosure is not limited thereto, and the plurality of transistors within the pixel may be formed in various arrangements.

A plurality of third transfer gates TG31i, TG32i, and TG33i may be formed within the first small photodiode group SPDG1. The plurality of third transfer gates TG31i, TG32i, and TG33i may be gates of plurality of third transmission transistors TX31i, TX32i, and TX33i, respectively. The third floating diffusion node FD313 may be formed within the first small photodiode group SPDG1. In addition, the ground region GND may be formed within the first small photodiode group SPDG1.

A second transfer gate TG21i may be formed within the second small photodiode group SPDG2. The second transfer gate TG21i may be a gate of the second transmission transistor TX21i. The fifth floating diffusion node FD315 may be formed in a region where the second transmission transistor TX21i is formed among the second small photodiode group SPDG2. In addition, the ground region GND may be formed within the second small photodiode group SPDG2.

The large photodiode group LPDG may be formed in the central region of the pixel PX32, and the first small photodiode group SPDG1 and the second small photodiode group SPDG2 may be disposed symmetrically to each other in a peripheral area (e.g., edge) of the pixel PX32. The first small photodiode group SPDG1 and the second small photodiode group SPDG2 may have a rectangular shape. As shown in FIG. 32, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

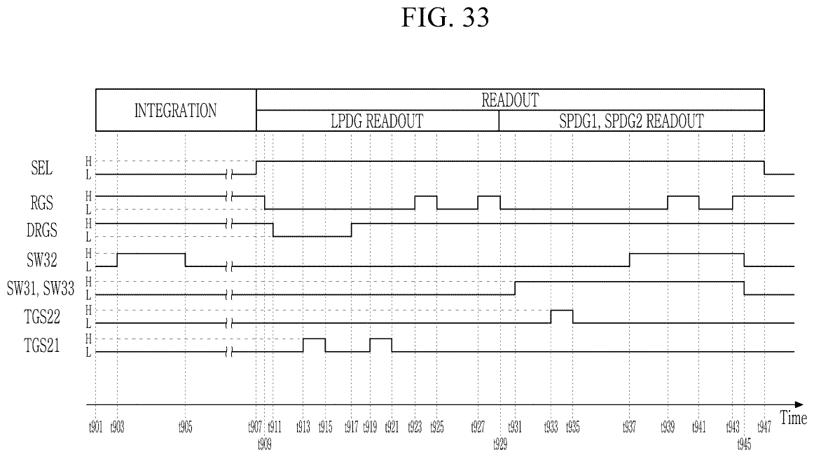

FIG. 33 is a timing diagram showing the operation of the image sensor according to one or more embodiments.

In more detail, FIG. 33 may be one scan period for driving the pixel PX32 according to FIG. 31. One scan period may sequentially include the integration period INTEGRATION and the readout period READOUT.

The integration period INTEGRATION (i.e., t901 to t907) may be a period where the first photoelectric element PD31, the second photodiode PD21i, and the plurality of third photodiodes PD31i, PD32i, and PD33i are exposed to light and thereby generates charges. Unless otherwise stated, the description of the integration period INTEGRATION (i.e., t801 to t807) made with reference to FIG. 30 may be equally applied to the integration period INTEGRATION (i.e., t901 to t907).

The readout period READOUT (i.e., t907 to t947) may be a period where the pixel signal VOUT generated by the pixel PX11 is transferred to the readout circuit 150 (see FIG. 1). The readout period READOUT may include the large photodiode group readout period LPDG READOUT (i.e., t907 to t929), the first and second small photodiode group readout periods SPDG1 and SPDG2 READOUT (i.e., t929 to t947). Unless otherwise stated, the description of the readout period READOUT (i.e., t807 to t847) made with reference to FIG. 30 may be equally applied to the readout period READOUT (i.e., t907 to t947).

In the readout period READOUT (i.e., t907 to t947), the third switch control signal SW33 may be the same as the first switch control signal SW31.

In more detail, at t931, at the first switch control signal SW31 and the third switch control signal SW33 may transition from the low level L to the high level H.

Since the first switch transistor SX11 and the third switch transistor SX13 is turned on by the first switch control signal SW31 and the third switch control signal SW33 of the high level H, the second floating diffusion node FD312, the third floating diffusion node FD313, and the fifth floating diffusion node FD315 may be connected.

Between t931 and t933, the pixel PX32 may output signals (i.e., reset signals) corresponding to the first floating diffusion node FD311, the second floating diffusion node FD312, the third floating diffusion node FD313, and the fifth floating diffusion node FD315, as the pixel signal VOUT.

Meanwhile, the charge generated and overflowed from the second photodiode PD21i and the plurality of third photodiodes PD31i, PD32i, and PD33i may be stored in the third capacitor C3.

Between t937 and t939, the pixel PX32 may output signals (i.e., image signals) corresponding to the first floating diffusion node FD311, the second floating diffusion node FD312, and the third floating diffusion node FD313, the fourth floating diffusion node FD314, and the fifth floating diffusion node FD315, as the pixel signal VOUT.

Thereafter, at t945, at the first switch control signal SW31, the second switch control signal SW32, and the third switch control signal SW33 may transition from the high level H to the low level L.

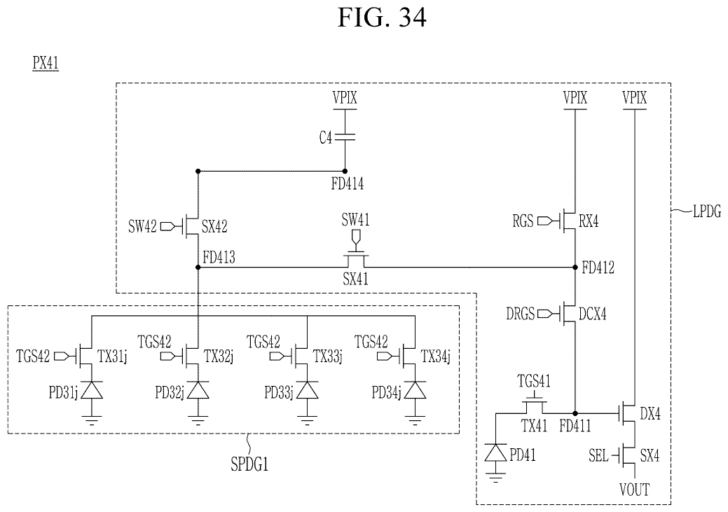

FIG. 34 is a circuit diagram of a pixel according to one or more embodiments. Specifically, FIG. 34 is a circuit diagram of the pixel PX of FIG. 1.

Referring to FIG. 34, a pixel PX41 may include the first small photodiode group SPDG1 including a plurality of third photodiodes PD31j, PD32j, PD33j, and PD34j, and the large photodiode group LPDG including a first photoelectric element PD41.

The second photodiode PD21h and the plurality of third photodiodes PD31j, PD32j, PD33j, and PD34j may be a small photodiode, and the first photoelectric element PD41 may be a large photodiode.

The large photodiode group LPDG may include a plurality of transistors, for example, a first transmission transistor TX41, a reset transistor RX4, a driving transistor DX4, a selection transistor SX4, a gain control transistor DCX4, a first switch transistor SX41, a second switch transistor SX42, and a fourth capacitor C4. Control signals TGS41, RGS, SEL, DRGS, SW41, and SW42 may be applied to the large photodiode group LPDG. In one or more embodiments, the control signals may be generated by the row driver 130 (see FIG. 1) based on the control of the timing controller 120.

The first transmission transistor TX41 may be connected between the first photoelectric element PD41 and a first floating diffusion node FD411. The first transmission transistor TX41 may be controlled by a first transmission control signal TGS41. When the first transmission transistor TX41 is turned on, the charge generated by the first photoelectric element PD41 may be transferred to the first floating diffusion node FD411.

The reset transistor RX4 may be connected between a second floating diffusion node FD412 and the power source voltage line supplying the power source voltage VPIX. The reset transistor RX4 may be controlled by the reset control signal RGS. When the reset transistor RX4 is turned on, the power source voltage VPIX may be applied to the second floating diffusion node FD412, and thereby the second floating diffusion node FD412 may be reset. When the switch transistor SX41 is turned on while the reset transistor RX4 is turned on, a third floating diffusion node FD413 and the second floating diffusion node FD412 may be reset to the power source voltage VPIX. When the switch transistor SX41 and the switch transistor SX42 is turned on while the reset transistor RX4 is turned on, the second floating diffusion node FD412, the third floating diffusion node FD413, and a fourth floating diffusion node FD414 may be reset to the power source voltage VPIX. When the gain control transistor DCX4 is turned on while the reset transistor RX4 is turned on, the first floating diffusion node FD411 and the second floating diffusion node FD412 may be reset to the power source voltage VPIX.

A gate of the driving transistor DX4 may be connected to the first floating diffusion node FD411. A first end of the driving transistor DX4 may be connected to the power source voltage VPIX, and a second end thereof may be connected to a first end of the selection transistor SX4. The driving transistor DX4 may operate as a source-follower amplifier with respect to a voltage of the first floating diffusion node FD411. In response to the voltage of the first floating diffusion node FD411, the driving transistor DX4 may output the pixel voltage VOUT to the column line CL (see FIG. 1) through the selection transistor SX4.

The selection transistor SX4 may be connected to the first end of the driving transistor DX4 and the column line CL, and may be controlled by the selection control signal SEL. When the selection transistor SX4 is turned on, the pixel voltage VOUT output from the driving transistor DX4 may be output to the readout circuit 150 (see FIG. 1) through the column line CL connected to the selection transistor SX4. For example, when the selection transistor SX4 is turned on in the readout operation, a pixel signal including a reset signal corresponding to a reset operation or an image signal corresponding to a charge accumulation operation may be output through the column line CL.

The gain control transistor DCX4 may be connected between the first floating diffusion node FD411 and the second floating diffusion node FD412. The gain control transistor DCX4 may be controlled by the gain control signal DRGS. When the gain control transistor DCX4 is turned on, the first floating diffusion node FD411 and the second floating diffusion node FD412 are connected to each other such that the capacitance may increase, and a conversion gain, which is a ratio of charges converted to voltage may decrease. That is, when a conversion gain transistor DCX4 is turned on, the first photoelectric element PD41 may operate in the low conversion gain (LCG) mode. To the contrary, when the conversion gain transistor DCX4 is turned off, the first photoelectric element PD41 may operate in the high conversion gain (HCG) mode.

The first switch transistor SX41 may be connected between the second floating diffusion node FD412 and the third floating diffusion node FD413. The first switch transistor SX41 may be controlled by a first switch control signal SW41. When the first switch transistor SX41 is turned on, the first floating diffusion node FD411 and the third floating diffusion node FD413 may be connected. Meanwhile, the present disclosure is not limited thereto, and the pixel PX41 may not include the first switch transistor SX41. In this case, the third floating diffusion node FD413 may be the second floating diffusion node FD412.

The second switch transistor SX42 may be connected between the third floating diffusion node FD413 and the fourth floating diffusion node FD414. The second switch transistor SX42 may be controlled by a second switch control signal SW42. When the second switch transistor SX42 is turned on, the third floating diffusion node FD413 and the fourth floating diffusion node FD414 are connected, so that the fourth capacitor C4 is connected to the third floating diffusion node FD413, thereby increasing the capacitance.

The fourth capacitor C4 may be connected between the fourth floating diffusion node FD414 and the power source voltage line supplying the power source voltage VPIX. When the second switch transistor SX42 is turned on while the first switch transistor SX41 is turned on, the second floating diffusion node FD412, the third floating diffusion node FD413, and the fourth floating diffusion node FD414 may be connected to each other, thereby increasing a capacitance of the second floating diffusion node FD412. That is, the fourth capacitor C4 may be used to adjust the capacitance of the second floating diffusion node FD412. In one or more embodiments, the photoelectric charge generated from the plurality of third photodiodes PD31j, PD32j, PD33j, and PD34j during the integration period may overflow, and the overflowed charge may be accumulated in the fourth capacitor C4 by passing through the third floating diffusion node FD413 and the fourth floating diffusion node FD414.

The fourth capacitor C4 may include a lateral overflow integration capacitor (LOFIC). When the fourth capacitor C4 includes LOFIC, overflowed charges among charges transferred from the first photoelectric element PD41, the second photodiode PD21h, and the plurality of third photodiodes PD31j, PD32j, PD33j, and PD34j to the first floating diffusion node FD411 may be stored. That is, a large amount of charge that overflows may be accumulated into the fourth capacitor C4 without being discarded.

The first small photodiode group SPDG1 may include a plurality of third transmission transistors TX31j, TX32j, TX33j, and TX34j. Control signal TGS42 may be applied to the first small photodiode group SPDG1.

The plurality of third transmission transistors TX31j, TX32j, TX33j, and TX34j may be connected between the plurality of third photodiodes PD31j, PD32j, PD33j, and PD34j corresponding thereto and the third floating diffusion node FD413. The plurality of third transmission transistors TX31j, TX32j, TX33j, and TX34j may be controlled by a second transmission control signal TGS42. When the plurality of third transmission transistors TX31j, TX32j, TX33j, and TX34j are turned on, the charge generated by the plurality of third photodiodes PD31j, PD32j, PD33j, and PD34j may be transferred to the third floating diffusion node FD413.

The photoelectric charges generated by the large photodiode group LPDG and the first small photodiode group SPDG1 may be transmitted to and accumulated in at least one among the first floating diffusion node FD411, the second floating diffusion node FD412, the third floating diffusion node FD413, the fourth capacitor C4. Although not shown in FIG. 34, in each of the first floating diffusion node FD411, the second floating diffusion node FD412, and the third floating diffusion node FD413, a parasitic capacitor (not shown) may be formed, or an actual capacitor element may be connected.

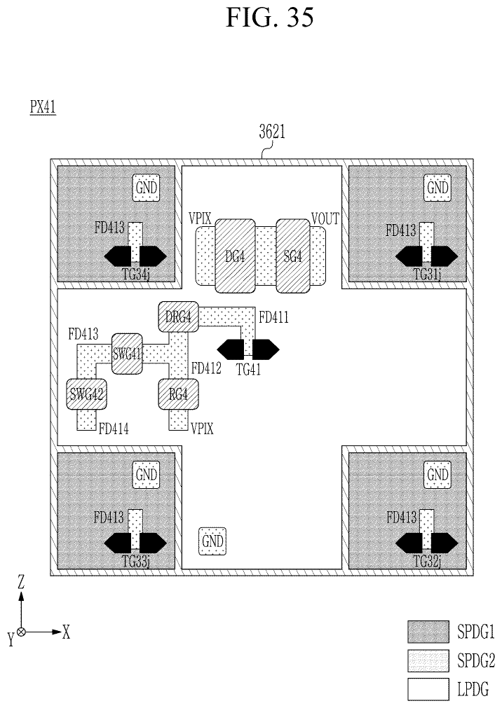

FIG. 35 is a top plan view schematically showing the pixel according to FIG. 34.

Referring to FIG. 35, the pixel PX41 may include the first small photodiode group SPDG1 and the large photodiode group LPDG.

As shown in FIG. 35, a separation pattern 3621 may be disposed on the outer surface of the pixel PX41, and between the first small photodiode group SPDG1, and the large photodiode group LPDG of the pixel PX41.

The separation pattern 3621 may divide regions of the first small photodiode group SPDG1, and the large photodiode group LPDG, on a two-dimensional plane.

A first switch gate SWG41, a second switch gate SWG42, a reset gate RG4, a gain control gate DRG4, a driving gate DG4, a selection gate SG4, first transfer gate TG41 may be formed within the large photodiode group LPDG. The first switch gate SWG41 may be a gate of the first switch transistor SX41. The second switch gate SWG42 may be a gate of the second switch transistor SX42. The reset gate RG4 may be a gate of the reset transistor RX4. The gain control gate DRG4 may be a gate of the gain control transistor DCX4. The driving gate DG4 may be a gate of the driving transistor DX4. The selection gate SG4 may be a gate of the selection transistor SX4. The first transfer gate TG41 may be a gate of the first transmission transistor TX41.

In addition, the first floating diffusion node FD411, the second floating diffusion node FD412, the third floating diffusion node FD413, and the fourth floating diffusion node FD414 may be formed within the large photodiode group LPDG. The ground region GND and the power source voltage region VPIX, the pixel voltage region VOUT may be formed within the large photodiode group LPDG.

In one or more embodiments, the second switch gate SWG42 may be formed in the first small photodiode group SPDG1 rather than the large photodiode group LPDG. Meanwhile, the present disclosure is not limited thereto, and the plurality of transistors within the pixel may be formed in various arrangements.

A plurality of third transfer gates TG31j, TG32j, TG33j, and TG34j may be formed within the first small photodiode group SPDG1. The plurality of third transfer gates TG31j, TG32j, TG33j, and TG34j may be gates of plurality of third transmission transistors TX31j, TX32j, TX33j, and TX34j, respectively. The third floating diffusion node FD413 may be formed within the first small photodiode group SPDG1. In addition, the ground region GND may be formed within the first small photodiode group SPDG1.

The large photodiode group LPDG may be formed in the central region of the pixel PX41, and the first small photodiode group SPDG1 and the second small photodiode group SPDG2 may be disposed symmetrically to each other in a peripheral area (e.g., edge) of the pixel PX41. The first small photodiode group SPDG1 and the second small photodiode group SPDG2 may have a rectangular shape. As shown in FIG. 35, the large photodiode group LPDG may have a cross shape. However, the present disclosure is not limited thereto, and the shapes of the large photodiode group LPDG, the first small photodiode group SPDG1, and the second small photodiode group SPDG2 may be variously modified.

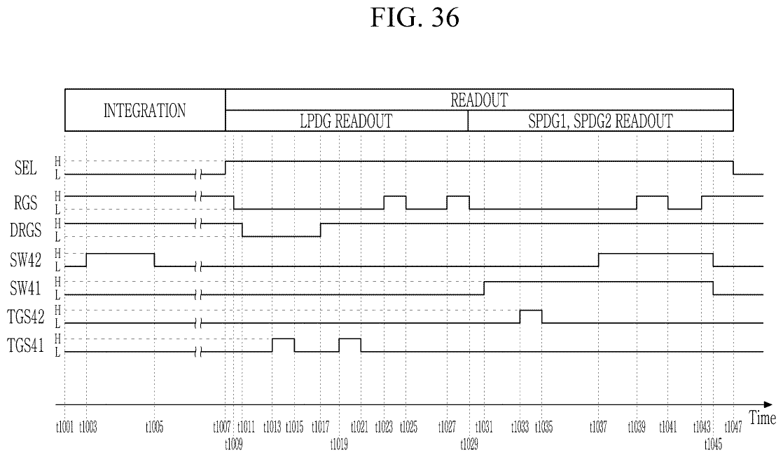

FIG. 36 is a timing diagram showing the operation of the image sensor according to one or more embodiments.

In more detail, FIG. 36 may be one scan period for driving the pixel PX41 according to FIG. 34. One scan period may sequentially include the integration period INTEGRATION and the readout period READOUT.

The integration period INTEGRATION (i.e., t1001 to t1007) may be a period where the first photoelectric element PD41, and the plurality of third photodiodes PD31j, PD32j, PD33j, and PD34j are exposed to light and thereby generates charges. Unless otherwise stated, the description of the integration period INTEGRATION (i.e., t101 to t107) made with reference to FIG. 5 may be equally applied to the integration period INTEGRATION (i.e., t1001 to t1007).

The readout period READOUT (i.e., t1007 to t1047) may be a period where the pixel signal VOUT generated by the pixel PX11 is transferred to the readout circuit 150 (see FIG. 1). The readout period READOUT may include the large photodiode group readout period LPDG READOUT (i.e., t1007 to t1029), the first and second small photodiode group readout periods SPDG1 and SPDG2 READOUT (i.e., t1029 to t1047). Unless otherwise stated, the description of the readout period READOUT (i.e., t107 to t147) made with reference to FIG. 5 may be equally applied to the readout period READOUT (i.e., t1007 to t1047).

Here, the first switch control signal SW41 may be the same as the first switch control signal SW11 of FIG. 5, the second switch control signal SW42 may be the same as the second switch control signal SW12 of FIG. 5, the first transmission control signal TGS41 may be the same as the first transmission control signal TGS11, and the second transmission control signal TGS42 may be the same as the second transmission control signal TGS12.

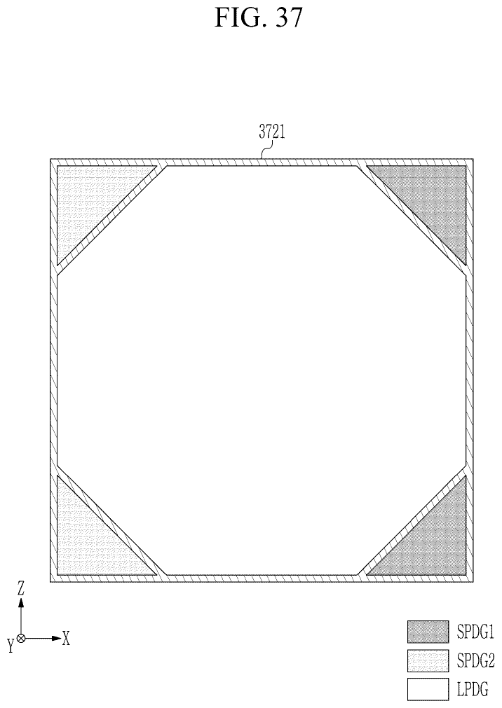

FIG. 37 to FIG. 47 are top plan views schematically showing a pixel according to one or more embodiments.

In more detail, FIG. 37 to FIG. 47 are drawings schematically showing the pixel PX of FIG. 1.

The pixel PX may include the first small photodiode group SPDG1 including at least one small photodiode connected to a high-capacity capacitor, the second small photodiode group SPDG2 including at least one small photodiode that is not connected to the high-capacity capacitor, and the large photodiode group LPDG including the large photodiode.

Referring to FIG. 37, a separation pattern 3721 may be disposed on the outer surface of the pixel PX, and between the first small photodiode group SPDG1, the second small photodiode group SPDG2, and the large photodiode group LPDG of the pixel PX.

The separation pattern 3721 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 37, the large photodiode group LPDG may have an octagonal shape.

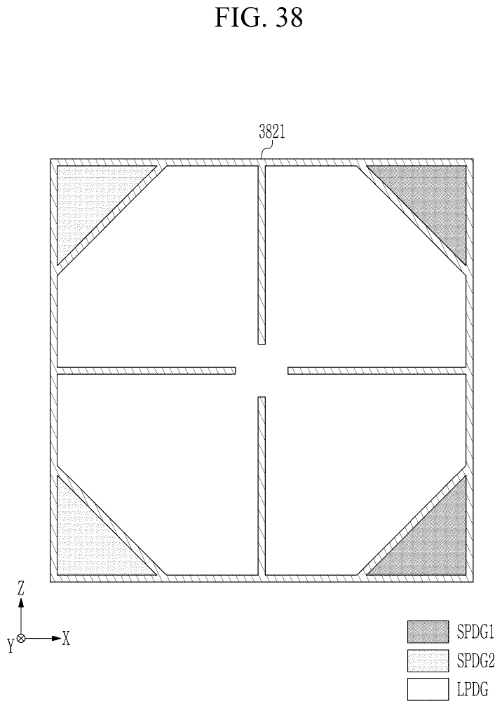

Referring to FIG. 38, a separation pattern 3821 may be disposed on the outer surface of the pixel PX, and between the first small photodiode group SPDG1, the second small photodiode group SPDG2, and the large photodiode group LPDG of the pixel PX.

The separation pattern 3821 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 38, the large photodiode group LPDG may have an octagonal shape.

The separation pattern 3821 may be disposed to extend from at least one surface of the large photodiode group LPDG extending in the first direction X toward the center of the large photodiode group LPDG in the second direction Z or the opposite direction-Z of the second direction, which is a perpendicular direction. Specifically, the separation pattern 3821 may be disposed to extend from a center of the first surface extending in the first direction X toward the center of the large photodiode group LPDG. For example, a length of the separation pattern 3821 may be shorter than ½ of a length of the pixel PX in the second direction.

In addition, the separation pattern 3821 may be disposed to extend from at least one surface of the large photodiode group LPDG extending in the second direction Z toward the center of the large photodiode group LPDG in the first direction X or the opposite direction-X of the first direction, which is a perpendicular direction. Specifically, the separation pattern 3821 may be disposed to extend from a center of the second surface extending in the second direction Z toward the center of the large photodiode group LPDG. For example, the length of the separation pattern 3821 may be shorter than ½ of a length of the pixel PX in the first direction.

The separation pattern 3821 may be symmetrical about the first direction X and/or the second direction Z.

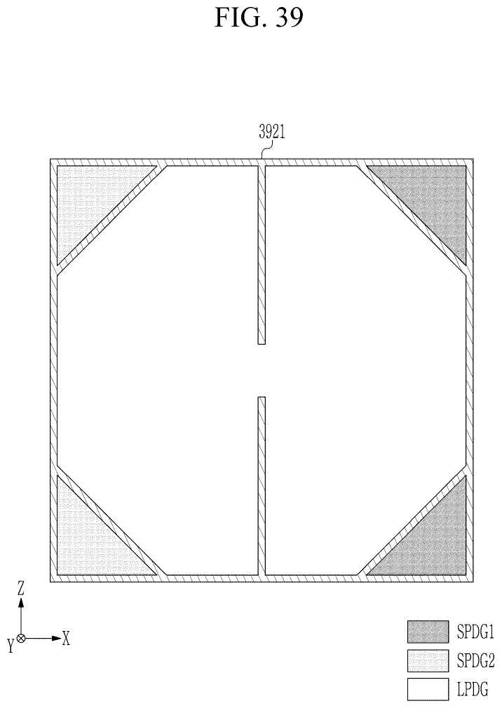

Referring to FIG. 39, a separation pattern 3921 may be disposed on the outer surface of the pixel PX, and between the first small photodiode group SPDG1, the second small photodiode group SPDG2, and the large photodiode group LPDG of the pixel PX.

The separation pattern 3921 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 39, the large photodiode group LPDG may have an octagonal shape.

The separation pattern 3921 may be disposed to extend from at least one surface of the large photodiode group LPDG extending in the first direction X toward the center of the large photodiode group LPDG in the second direction Z or the opposite direction-Z of the second direction, which is a perpendicular direction. Specifically, the separation pattern 3921 may be disposed to extend from the center of the first surface extending in the first direction X toward the center of the large photodiode group LPDG. For example, a length of the separation pattern 3921 may be shorter than ½ of the length of the pixel PX in the second direction.

The separation pattern 3921 may be symmetrical about the first direction X.

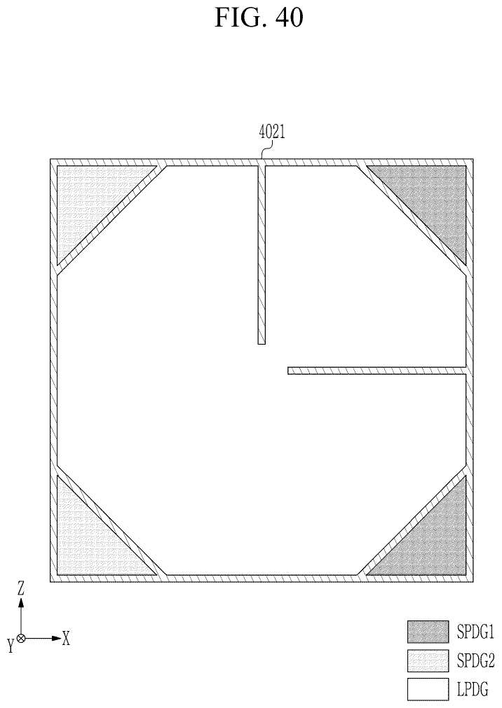

Referring to FIG. 40, a separation pattern 4021 may be disposed on the outer surface of the pixel PX, and between the first small photodiode group SPDG1, the second small photodiode group SPDG2, and the large photodiode group LPDG of the pixel PX.

The separation pattern 4021 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 40, the large photodiode group LPDG may have an octagonal shape.

The separation pattern 4021 may be disposed to extend from at least one surface of the large photodiode group LPDG extending in the first direction X toward the center of the large photodiode group LPDG in the opposite direction-Z of the second direction, which is a perpendicular direction. In addition, the separation pattern 4021 may be disposed to extend from at least one surface of the large photodiode group LPDG extending in the second direction Z toward the center of the large photodiode group LPDG in the opposite direction-X of the first direction, which is a perpendicular direction. For example, the length of the separation pattern 3921 may be shorter than ½ of the length of the pixel PX in the second direction.

The separation pattern 4021 may be symmetrical about the third direction crossing the first direction X and the second direction Z.

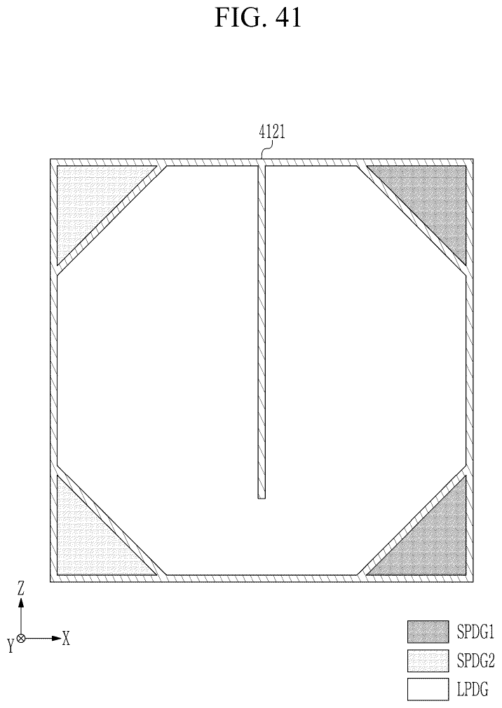

Referring to FIG. 41, a separation pattern 4121 may be disposed on the outer surface of the pixel PX, and between the first small photodiode group SPDG1, the second small photodiode group SPDG2, and the large photodiode group LPDG of the pixel PX.

The separation pattern 4121 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 41, the large photodiode group LPDG may have an octagonal shape.

The separation pattern 4121 may be disposed to extend from at least one surface of the large photodiode group LPDG extending in the first direction X, in the opposite direction-Z of the second direction perpendicular to the at least one surface, until the opposite surface becomes in contact by passing through the center of the large photodiode group LPDG. A length of the separation pattern 4121 in the second direction may be shorter than the length of the pixel PX in the second direction, and may be longer than ½ of the length of the pixel PX in the second direction.

The separation pattern 4121 may be symmetrical about the second direction Z.

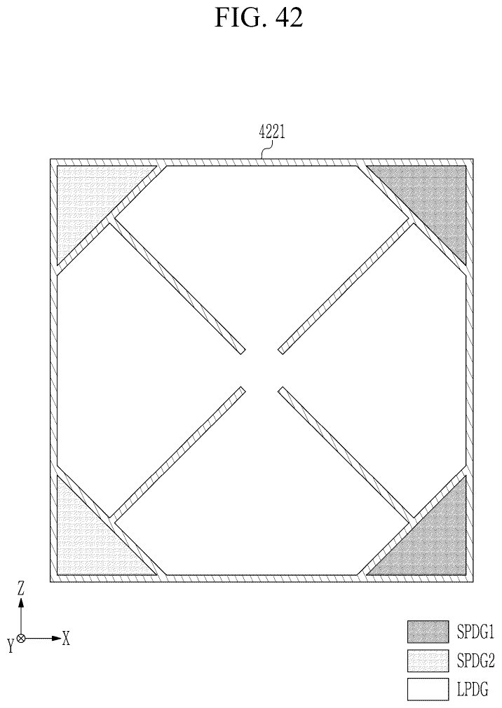

Referring to FIG. 42, a separation pattern 4221 may be disposed on the outer surface of the pixel PX, and between the first small photodiode group SPDG1, the second small photodiode group SPDG2, and the large photodiode group LPDG of the pixel PX.

The separation pattern 4221 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 42, the large photodiode group LPDG may have an octagonal shape.

A first separation pattern among the separation patterns 4221 may be disposed to extend from at least one first surface extending in the third direction crossing the first direction X and the second direction Z toward the center of the large photodiode group LPDG in a direction perpendicular to the at least one first surface. For example, the first separation pattern may extend from the center of the first surface.

A second separation pattern among the separation patterns 4221 may be disposed to extend from at least one second surface of the large photodiode group LPDG extending in a fourth direction crossing the opposite direction-X of the first direction and the second direction Z toward the center of the large photodiode group LPDG, in a direction perpendicular to at least one second surface. For example, the second separation pattern may extend from the center of the second surface.

A third separation pattern among the separation patterns 4221 may be disposed to extend from at least one third surface of the large photodiode group LPDG extending in a fifth direction crossing the first direction X and the opposite direction-Z of the second direction toward the center of the large photodiode group LPDG, in a direction perpendicular to at least one second surface. For example, the third separation pattern may extend from a center of the third surface.

A fourth separation pattern among the separation patterns 4221 may be disposed to extend from at least one fourth surface of the large photodiode group LPDG extending in a sixth direction crossing the opposite direction-X of the first direction and the opposite direction-Z of the second direction toward the center of the large photodiode group LPDG, in a direction perpendicular to at least one second surface. For example, the fourth separation pattern may extend from a center of the fourth surface.

In one or more embodiments, each of the first separation pattern, the second separation pattern, the third separation pattern, and the fourth separation pattern may be perpendicular to each other. In one or more embodiments, the length of each of the first separation pattern, the second separation pattern, the third separation pattern, and the fourth separation pattern may be shorter than the length from the center of the large photodiode group LPDG to the first small photodiode group SPDG1 and/or the second small photodiode group SPDG2.

In other words, the separation pattern 4221 may be disposed to extend from a surface adjacent to the large photodiode group LPDG and the first small photodiode group SPDG1 and/or a surface adjacent to the large photodiode group LPDG and the second small photodiode group SPDG2 toward the center of the large photodiode group LPDG, in a direction perpendicular to the surface.

The separation pattern 4221 may be symmetrical about the first direction X and/or the second direction Z.

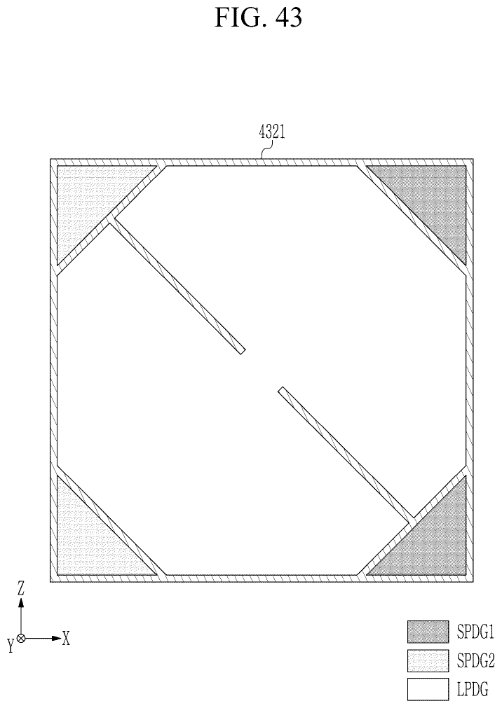

Referring to FIG. 43, a separation pattern 4321 may be disposed on the outer surface of the pixel PX, and between the first small photodiode group SPDG1, the second small photodiode group SPDG2, and the large photodiode group LPDG of the pixel PX.

The separation pattern 4321 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 43, the large photodiode group LPDG may have an octagonal shape.

The first separation pattern among the separation patterns 4321 may be disposed to extend from at least one first surface of the large photodiode group LPDG extending in the third direction crossing the opposite direction-X of the first direction and the second direction Z toward the center of the large photodiode group LPDG, in a direction perpendicular to at least one second surface. For example, the first separation pattern may extend from the center of the first surface.

The second separation pattern among the separation patterns 4321 may be disposed to extend from at least one second surface of the large photodiode group LPDG extending in the fourth direction crossing the first direction X and the opposite direction-Z of the second direction toward the center of the large photodiode group LPDG, in a direction perpendicular to at least one second surface. For example, the second separation pattern may extend from the center of the second surface.

In one or more embodiments, each of the lengths of the first separation pattern and the second separation pattern may be shorter than the length from the center of the large photodiode group LPDG to the first small photodiode group SPDG1 and/or the second small photodiode group SPDG2.

It may be disposed to extend from a surface adjacent to the large photodiode group LPDG and the first small photodiode group SPDG1 and/or a surface adjacent to the large photodiode group LPDG and the second small photodiode group SPDG2 toward the center of the large photodiode group LPDG, in a direction perpendicular to the surface.

The separation pattern 4321 may be symmetrical about the fifth direction crossing the first direction X and the second direction Z.

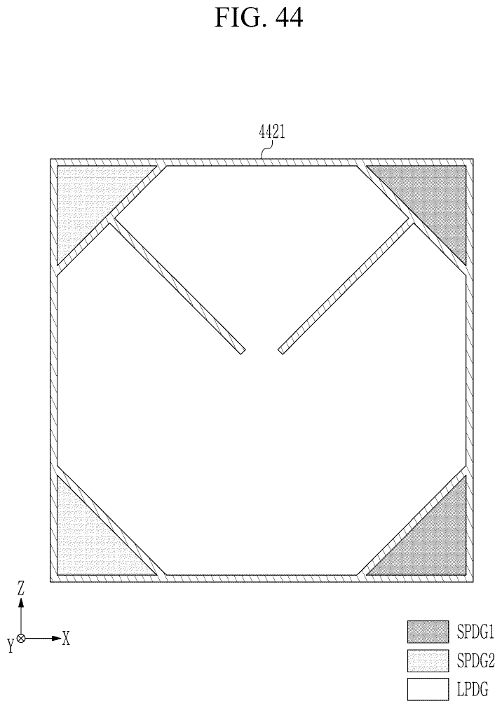

Referring to FIG. 44, a separation pattern 4421 may be disposed on the outer surface of the pixel PX, and between the first small photodiode group SPDG1, the second small photodiode group SPDG2, and the large photodiode group LPDG of the pixel PX.

The separation pattern 4421 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 44, the large photodiode group LPDG may have an octagonal shape.

The first separation pattern among the separation patterns 4421 may be disposed to extend from at least one first surface of the large photodiode group LPDG extending in the third direction crossing the first direction X and the opposite direction-Z of the second direction toward the center of the large photodiode group LPDG, in a direction perpendicular to at least one second surface. For example, the first separation pattern may extend from the center of the first surface.

The second separation pattern among the separation patterns 4421 may be disposed to extend from at least one second surface of the large photodiode group LPDG extending in the fourth direction crossing the opposite direction-X of the first direction and the opposite direction-Z of the second direction toward the center of the large photodiode group LPDG, in a direction perpendicular to at least one second surface. For example, the second separation pattern may extend from the center of the second surface.

In one or more embodiments, each of the lengths of the first separation pattern and the second separation pattern may be shorter than the length from the center of the large photodiode group LPDG to the first small photodiode group SPDG1 and/or the second small photodiode group SPDG2.

It may be disposed to extend from a surface adjacent to the large photodiode group LPDG and the first small photodiode group SPDG1 and/or a surface adjacent to the large photodiode group LPDG and the second small photodiode group SPDG2 toward the center of the large photodiode group LPDG, in a direction perpendicular to the surface. The separation pattern 4421 may be symmetrical about the second direction Z.

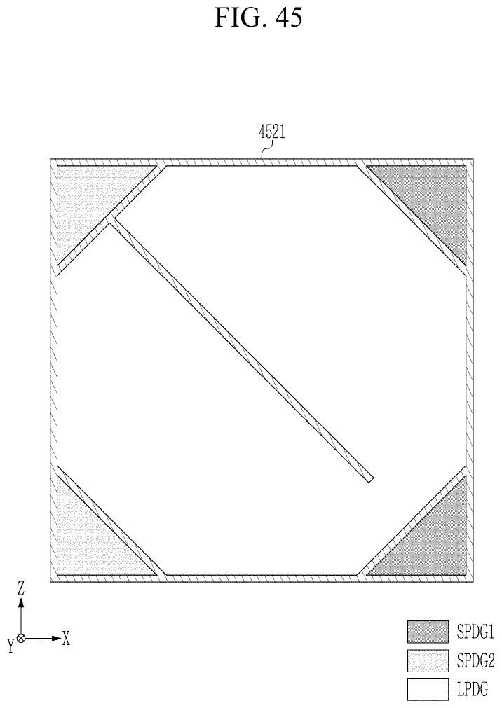

Referring to FIG. 45, a separation pattern 4521 may be disposed on the outer surface of the pixel PX, and between the first small photodiode group SPDG1, the second small photodiode group SPDG2, and the large photodiode group LPDG of the pixel PX.

The separation pattern 4521 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed symmetrically to each other in a peripheral area (e.g., edge) of the pixel PX. The first small photodiode group SPDG1 and the second small photodiode group SPDG2 may have a triangular shape. As shown in FIG. 45, the large photodiode group LPDG may have an octagonal shape.

The first separation pattern among the separation patterns 4521 may be disposed to extend from at least one first surface of the large photodiode group LPDG extending in the third direction crossing the first direction X and the opposite direction-Z of the second direction toward the center of the large photodiode group LPDG, in a direction perpendicular to at least one second surface. For example, the first separation pattern may extend from the center of the first surface.

A length of the separation pattern 4521 in the third direction may be shorter than a length of the pixel PX in the third direction, and may be longer than ½ of the length of the pixel PX in the third direction.

The separation pattern 4521 may be disposed to extend from at least one surface of the large photodiode group LPDG extending in the third direction crossing the first direction X and the second direction Z toward the center of the large photodiode group LPDG, in a direction perpendicular to at least one second surface. It may be disposed to extend from a surface adjacent to the large photodiode group LPDG and the first small photodiode group SPDG1 and/or a surface adjacent to the large photodiode group LPDG and the second small photodiode group SPDG2 toward the center of the large photodiode group LPDG, in a direction perpendicular to the surface. The separation pattern 4521 may be symmetrical about the third direction.

However, the present disclosure is not limited thereto, and the shapes of the large photodiode group LPDG, the first small photodiode group SPDG1, and the second small photodiode group SPDG2 may be variously modified.

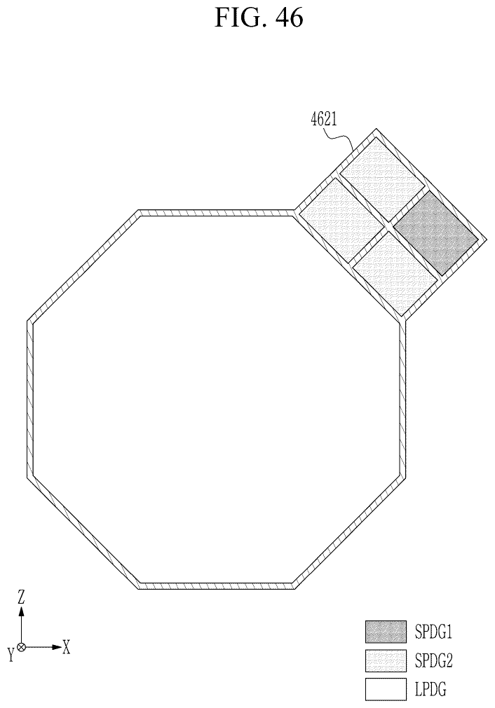

Referring to FIG. 46, a separation pattern 4621 may be disposed on the outer surface of the pixel PX, and between the first small photodiode group SPDG1, the second small photodiode group SPDG2, and the large photodiode group LPDG of the pixel PX.

The separation pattern 4621 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed on the first surface of the large photodiode group LPDG. The first small photodiode group SPDG1 and the second small photodiode group SPDG2 may have a rectangular shape. The large photodiode group LPDG may have an octagonal shape.

The first small photodiode group SPDG1 and the second small photodiode group SPDG2 may be disposed along the third direction crossing the first direction X and the second direction Z. In addition, the first small photodiode group SPDG1 and the second small photodiode group SPDG2 may be disposed along the fourth direction perpendicular to the third direction. That is, the first small photodiode group SPDG1 and the second small photodiode group SPDG2 may be disposed in a matrix shape.

Meanwhile, FIG. 46 illustrates that the pixel PX includes one first small photodiode group SPDG1, but the present disclosure is not limited thereto, and the pixel PX may include a plurality of first small photodiode groups SPDG1.

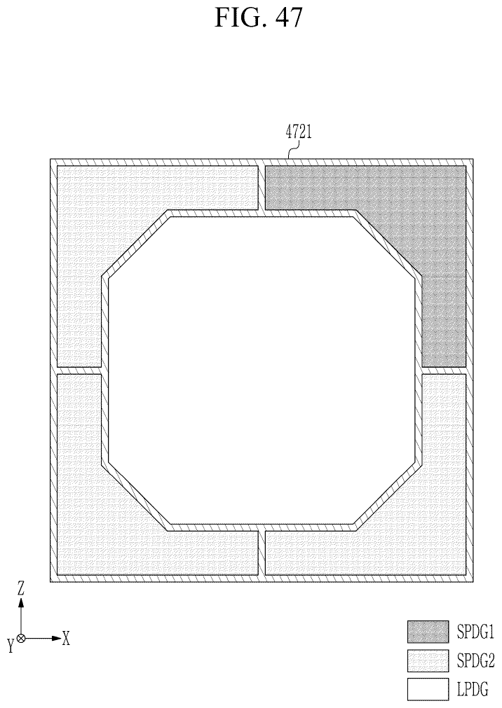

Referring to FIG. 47, a separation pattern 4721 may be disposed on the outer surface of the pixel PX, and between the first small photodiode group SPDG1, the second small photodiode group SPDG2, and the large photodiode group LPDG of the pixel PX.

The separation pattern 4721 may divide regions of the first small photodiode group SPDG1, the second small photodiode group SPDG2, and the large photodiode group LPDG, on a two-dimensional plane.

The large photodiode group LPDG may be formed in the central region of the pixel PX, and the first small photodiode group SPDG1 and the second small photodiode group SPDG2 may be disposed on the first surface of the large photodiode group LPDG. The first small photodiode group SPDG1 and the second small photodiode group SPDG2 may have a shape surrounding an edge of the large photodiode group LPDG. The large photodiode group LPDG may have an octagonal shape. As shown in FIG. 47, the pixel PX may have a rectangular shape by the first small photodiode group SPDG1 and the second small photodiode group SPDG2 surrounding the large photodiode group LPDG.

Meanwhile, FIG. 47 illustrates that the pixel PX includes the one first small photodiode group SPDG1, but the present disclosure is not limited thereto, and the pixel PX may include the plurality of first small photodiode groups SPDG1.

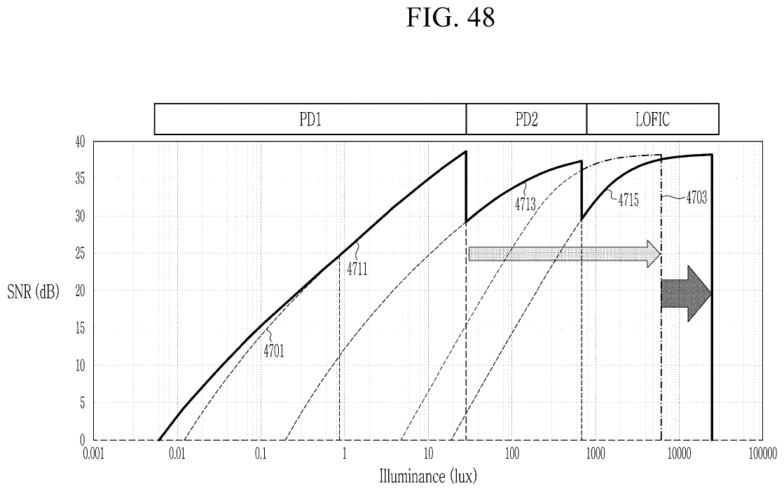

FIG. 48 is a graph showing a signal-to-noise ratio (SNR) according to one or more embodiments.

A first graph 4701 and a second graph 4703 is a graph representing the signal-to-noise ratio (SNR) of a synthesized signal of image signals read by applying a dual conversion gain (DCG) mode with respect to a pixel including one large photodiode and one small photodiode connected to a high-capacity capacitor, in the dB units. A signal-to-noise ratio (SNR) dip may occur in the first graph 4701 and the second graph 4703. At this time, the SNR dip refers to the phenomenon in which the SNR rapidly decreases at a boundary when images having different exposure times are combined, that is, when image signals generated by using different capacitances are combined.

Meanwhile, a third graph 4711, a fourth graph 4713, a fifth graph 4715 is a graph representing the signal-to-noise ratio (SNR) of a synthesized signal of image signals read by applying DCG to the pixel PX according to one or more embodiments, in the dB units. Specifically, the third graph 4711 is a graph representing an image signal read by applying DCG with respect to the first photoelectric element PD11 of FIG. 2, the fourth graph 4713 is a graph representing an image signal read with respect to the plurality of second photodiodes PD21a, PD22a, and PD23a of FIG. 2, and the fifth graph 4715 is a graph representing an image signal read with respect to the third photodiode PD3a connected to the high-capacity capacitor. The fifth graph 4715 may be changed based on the number of the third photodiodes PD3a to which the capacitor is connected. Specifically, by controlling the capacity of the plurality of second photodiodes PD21a, PD22a, and PD23a, the third photodiode PD3a, the first capacitor C1, the fifth graph 4715 may move in the x-axis direction.

For example, based on the first photoelectric element PD11, by dividing small photodiodes (i.e., the plurality of second photodiodes PD21a, PD22a, and PD23a and the third photodiode PD3a) into a plurality and setting a small photodiode connected to the first capacitor C1 among the small photodiodes as the third photodiode PD3a, the image sensor 100 may include the pixel PX having a desired sensitivity. That is, the image sensor 100 may set the sensitivity of the plurality of second photodiodes PD21a, PD22a, and PD23a based on the first photoelectric element PD11, and set the sensitivity of the first capacitor C1 based on the plurality of second photodiodes PD21a, PD22a, and PD23a, b which a desired dynamic range for the pixel PX may be secured.

As shown in FIG. 48, the dynamic range in the third graph 4711, the fourth graph 4713, the fifth graph 4715 may be wider than the dynamic range in the first graph 4701 and the second graph 4703.

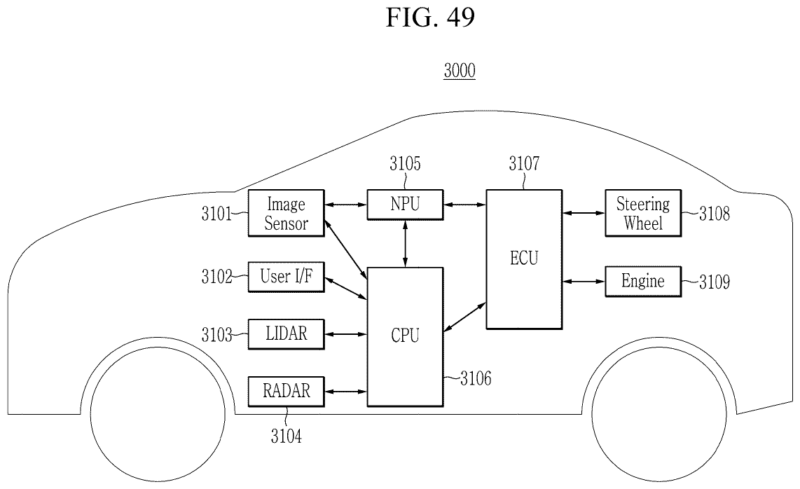

FIG. 49 is a block diagram showing a vehicle according to one or more embodiments.

As shown in FIG. 49, a vehicle 3000 may include an image sensor 3101, a user interface 3102, a Light Detection and Ranging (LIDAR) sensor 3103, a radio detection and ranging (RADAR) sensor 3104, a neural processing unit (NPU) 3105, a CPU 3106, an ECU 3107.

The ECU 3107 may control a steering angle of the vehicle and the vehicle speed through interactions with a steering wheel 3108 and an engine 3109. The vehicle 3000 may further include a communication module, an input/output module, a security module, a power control device, and the like, and may also further include various types of control devices.

Here, the image sensor 3101 may be the image sensor described with reference to FIG. 1 to FIG. 48.

In one or more embodiments, the vehicle 3000 may detect objects, by using information on the external environment acquired through the sensors (for example, the image sensor 3101, the LIDAR sensor 3103, and/or the RADAR sensor 3104). The sensors 3101, 3103, and 3104 may image an object, and measure a distance to the object and transmit it to processors (e.g., the CPU 3106, an NPU 3105 and the ECU 3107). In order for the sensors 3101, 3103, and 3104 to detect objects, besides the above-described sensors, a time of flight (ToF) sensor, an ultrasonic wave sensor, an infrared sensor, a magnetic sensor, a position sensor (e.g., GPS), an acceleration sensor, an air pressure sensor, a temperature/humidity sensor, a proximity sensor, a gyroscope sensor, or the like may be further used.

The image sensor 3101 may provide image or optical sensing, and may, for example, a complementary metal-oxide-semiconductor (CMOS) image sensor. The image sensor 3101 may obtain image or visual information on objects. For example, the image sensor 3101 may be attached in front of the vehicle, to capture driving images or to measure the distances to objects located in front of the vehicle, etc. The position at which the image sensor 3101 is attached is not limited thereto, and the image sensor may be attached at various positions to accomplish the intended purpose of obtaining information on objects.

The image sensor 3101 may image an environment surrounding the vehicle 3000. The vehicle 3000 may include at least two image sensors to capture images of the full 360-degree view of the vehicle's surroundings. In one or more embodiments, the image sensor 3101 may include a wide-angle lens. In one or more embodiments, the vehicle 3000 may include four image sensors for the front, rear, left, and right sides of the vehicle; however, the present disclosure is not limited thereto, the single image sensor 3101 may capture images of the environment around the vehicle. The image sensor 3101 may continuously capture images of the vehicle's surroundings to continuously provide information on the vehicle's surroundings to the vehicle 3000.

The image sensed by the image sensor 3101 may be processed by the CPU 3106 and/or the NPU 3105. The CPU 3106 may process the sensed images in a motion-based manner to detect objects, and the NPU 3105 may process the sensed images in a shape-based manner to detect objects. The image sensor 3101 may be attached to the front of the vehicle to sense the external environment in front of the vehicle; however, it is not limited thereto, and may be attached to various surfaces of the vehicle to sense the external environment.

Here, the image sensor 3101 may be an image sensor described with reference to FIG. 1 to FIG. 48.

The image sensor 3101 may include a large photodiode and at least one small photodiode, and may include a capacitor connected to some small photodiodes among the at least one small photodiode. Here, at least one small at least one small photo diode may be arranged to be spatially separated within the pixel.

Accordingly, the image sensor 3101 can control the sensitivity ratio between the large photoelectric element, the small photoelectric element, and the capacitor, so that a wider dynamic range can be secured. Additionally, the image sensor 3101 may be capable of achieving HDR without adding a separate capacitor.

The user interface 3102 may include various electronic devices and mechanical devices included in the driver's seat, the passenger's seats, and so on, such as the vehicle's instrument panel, a display indicating driving information, a navigation device, an air conditioning system, etc.

The LIDAR sensor 3103 may measure the distances to target objects by emitting a laser pulse and receiving the echoes of the laser pulse from the objects. The LIDAR sensor 3103 may typically include a laser, a scanner, a receiver, and a positioning system. For the laser, light in the wavelength range of 600 nm to 1000 nm is generally used, but the wavelength range may differ depending on the laser's use. The scanner may scan the sensed surrounding environment to quickly acquire information on the surrounding environment, and there may be several forms of scanners using a plurality of mirrors. The receiver may receive the laser pulses reflected from target objects, and sense and amplify photons from the laser pulses. The positioning system may check out the location coordinates and direction of the device equipped with the receiver, to realize three-dimensional images. The LIDAR sensor 3103 and the RADAR sensor 3104 may be differentiated according to their effective measurement distances.

The RADAR sensor 3104 may emit an electromagnetic wave and receive the echoes of the electromagnetic wave from target objects, to measure the distances to the objects or identify the objects, or measure the locations and moving speeds of the objects, etc. The RADAR sensor 3104 may include a transmitter and a receiver. The transmitter may generate and output an electromagnetic wave, and the receiver may receive the echoes from target objects and process the signals. The RADAR sensor 3103 may perform transmission and reception through one antenna, but is not limited thereto. The electromagnetic wave frequency band which is used in the RADAR sensor 3104 may be a radio wave band or a microwave band, but may be changed depending on its purpose. In one or more embodiments, the LIDAR sensor 3103 and the RADAR sensor 3104 may be attached to the vehicle to assist in determining the relative positional relationship between the vehicle and objects of interest. The RADAR sensor 3104 may be categorized as a long radar sensor or a short radar sensor.

The NPU 3105 may receive input data, and perform computations using an artificial neural network, and provide output data based on the computation results. The NPU 3105 may be a processor optimized for simultaneous matrix operations, and be able to process multiple computations in real time, and derive optimal values by self-learning based on accumulated data. The NPU 3105 is optimized for simultaneous matrix calculation thereby capable of processing multiple operations in real time, and may learn on its own based on accumulated data to derive local-maximum values from current driving parameters.

In one or more embodiments, the NPU 3105 may be a specialized processor to execute a deep-learning type algorithm. For example, the NPU 3105 may be a specialized processor to perform a deep-learning algorithm. For example, the NPU 3105 is capable of calculation based on various types of network, such as convolutional neural network (CNN), region-based convolutional neural network (R-CNN), region proposal network (RPN), recurrent neural network (RNN), Fully Convolutional Network, long short-term memory (LSTM) Network, Classification Network, or the like. However, the NPU is not limited thereto, and may be capable of various kinds of arithmetic processing simulating human neural networks.

The NPU 3105 may receive driving images from the image sensor 3101, and perform shape-based object detection based on the driving images. The NPU 3105 may identify each of the plurality of objects from the driving image by extracting the features of a plurality of objects, and performing self-learning based on the accumulated data. For example, the NPU 3105 may extract objects serving as criteria for driving, such as vehicles, pedestrians, traffic lights, lanes, or the like, even from a single driving image, based on the features determined by using the accumulated data as learning materials.

The CPU 3106 may control an overall operation of the vehicle 3000. The CPU 3106 may include a single processor core (i.e., single core), or multiple processor cores (i.e., a multi-core). The CPU 3106 may process or execute programs and/or data stored in the memories. For example, the CPU 3106 may control the functions of the NPU 3105 and the ECU 3107 by executing programs stored in the memories.

The CPU 3106 may acquire the steering angle and the vehicle speed from the ECU 3107. The steering angle may be determined by the driver's operation on the steering wheel 3108, and be processed by the ECU 3107 controlling the operation of a steering control unit, and be provided to the CPU 3106. The vehicle speed may be measured based on at least one of the driver's pedaling (e.g., the operation on the accelerator), the rotational speed of the engine 3109, and the wheel speed measured by wheel sensors, and may be processed in the ECU 3107 controlling the vehicle speed and be provided to the CPU 3106.

Further, the CPU 3106 may determine the relative position relationship between the vehicle and the surrounding vehicle, may issue a command to maintain the rotation speed of the engine 3109 for cruising to maintain a certain distance from the surrounding vehicle according to a predetermined driving plan, and may issue a command to adjust the steering wheel 3108 to the left or right to change the steering angle, to perform an evasive maneuver, when the vehicle and the surrounding vehicle are below a threshold distance or when the surrounding vehicle cuts in. In FIG. 49, the steering wheel 3108 and the engine 3109 are shown as components related to the steering angle and the vehicle speed; however, the present disclosure is not limited thereto, and the steering angle and the vehicle speed may be determined through various vehicle components.

The CPU 3106 may perform object detection on driving images in a motion-based manner. The motion-based manner is a method of detecting the degree of motion of an object over time to determine its relative motion. Driving images may be consecutively acquired in units of a frame through the image sensor 3101. For example, individual frames may be acquired at a rate of 60 fps (frames per second). In this case, the CPU 3106 may detect motions over time between image frames acquired every 1/60 seconds. In the motion-based manner, optical flow which refers to the distribution of motion vectors of an object, and so on may be included.

The CPU 3106 may auxiliarily use the distances to objects acquired from the LIDAR sensor 3103 and the RADAR sensor 3104 other than the image sensor 3101, to maintain a stable driving state of the vehicle. Further, the CPU 3106 may issue commands to adjust the conditions inside and outside the vehicle, in response to driver's operations on the user interface 3102.

The ECU 3107 may be an electronic control unit provided to control the overall operation or a part of the operation of the vehicle. The ECU 3107 may control the operation of the vehicle according to parameters of the vehicle based on the operation of a combustion engine, the operation of one or more electric motors, a semi-automatic gearbox (SAGB) or an automatic gearbox (AGB), and other driver's control, through a controller area network (CAN) multiplexing bus.

The ECU 3107 may electronically control the vehicle's engine, the actuator of the steering control device, the shift control system, the anti-lock brake system, the airbag control system, and the like, by a computer, and may provide the vehicle speed based on the rotational speed of the engine or the wheel speed measured by a wheel sensor, to the vehicle 3000, and may provide the steering angle of the vehicle from the steering control device to the vehicle 3000.

In one or more embodiments, the ECU 3107 may control the states of the steering wheel 3108 and the engine 3109 in response to commands issued by the CPU 3106 and the NPU 3105. In one or more embodiments, the ECU 3107 may accelerate or decelerate the vehicle in response to commands issued by the CPU 3106 and NPU 3105, and may provide a signal to the engine 3109 to increase or decrease the rotational speed of the engine for acceleration or deceleration. Further, the ECU 3107 may adjust the steering wheel 3108 to the left or right for an evasive maneuver according to a predetermined driving plan, when the distance to a surrounding vehicle is below a threshold distance, or when a surrounding vehicle cuts in.

According to one or more embodiments of this disclosure, the CPU 3106 or the ECU 3107 may check defects in a ramp signal RML to turn off the autonomous driving mode of the vehicle 3000. For example, the CPU 3106 or the ECU 3107 may detect a defect in the ramp signal RML while the vehicle is running in the autonomous driving mode based on the image sensor 3101, and immediately change the driving mode from the autonomous driving mode to the manual driving mode by the driver, such that the safety of the user is secured. For example, the vehicle 3000 may detect a defect in the ramp signal RML, and stop the driving assistance function based on the ramp signal RML, such that the safety of the driver or the user is secured.

Although the drawings illustrates that the ECU 3107 is provided separately from the CPU 3106 in the vehicle, the present disclosure is not limited thereto, and the vehicle control function of the ECU 3107 may be given to the CPU 3106 and be performed in the CPU, and in this case, the CPU 3106 may be understood as having at least two processor cores. In FIG. 49, it is shown that the ECU 3107 is a separate component from the CPU 3106; however, it is not limited thereto, and may be included in the CPU 3106.

The vehicle 3000 may further include a communication module. The communication module may transmit and receive data to and from the outside of the vehicle 3000. For example, the communication module may perform communication with objects outside the vehicle 3000. In this case, the communication module may perform communication in the vehicle-to-everything (V2X) manner. For example, the communication module may perform communication in the vehicle-to-vehicle (V2V), vehicle-to-infra (V21), vehicle-to-pedestrian (V2P) and vehicle-to-nomadic devices (V2N) manners. However, the communication module is not limited thereto, may transmit and receive data in various well-known communication manners. For example, the communication module performs communication by using, for example, 3G, 4G (LTE), 5G, Wi-Fi, Bluetooth, Bluetooth Low Energy (BLE), Zigbee, near-field communication (NFC), and ultrasonic communication methods, or the like, and may include both short-distance and long-distance communication.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An image sensor comprising:
a pixel comprising:
a first photoelectric element, at least one second photoelectric element, and at least one third photoelectric element that are connected to a first node, a second node, and a third node, respectively;
a driving transistor configured to generate a pixel signal based on a voltage of the first node applied to a gate of the driving transistor;
a gain control transistor connected between the first node and the second node;
a first switch transistor connected between the second node and the third node; and
a capacitor connected between the third node and a power source; and
a row driver connected to the pixel and configured to control the pixel.

2. The image sensor of claim 1, wherein:
the pixel further comprises a second switch transistor connected between the third node and the capacitor,
the first photoelectric element, the at least one second photoelectric element, and the at least one third photoelectric element are configured to generate a first photoelectric charge, a second photoelectric charge, and a third photoelectric charge, respectively, in an integration period;
the row driver is configured to control the pixel to turn on the second switch transistor in the integration period so that the third photoelectric charge generated by the at least one third photoelectric element and overflowing from the at least one third photoelectric element is transferred to the capacitor.

3. The image sensor of claim 2, wherein, in a readout period comprising a first section and a second section, the row driver is configured to control the pixel to:
turn on the gain control transistor and the first switch transistor during the first section to transfer the second photoelectric charge generated by the at least one second photoelectric element to the first node; and
turn on the gain control transistor, the first switch transistor, and the second switch transistor during the second section to transfer the third photoelectric charge stored in the capacitor to the first node.

4. The image sensor of claim 3, wherein, in a readout period comprising a third section and a fourth section, the row driver is configured to control the pixel to:
turn off the gain control transistor during the third section to transfer the first photoelectric charge generated by the first photoelectric element to the first node; and
turn on the gain control transistor during the fourth section to transfer the first photoelectric charge to the second node.

5. The image sensor of claim 1, wherein:
the pixel further comprises a second switch transistor connected between the third node and the capacitor;
the first photoelectric element, the at least one second photoelectric element, and the at least one third photoelectric element are configured to generate a first photoelectric charge, a second photoelectric charge, and a third photoelectric charge, respectively, in an integration period; and
the row driver is configured to control the pixel to turn on the first switch transistor and the second switch transistor in the integration period so that the second photoelectric charge generated by and overflowing from the at least one second photoelectric element and the third photoelectric charge generated by and overflowing from the at least one third photoelectric element is transferred to the capacitor.

6. The image sensor of claim 1, wherein:
the at least one second photoelectric element and the at least one third photoelectric element have a smaller light-receiving area than that of the first photoelectric element.

7. The image sensor of claim 1, wherein the pixel comprises:
a first group comprising the first photoelectric element;
a second group comprising the at least one second photoelectric element;
a third group comprising the at least one third photoelectric element; and
a separation pattern disposed between the first group, the second group, and the third group,
wherein the first group is disposed in a central region of the pixel, and
wherein the second group and the third group are disposed in a plurality of peripheral areas of the pixel.

8. The image sensor of claim 7, wherein the first group has an octagonal shape, and the second group and the third group have a triangular shape.

9. The image sensor of claim 8, wherein a first separation pattern among the separation patterns extends from at least one first surface extending in a first direction among a plurality of surfaces of the first group toward a center of the first group in a second direction perpendicular to the first direction, and
a length of the first separation pattern is shorter than ½ of a first length of the pixel in the second direction.

10. The image sensor of claim 8, wherein a first separation pattern among the separation patterns extends from at least one first surface extending in a first direction among a plurality of surfaces of the first group toward a center of the first group in a second direction perpendicular to the first direction, and
a length of the first separation pattern is shorter than a first length of the pixel in the second direction, and longer than ½ of the first length.

11. The image sensor of claim 8, wherein:
a first separation pattern among the separation patterns extends in a direction perpendicular from at least one first surface extending in a first direction and a third direction crossing a second direction perpendicular to the first direction toward a center of the first group to the at least one first surface; and
a length of the first separation pattern is shorter than a length from the center of the first group to the plurality of peripheral areas in the third direction.

12. The image sensor of claim 8, wherein:
a first separation pattern among the separation patterns extends in a direction perpendicular from at least one first surface extending in a first direction and a third direction crossing a second direction perpendicular to the first direction toward a center of the first group to the at least one first surface; and
a length of the first separation pattern is longer than a first length from the center of the first group to the plurality of peripheral areas in the third direction, and shorter than a second length of the pixel in the third direction.

13. The image sensor of claim 8, wherein:
the first group has an octagonal shape, and the second group and the third group have a triangular shape.

14. The image sensor of claim 1, wherein the capacitor is a lateral overflow integration capacitor.

15. A pixel circuit comprising:
a first group comprising a first photoelectric element configured to generate a photoelectric charge, a driving transistor configured to generate a pixel signal based on a voltage of a first node connected to the first photoelectric element, a gain control transistor connected between the first node and a second node, and a first switch transistor connected between the second node and a third node;
a second group comprising at least one second photoelectric element connected to the second node;
a third group comprising at least one third photoelectric element connected to the third node and a capacitor between the third node and a power source; and
a separation pattern disposed between the first group, the second group, and the third group,
wherein the first group is disposed in a central region of the pixel circuit, and
wherein the second group and the third group are disposed in a plurality of peripheral areas of the pixel circuit.

16. The pixel circuit of claim 15, wherein the first group has an octagonal shape, and the second group and the third group have a rectangular shape.

17. The pixel circuit of claim 15, wherein the first group has an octagonal shape, and the second group and the third group have a triangular shape.

18. The pixel circuit of claim 15, wherein a first separation pattern among the separation patterns extends from at least one first surface extending in a first direction among a plurality of surfaces of the first group toward a center of the first group in a second direction perpendicular to the first direction, and
a length of the first separation pattern is shorter than ½ of a first length of the pixel circuit in the second direction.

19. The pixel circuit of claim 15, wherein a first separation pattern among the separation patterns extends from at least one first surface extending in a first direction among a plurality of surfaces of the first group toward a center of the first group in a second direction perpendicular to the first direction, and
a length of the first separation pattern is shorter than a first length of the pixel circuit in the second direction, and longer than ½ of the first length.

20. An image sensor comprising:
a pixel comprising:
a first photoelectric element, at least one second photoelectric element, and at least one third photoelectric element that are connected to a first node, a second node, and a third node, respectively;
a driving transistor configured to generate a pixel signal based on a voltage of the first node applied to a gate of the driving transistor;
a gain control transistor connected between the first node and the second node;
a first switch transistor connected between the second node and the third node; and
a capacitor connected between the third node and a power source; and
a row driver connected to the pixel and configured to control the pixel,
wherein the first switch transistor is disposed in a central region of the pixel, and the at least one second photoelectric element and the at least one third photoelectric element are disposed in a plurality of peripheral areas of the pixel.
